(19) United States
(12) Patent Application Publication
(10) Pub. No.: US 2025/0048909 A1
(43) Pub. Date: Feb. 6, 2025

(54) DISPLAY APPARATUS

(71) Applicant: SEMICONDUCTOR ENERGY LABORATORY CO., LTD., Atsugi-shi, Kanagawa-ken (JP)

(72) Inventors: Yuichi YANAGISAWA, Atsugi, Kanagawa (JP); Daiki NAKAMURA, Atsugi, Kanagawa (JP); Hiromi SAWAI, Atsugi, Kanagawa (JP); Ryota HODO, Atsugi, Kanagawa (JP)

(21) Appl. No.: 18/718,878

(22) PCT Filed: Dec. 16, 2022
(86) PCT No.: PCT/IB2022/062338

§ 371 Date: Jun. 12, 2024

(30) Foreign Application Priority Data
Dec. 29, 2021 (JP) 2021-215356

(51) Int. Cl. H10K 59/88; H10K 59/122; H10K 59/80

(52) U.S. Cl. CPC H10K 59/88; H10K 59/122; H10K 59/8792

(57) ABSTRACT

A display apparatus with high display quality is provided. In the display apparatus, a dummy pixel portion is a region that does not contribute to display. The dummy pixel portion is positioned adjacent to the outside of a pixel portion in a plan view. The pixel portion includes a first insulating layer, a first pixel electrode and a second pixel electrode over the first insulating layer, a first layer over the first pixel electrode, a second layer over the second pixel electrode, and a common electrode over the first layer and the second layer. The dummy pixel portion includes the first insulating layer, a first conductive layer and a second conductive layer over the first insulating layer, a third layer over the first conductive layer, a fourth layer over the second conductive layer, and the common electrode over the third layer and the fourth layer. The first insulating layer includes a first groove and a second groove. The first groove includes a first region overlapping with the first pixel electrode and a second region overlapping with the second pixel electrode. The second groove includes a third region overlapping with the first conductive layer and a fourth region overlapping with the second conductive layer.

### TECHNICAL FIELD

One embodiment of the present invention relates to a display apparatus.

Note that one embodiment of the present invention is not limited to the above technical field. Examples of the technical field of one embodiment of the present invention disclosed in this specification and the like include a semiconductor device, a display apparatus, a light-emitting apparatus, a power storage device, a storage device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, higher resolution has been required for display panels. Examples of devices that require high-resolution display panels include a smartphone, a tablet terminal, and a notebook computer. Furthermore, higher resolution has been required for a stationary display apparatus such as a television device or a monitor device along with an increase in definition. An example of a device required to have the highest resolution is a device for virtual reality (VR) or augmented reality (AR).

Typical examples of a display apparatus that can be used for a display panel include a liquid crystal display apparatus, a light-emitting apparatus including a light-emitting element such as an organic EL (Electro Luminescence) element or a light-emitting diode (LED), and electronic paper performing display by an electrophoretic method or the like.

For example, the basic structure of an organic EL element is a structure in which a layer containing a light-emitting organic compound is provided between a pair of electrodes. By voltage application to this element, light emission can be obtained from the light-emitting organic compound. A display apparatus using such an organic EL element does not need a backlight that is necessary for a liquid crystal display apparatus and the like; thus, a thin, lightweight, high-contrast, and low-power display apparatus can be achieved. Patent Document 1, for example, discloses an example of a display apparatus using an organic EL element.

Patent Document 2 discloses a display apparatus for VR using an organic EL device.

### REFERENCE

### Patent Document

[Patent Document 1] Japanese Published Patent Application No. 2002-324673
[Patent Document 2] PCT International Publication No. 2018/087625

### SUMMARY OF THE INVENTION

### Problems to be Solved by the Invention

An object of one embodiment of the present invention is to provide a display apparatus with high display quality. An object of one embodiment of the present invention is to provide a highly reliable display apparatus. An object of one embodiment of the present invention is to provide a display apparatus that can easily achieve a higher resolution. An object of one embodiment of the present invention is to provide a display apparatus having both high display quality and a high resolution. An object of one embodiment of the present invention is to provide a display apparatus with low power consumption.

An object of one embodiment of the present invention is to provide a display apparatus having a novel structure or a method for manufacturing the display apparatus. An object of one embodiment of the present invention is to provide a method for manufacturing the above-described display apparatus with high yield. An object of one embodiment of the present invention is to at least alleviate at least one of problems of the conventional technique.

Note that the description of these objects does not preclude the existence of other objects. Note that one embodiment of the present invention does not need to achieve all of these objects. Note that objects other than these can be derived from the description of the specification, the drawings, the claims, and the like.

### Means for Solving the Problems

One embodiment of the present invention is a display apparatus including a pixel portion and a dummy pixel portion. The dummy pixel portion is a region that does not contribute to display. The dummy pixel portion is positioned adjacent to the outside of the pixel portion in a plan view. The pixel portion includes a first insulating layer, a first pixel electrode and a second pixel electrode over the first insulating layer, a first layer over the first pixel electrode, a second layer over the second pixel electrode, and a common electrode over the first layer and the second layer. The dummy pixel portion includes the first insulating layer, a first conductive layer and a second conductive layer over the first insulating layer, a third layer over the first conductive layer, a fourth layer over the second conductive layer, and the common electrode over the third layer and the fourth layer. The first conductive layer and the second conductive layer each include the same material as a material of the first pixel electrode. The first layer includes a first compound, and the first compound is a light-emitting organic compound. The third layer includes the first compound. The first insulating layer includes a first groove and a second groove. The first groove includes a first region overlapping with the first pixel electrode and a second region overlapping with the second pixel electrode. The second groove includes a third region overlapping with the first conductive layer and a fourth region overlapping with the second conductive layer.

In the above structure, the display apparatus preferably includes a resin layer. The resin layer is preferably positioned in the first region, in the second region, and in a fifth region between the first region and the second region inside the first groove, and is preferably positioned in the third region, in the fourth region, and in a sixth region between the third region and the fourth region inside the second groove.

In the above structure, it is preferable that the resin layer overlap with the first pixel electrode and include a first opening portion overlapping with the first pixel electrode. It is preferable that the resin layer overlap with the second pixel electrode and include a second opening portion overlapping with the second pixel electrode. It is preferable that the first layer and the common electrode be in contact with each other in the first opening portion, and the second layer and the common electrode be in contact with each other in the second opening portion.

In the above structure, the resin layer preferably includes a seventh region that overlaps with 50% or more of the area of the first conductive layer in the plan view and is located between the third layer and the common electrode; and an eighth region that overlaps with 50% or more of the area of the second conductive layer in the plan view and is located between the fourth layer and the common electrode.

In the above structure, it is preferable that the second layer include a second compound, and the second compound be a light-emitting organic compound. The fourth layer preferably includes at least one of the first compound and the second compound. The first compound is preferably a light-emitting organic compound that emits light with intensity in a red wavelength range, a green wavelength range, or a blue wavelength range. The second compound is preferably a light-emitting organic compound that emits light with intensity in a wavelength range of a color different from the color for the first compound among the red wavelength range, the green wavelength range, and the blue wavelength range. Alternatively, in the above structure, the second layer and the fourth layer each preferably include the first compound.

In the above structure, it is preferable that a second insulating layer be provided, and the second insulating layer include a region in contact with a top surface of the first layer, and a region in contact with the first insulating layer in the first region.

### Effect of the Invention

According to one embodiment of the present invention, a display apparatus with high display quality can be provided. A highly reliable display apparatus can be provided. A display apparatus that can easily achieve a higher resolution can be provided. A display apparatus with both high display quality and a high resolution can be provided. A display apparatus with low power consumption can be provided.

According to one embodiment of the present invention, a display apparatus having a novel structure or a method for manufacturing the display apparatus can be provided. A method for manufacturing the above-described display apparatus with high yield can be provided.

According to one embodiment of the present invention, at least one of problems of the conventional technique can be at least reduced.

Note that the description of these effects does not preclude the existence of other effects. Note that one embodiment of the present invention does not need to have all the effects. Note that effects other than these can be derived from the description of the specification, the drawings, the claims, and the like.

### BRIEF DESCRIPTION OF THE DRAWINGS

FIG. 1A and FIG. 1B are top views illustrating an example of a display apparatus.

FIG. 2A and FIG. 2B are top views illustrating examples of a display apparatus.

FIG. 3 is a top view illustrating an example of a display apparatus.

FIG. 4A and FIG. 4B are top views illustrating examples of a display apparatus.

FIG. 5 is a top view illustrating an example of a display apparatus.

FIG. 6A and FIG. 6B are top views each illustrating an example of a pixel. FIG. 6C and FIG. 6D are cross-sectional views each illustrating an example of a display apparatus.

FIG. 7A and FIG. 7B are top views each illustrating an example of a pixel. FIG. 7C is a cross-sectional view illustrating an example of a display apparatus.

FIG. 8A and FIG. 8B are top views illustrating examples of a pixel. FIG. 8C is a cross-sectional view illustrating an example of a display apparatus.

FIG. 9 is a top view illustrating an example of a display apparatus.

FIG. 10 is a top view illustrating an example of a display apparatus.

FIG. 11 is a top view illustrating an example of a display apparatus.

FIG. 12A and FIG. 12B are top views each illustrating an example of a pixel.

FIG. 13 is a top view illustrating an example of pixels.

FIG. 14A is a cross-sectional view illustrating an example of a display apparatus. FIG. 14B is a top view illustrating an example of a display apparatus.

FIG. 15A and FIG. 15B are cross-sectional views illustrating examples of a display apparatus.

FIG. 15C is a top view illustrating an example of a display apparatus. FIG. 15D is a cross-sectional view illustrating an example of a display apparatus.

FIG. 16A and FIG. 16B are cross-sectional views illustrating examples of a display apparatus.

FIG. 17A and FIG. 17B are cross-sectional views illustrating examples of a display apparatus.

FIG. 18A to FIG. 18D are cross-sectional views illustrating an example of a method for manufacturing a display apparatus.

FIG. 19A to FIG. 19D are cross-sectional views illustrating an example of a method for manufacturing a display apparatus.

FIG. 20A to FIG. 20F are top views illustrating examples of a pixel.

FIG. 21A to FIG. 21H are top views illustrating examples of a pixel.

FIG. 22A to FIG. 22J are top views illustrating examples of a pixel.

FIG. 23A to FIG. 23D are top views illustrating examples of a pixel. FIG. 23E to FIG. 23G are cross-sectional views illustrating examples of a display apparatus.

FIG. 24A and FIG. 24B are perspective views illustrating an example of a display apparatus.

FIG. 25A to FIG. 25E are top views illustrating examples of a structure of a display module.

FIG. 26A and FIG. 26B are cross-sectional views illustrating examples of a display apparatus.

FIG. 27 is a cross-sectional view illustrating an example of a display apparatus.

FIG. 28 is a cross-sectional view illustrating an example of a display apparatus.

FIG. 29 is a cross-sectional view illustrating an example of a display apparatus.

FIG. 30 is a cross-sectional view illustrating an example of a display apparatus.

FIG. 31 is a cross-sectional view illustrating an example of a display apparatus.

FIG. 32 is a perspective view illustrating an example of a display apparatus.

FIG. 33A is a cross-sectional view illustrating an example of a display apparatus. FIG. 33B and FIG. 33C are cross-sectional views illustrating examples of transistors. FIG. 33D is a cross-sectional view illustrating an example of a display apparatus.

FIG. 34A is a block diagram illustrating an example of a display apparatus. FIG. 34B to FIG. 34D are diagrams illustrating examples of a pixel circuit.

FIG. 35A to FIG. 35D are cross-sectional views illustrating examples of transistors.

FIG. 36A to FIG. 36F are diagrams illustrating structure examples of light-emitting devices.

FIG. 37A to FIG. 37D are diagrams illustrating examples of electronic devices.

FIG. 38A to FIG. 38F are diagrams illustrating examples of electronic devices.

FIG. 39A to FIG. 39G are diagrams illustrating examples of electronic devices.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the invention described below, the same reference numerals are commonly used for the same portions or portions having similar functions in different drawings, and a repeated description thereof is omitted. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Therefore, they are not limited to the illustrated scale.

Note that ordinal numbers such as “first” and “second” in this specification and the like are used in order to avoid confusion among components and do not limit the number of components.

In this specification and the like, a display apparatus may be rephrased as an electronic device.

In this specification and the like, a display apparatus that is one embodiment of a display apparatus has a function of displaying (outputting) an image or the like on (to) a display surface. Therefore, the display apparatus is one embodiment of an output device.

In this specification and the like, a substrate of a display apparatus to which a connector such as an FPC (Flexible Printed Circuit) or a TCP (Tape Carrier Package) is attached, or the substrate on which an IC is mounted by a COG (Chip On Glass) method or the like is referred to as a display module in some cases. In this specification and the like, a display apparatus is sometimes referred to as a display panel.

In this specification and the like, the term “film” and the term “layer” can be interchanged with each other. For example, in some cases, the term “conductive layer” and the term “insulating layer” can be interchanged with the term “conductive film” and the term “insulating film”, respectively.

Note that in this specification and the like, an EL layer means a layer containing at least a light-emitting substance (also referred to as a light-emitting layer) or a stack including the light-emitting layer provided between a pair of electrodes of a light-emitting device (also referred to as a light-emitting element).

In this specification and the like, a device fabricated using a metal mask or an FMM (fine metal mask) is sometimes referred to as a device having an MM (metal mask) structure. In this specification and the like, a device fabricated without using a metal mask or an FMM is sometimes referred to as a device having an MML (metal maskless) structure.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be distinguished from one another on the basis of the cross-sectional shape, properties, or the like. Furthermore, one layer may have two or three functions of the carrier-injection layer, the carrier-transport layer, and the carrier-blocking layer.

### Embodiment 1

In this embodiment, a display apparatus of one embodiment of the present invention will be described.

One embodiment of the present invention is a display apparatus that includes a display portion capable of performing full-color display. The display portion includes a first subpixel and a second subpixel that emit light of different colors. The first subpixel includes a first light-emitting device that emits light of a first color, and the second subpixel includes a second light-emitting device that emits light of a color different from the color of light emitted by the first light-emitting device, for example, a second color. At least one material is different between the first light-emitting device and the second light-emitting device; for example, a light-emitting material in the first light-emitting device is different from a light-emitting material in the second light-emitting device. That is, light-emitting devices for different emission colors are separately formed in the display apparatus of one embodiment of the present invention.

A structure in which light-emitting layers in light-emitting devices of different colors (e.g., blue (B), green (G), and red (R)) are separately formed or separately patterned is sometimes referred to as an SBS (Side By Side) structure. The SBS structure allows optimization of materials and structures of light-emitting devices and thus can extend freedom of choice of the materials and the structures, which makes it easy to improve the luminance and the reliability.

In the case of fabricating a display apparatus that includes a plurality of light-emitting devices emitting light of different colors, the light-emitting layers emitting light of different colors each need to be formed into an island shape. Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

For example, an island-shaped light-emitting layer can be formed by a vacuum evaporation method using a metal mask (also referred to as a shadow mask). However, this method causes a deviation from the designed shape and position of an island-shaped light-emitting layer owing to various influences such as the low accuracy of the metal mask, the positional deviation between the metal mask and a substrate, a warp of the metal mask, and the vapor-scattering-induced expansion of outline of the formed film; accordingly, it is difficult to achieve high resolution and a high aperture ratio of a display apparatus. In addition, the outline of the layer may blur during vapor deposition, whereby the thickness of an end portion may be reduced. That is, the thickness of the island-shaped light-emitting layer may vary from area to area. In the case of fabricating a display apparatus with a large size, high definition, or high resolution, the manufacturing yield might be reduced because of low dimensional accuracy of the metal mask and deformation due to heat or the like.

In a method for manufacturing a display apparatus of one embodiment of the present invention, a first layer (also referred to as an EL layer or part of an EL layer) that includes a light-emitting layer emitting light of the first color is formed over the entire surface, and then a first mask layer is formed over the first layer. Then, a first resist mask is formed over the first mask layer and the first layer and the first mask layer are processed using the first resist mask, so that the first layer is formed into an island shape. Next, in a manner similar to that for the first layer, a second layer (also referred to as an EL layer or part of an EL layer) that includes a light-emitting layer emitting light of the second color is formed into an island shape using a second mask layer and a second resist mask.

In this specification and the like, a mask layer is positioned above at least a light-emitting layer (specifically, a layer processed into an island shape among layers included in an EL layer) and has a function of protecting the light-emitting layer in the manufacturing process.

Note that in the case where a layer including at least part of the EL layer is processed into an island shape, a method in which processing is performed directly above the light-emitting layer by a photolithography method can be considered. In the case where this method is employed, damage to the light-emitting layer (e.g., processing damage) might significantly degrade the reliability. In view of the above, in the fabrication of the display apparatus of one embodiment of the present invention, a mask layer or the like is preferably formed over a layer above the light-emitting layer (e.g., a carrier-transport layer, a carrier-blocking layer, or a carrier-injection layer, specifically, an electron-transport layer, a hole-blocking layer, or an electron-injection layer), followed by the processing of the light-emitting layer into an island shape. Such a method provides a highly reliable display apparatus.

As described above, in the method for manufacturing a display apparatus of one embodiment of the present invention, an island-shaped EL layer or an island-shaped layer including part of the EL layer is formed not by using a metal mask having a fine pattern but by processing a film to be the EL layer or a film to be the part of the EL layer formed over the entire surface. Accordingly, a high-resolution display apparatus or a display apparatus with a high aperture ratio, each of which has been difficult to achieve, can be obtained. Moreover, the island-shaped EL layer or the island-shaped layer including the part of the EL layer can be formed separately for each color, enabling the display apparatus to perform extremely clear display with high contrast and high display quality. Moreover, providing the mask layer over the island-shaped EL layer or the island-shaped layer including the part of the EL layer can reduce damage to the island-shaped EL layer or the island-shaped layer including the part of the EL layer in the manufacturing process of the display apparatus, resulting in an increase in reliability of the light-emitting device.

It is difficult to set the interval between adjacent light-emitting devices to less than 10 μm with a formation method using a metal mask, for example; however, with the above method, the interval can be reduced to less than 10 μm, less than or equal to 8 μm, less than or equal to 5 μm, less than or equal to 3 μm, less than or equal to 2 μm, or less than or equal to 1 μm. Furthermore, for example, with the use of a light exposure apparatus for LSI, the interval between adjacent light-emitting devices can be reduced to less than or equal to 500 nm, less than or equal to 200 nm, less than or equal to 100 nm, or even less than or equal to 50 nm. Accordingly, the area of a non-light-emitting region that could exist between two light-emitting devices can be significantly reduced, and the aperture ratio can be close to 100%. For example, the aperture ratio higher than or equal to 50%, higher than or equal to 60%, higher than or equal to 70%, higher than or equal to 80%, or higher than or equal to 90% and lower than 100% can be achieved.

Furthermore, a pattern of the island-shaped EL layer or the island-shaped layer including the part of the EL layer itself can be made much smaller than that in the case of using a metal mask. For example, in the case of using a metal mask for separately forming the island-shaped EL layers or the island-shaped layers including the parts of the EL layers, a variation in the thickness occurs between the center and the edge of the pattern, which causes a reduction in an effective area that can be used as a light-emitting region with respect to the entire pattern area. By contrast, in the above manufacturing method, a film formed to have a uniform thickness is processed, so that the island-shaped EL layers or the island-shaped layers including the parts of the EL layers can be formed to have a uniform thickness. Accordingly, even in a fine pattern, almost the whole area can be used as a light-emitting region. Consequently, a display apparatus having both high resolution and a high aperture ratio can be fabricated.

In the method for manufacturing a display apparatus of one embodiment of the present invention, it is preferable that a layer that includes a light-emitting layer (the layer can be referred to as an EL layer or part of an EL layer) be formed over the entire surface, and then a mask layer be formed over the EL layer or an island-shaped layer including the part of the EL layer. Then, it is preferable that a resist mask be formed over the mask layer and the EL layer or the part of the EL layer and the mask layer be processed using the resist mask to form an island-shaped EL layer or an island-shaped layer including part of the EL layer. Then, it is preferable that a resist mask be formed over the mask layer and the EL layer or part of the EL layer and the mask layer be processed using the resist mask to form the island-shaped EL layer or the island-shaped layer including part of an EL layer.

Providing the mask layer over the EL layer or the part of the EL layer can reduce damage to the EL layer or the part of the EL layer during the manufacturing process of the display apparatus and increase the reliability of the light-emitting device.

Note that it is not necessary to form all layers included in the EL layers separately for the respective light-emitting devices emitting light of different colors, and some layers of the EL layers can be formed in the same step. Examples of the layers included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In the method for manufacturing a display apparatus of one embodiment of the present invention, after some layers included in the EL layer are formed into an island shape separately for each color, the mask layer is removed at least partly; then, the other layers (sometimes referred to as common layers) included in the EL layers and a common electrode (also referred to as an upper electrode) are formed (as a single film) to be shared by the light-emitting devices of different colors. For example, a carrier-injection layer and a common electrode can be formed to be shared by the light-emitting devices of different colors.

Meanwhile, the carrier-injection layer often has relatively high conductivity in the EL layer. Therefore, when the carrier-injection layer is in contact with the side surface of any layer of the EL layer formed into an island shape or the side surface of the pixel electrode, the light-emitting device might be short-circuited. Note that also in the case where the carrier-injection layer is provided in an island shape and the common electrode is formed to be shared by the light-emitting devices of different colors, the light-emitting device might be short-circuited when the common electrode is in contact with the side surface of the EL layer or the side surface of the pixel electrode.

In view of the above, the display apparatus of one embodiment of the present invention includes an insulating layer covering at least the side surface of an island-shaped light-emitting layer. The insulating layer may cover part of the top surface of the island-shaped light-emitting layer. Note that the side surface of the island-shaped light-emitting layer here refers to the plane that is not parallel to the substrate (or the surface where the light-emitting layer is formed) among the interfaces between the island-shaped light-emitting layer and other layers. The side surface is not necessarily one of a flat plane and a curved plane in an exactly mathematical perspective.

This can inhibit at least some layers of the island-shaped EL layer and the pixel electrode from being in contact with the carrier-injection layer or the common electrode. Hence, a short circuit of the light-emitting device is inhibited, and the reliability of the light-emitting device can be increased.

The above-described insulating layer is preferably provided to be thin. Treatment such as heat treatment is performed on the insulating layer in the fabrication of the display apparatus of one embodiment of the present invention, and the treatment causes shrinkage of the insulating layer in some cases. Stress caused by the shrinkage of the insulating layer is applied on layers included in the light-emitting device in some cases. When the insulating layer is too thick in such a case, the stress becomes larger and separation might occur at the interface between the layers included in the light-emitting device. The insulating layer provided to be thin can inhibit separation; thus, the reliability of the light-emitting device can be improved.

In a light-emitting device in which the level of the top surface of the EL layer is low, for example, the insulating layer provided to be adjacent to the EL layer may have a larger thickness than that in a light-emitting device in which the level of the top surface of the EL layer is high. In this manner, the thickness of the insulating layer varies. Furthermore, in the case where not only the variation in thickness but also unevenness in a film is caused, variation in the top surface shape might be caused in addition to the variation in thickness.

In the display apparatus of one embodiment of the present invention, when the top surfaces of island-shaped EL layers or the top surfaces of island-shaped layers including parts of the EL layers in adjacent light-emitting devices are substantially level with each other, unevenness of the formation surface of the insulating layer can be eliminated, and the thickness of the insulating layer can be uniformly thin.

In the display apparatus of one embodiment of the present invention in which two adjacent light-emitting devices are provided over a first insulating layer, when an island-shaped EL layer or an island-shaped layer including part of the EL layer in a first light-emitting device has a smaller thickness than an island-shaped EL layer or an island-shaped layer including part of the EL layer in a second light-emitting device, the level difference between the top surfaces of the island-shaped EL layers or the island-shaped layers including the parts of the EL layers in the two adjacent light-emitting devices can be made small in the following manner: a second insulating layer is provided between a pixel electrode of the first light-emitting device and the first insulating layer, and the top surface of the pixel electrode of the first light-emitting device is positioned to be at a higher level than the top surface of a pixel electrode of the second light-emitting device.

The insulating layer covering the side surface of the island-shaped EL layer or the island-shaped layer including the part of the EL layer preferably has a function of a barrier insulating layer against at least one of water and oxygen. The insulating layer preferably has a function of inhibiting diffusion of at least one of water and oxygen. The insulating layer preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a particular substance (also referred to as low permeability). Alternatively, a barrier property refers to a function of capturing or fixing (also referred to as gettering) a particular substance.

With the use of an insulating layer having a function of the barrier insulating layer or a gettering function, entry of impurities (typically, at least one of water and oxygen) that might diffuse into the light-emitting devices from the outside can be inhibited. With this structure, highly reliable light-emitting devices and a highly reliable display apparatus can be provided.

The display apparatus of one embodiment of the present invention includes a pixel electrode functioning as an anode; an island-shaped hole-injection layer, an island-shaped hole-transport layer, an island-shaped light-emitting layer, and an island-shaped electron-transport layer that are provided in this order over the pixel electrode; an insulating layer provided to cover the side surfaces of the hole-injection layer, the hole-transport layer, the light-emitting layer, and the electron-transport layer; an electron-injection layer provided over the electron-transport layer; and a common electrode that is provided over the electron-injection layer and functions as a cathode.

Alternatively, the display apparatus of one embodiment of the present invention includes a pixel electrode functioning as a cathode; an island-shaped electron-injection layer, an island-shaped electron-transport layer, an island-shaped light-emitting layer, and an island-shaped hole-transport layer that are provided in this order over the pixel electrode; an insulating layer provided to cover the side surfaces of the electron-injection layer, the electron-transport layer, the light-emitting layer, and the hole-transport layer; a hole-injection layer provided over the hole-transport layer; and a common electrode that is provided over the hole-injection layer and functions as an anode.

The hole-injection layer, the electron-injection layer, or the like often has relatively high conductivity in the EL layer. Since the side surfaces of these layers are covered with the insulating layer in the display apparatus of one embodiment of the present invention, these layers can be inhibited from being in contact with the common electrode or the like. Hence, a short circuit of the light-emitting device is inhibited, and the reliability of the light-emitting device can be increased.

The insulating layer covering the side surface of the island-shaped EL layer or the island-shaped layer including the part of the EL layer may have a single-layer structure or a stacked-layer structure.

When an insulating layer is formed to have a single-layer structure using an inorganic material, for example, the insulating layer can be used as a protective insulating layer for the island-shaped EL layer or the island-shaped layer including the part of the EL layer. This can increase the reliability of the display apparatus. It is preferable that the protective insulating layer also cover part of the top surface of the island-shaped EL layer or the island-shaped layer including the part of the EL layer. This structure sometimes allows the above mask layer to be left and formed between the top surface of the island-shaped EL layer or the island-shaped layer including the part of the EL layer and the protective insulating layer. The mask layer is preferably an insulating layer formed using an inorganic material like the above protective insulating film.

In the case where an insulating layer having a stacked-layer structure is used, a first layer of the insulating layer is preferably formed using an inorganic insulating material because it is formed in contact with the island-shaped EL layer or the island-shaped layer including the part of the EL layer. In particular, the first layer is preferably formed by an atomic layer deposition (ALD) method, which causes less film formation damage. Alternatively, an inorganic insulating layer is preferably formed by any of a sputtering method, a chemical vapor deposition (CVD) method, and a plasma-enhanced chemical vapor deposition (PECVD) method, which have higher film formation speed than an ALD method. In that case, a highly reliable display apparatus can be fabricated with high productivity. A second layer of the insulating layer is preferably formed using an organic material to fill a depressed portion formed by the first layer of the insulating layer.

For example, an aluminum oxide film formed by an ALD method can be used as the first layer of the insulating layer, and an organic resin film can be used as the second layer of the insulating layer. It is preferable to use a photosensitive acrylic resin as the organic resin, for example.

In the case where the side surface of the EL layer and the organic resin film are in direct contact with each other, the EL layer might be damaged by an organic solvent or the like that might be contained in the organic resin film. The use of an inorganic insulating film such as an aluminum oxide film formed by an ALD method as the first layer of the insulating layer enables a structure where the organic resin film and the side surface of the EL layer are not in direct contact with each other. Thus, the EL layer can be inhibited from being dissolved by the organic solvent, for example.

In the display apparatus of one embodiment of the present invention, an insulating layer covering an end portion of the pixel electrode does not need to be provided between the pixel electrode and the EL layer, so that the interval between adjacent light-emitting devices can be extremely short. As a result, higher resolution or higher definition of the display apparatus can be achieved. In addition, a mask for forming the insulating layer is not needed, reducing the manufacturing cost of the display apparatus.

Furthermore, light emitted from the EL layer can be extracted efficiently with a structure where an insulating layer covering the end portion of the pixel electrode is not provided between the pixel electrode and the EL layer, i.e., a structure where an insulating layer is not provided between the pixel electrode and the EL layer. Therefore, the display apparatus of one embodiment of the present invention can significantly reduce the viewing angle dependence. A reduction in the viewing angle dependence leads to an increase in visibility of an image on the display apparatus. For example, in the display apparatus of one embodiment of the present invention, the viewing angle (the maximum angle with a certain contrast ratio maintained when the screen is seen from an oblique direction) can be greater than or equal to 1000 and less than 180°, preferably greater than or equal to 1500 and less than or equal to 170°. Note that the viewing angle refers to that in the vertical direction and that in the horizontal direction.

The display apparatus of one embodiment of the present invention includes a pixel portion and a dummy pixel portion. The pixel portion includes a plurality of pixels. The dummy pixel portion includes a plurality of dummy pixels.

The dummy pixel includes a conductive layer that is formed by processing the same conductive film as a pixel electrode of the pixel. Since the conductive layer is formed by processing the same conductive film as the pixel electrode, the conductive layer is referred to as a pixel electrode in this specification and the like. Note that the pixel electrode of the dummy pixel does not have a function of an electrode in some cases. Specifically, for example, the pixel electrode of the dummy pixel is not electrically connected to a wiring or a circuit of the display apparatus in some cases. The pixel electrode of the dummy pixel is preferably formed using the same conductive film as the pixel electrode of the pixel. The pixel electrode of the dummy pixel may have substantially the same top surface shape as the pixel electrode of the pixel. Alternatively, the pixel electrode of the dummy pixel may have a shape different from that of the pixel electrode of the pixel.

Note that in this specification and the like, a top surface shape refers to, for example, a shape in a top view.

In the case where the pixel electrode or the like has a polygonal top surface shape, its corners may be rounded.

The pixel electrode of the dummy pixel is preferably formed using the same conductive film as the pixel electrode of the pixel. The pixel electrode of the dummy pixel sometimes has substantially the same thickness as the pixel electrode of the pixel.

The pixel includes an EL layer. Alternatively, the pixel includes an island-shaped layer including at least part of the EL layer. An island-shaped layer including at least part of an EL layer is sometimes referred to as an island-shaped organic layer of a pixel in this specification and the like. Note that the island-shaped organic layer may contain an inorganic material. The island-shaped layer including at least the part of the EL layer in the pixel preferably includes a light-emitting layer.

The dummy pixel includes an EL layer. The dummy pixel includes an island-shaped layer including at least part of the EL layer. The island-shaped layer including at least the part of the EL layer in the dummy pixel is preferably formed using the same film as the island-shaped layer including at least the part of the EL layer in the pixel.

The island-shaped layer including at least the part of the EL layer in the dummy pixel sometimes has substantially the same thickness as the island-shaped layer including at least the part of the EL layer in the pixel. The island-shaped layer including at least the part of the EL layer in the dummy pixel sometimes has the same sop surface shape as the island-shaped layer including at least the part of the EL layer in the pixel. Alternatively, the island-shaped layer in the dummy pixel may have a shape different from that of the island-shaped layer in the pixel.

In the display apparatus of one embodiment of the present invention, when the pixel includes subpixels (a first subpixel, a second subpixel, and a third subpixel) corresponding to three different colors, the dummy pixel may also include three different kinds of subpixels (a first dummy subpixel, a second dummy subpixel, and a third dummy subpixel). For example, the three kinds of subpixels of the dummy pixel are provided with EL layers that include light-emitting layers corresponding to three different emission colors. Note that the term “pixel” in this specification and the like refers to a subpixel in some cases.

Each of the first subpixel, the second subpixel, and the third subpixel includes an island-shaped organic layer. The island-shaped organic layer included in the subpixel preferably includes a light-emitting layer. The first subpixel, the second subpixel, and the third subpixel include light-emitting layers exhibiting different colors, for example.

The island-shaped layer including at least the part of the EL layer in the first dummy subpixel is preferably formed using the same film as the island-shaped layer including at least the part of the EL layer in the first subpixel. The island-shaped layer including at least the part of the EL layer in the second dummy subpixel is preferably formed using the same film as the island-shaped layer including at least the part of the EL layer in the second subpixel. The island-shaped layer including at least the part of the EL layer in the third dummy subpixel is preferably formed using the same film as the island-shaped layer including at least the part of the EL layer in the third subpixel.

In this specification and the like, layers formed using the same film sometimes have substantially the same thickness. Here, when the expression “substantially the same thickness” is used, for example, the difference in thickness between two layers formed using the same film is preferably less than or equal to 30%, further preferably less than or equal to 20%, still further preferably less than or equal to 10% of the thickness of one of the layers.

In the processes for fabricating the display apparatus, layers included in a light-emitting device, such as a pixel electrode and an EL layer, can be formed by formation of films to be the layers and partial removal of the films by etching. Etching using a mask enables formation of a fine pattern and miniaturization of an element.

The etching rate may change in accordance with the shape of the pattern, the size of the pattern, the density of a plurality of patterns arranged, the ratio between the region covered with the mask and the region not covered with the mask, the length of the periphery of the pattern, and the like. When a region provided in the vicinity of the region where the light-emitting device is formed has a pattern that is significantly different from the pattern of the region where the light-emitting device is formed, the etching rate in the region where the light-emitting device is formed might change, causing a defective shape of the pattern, unintended exposure of a lower layer by excessive etching, and the like.

The adhesion between films may change depending on a pattern on the formation surface. When a region provided in the vicinity of the region where the light-emitting device is formed has a pattern that is significantly different from the pattern of the region where the light-emitting device is formed, the adhesion between the films in the region where the light-emitting device is formed might change, causing peeling and the like. Specifically, when the adhesion between a pixel electrode and an organic layer is low, peeling would hinder the performance or the light-emitting function of the light-emitting device.

When the region having a pattern similar to that of the pixel portion is placed to be adjacent to the pixel portion, etching of the layers of the light-emitting device included in the pixel portion can be performed stably. In addition, formation of the films to be the layers of the light-emitting device can be performed stably.

### [Structure Example of Display Apparatus]

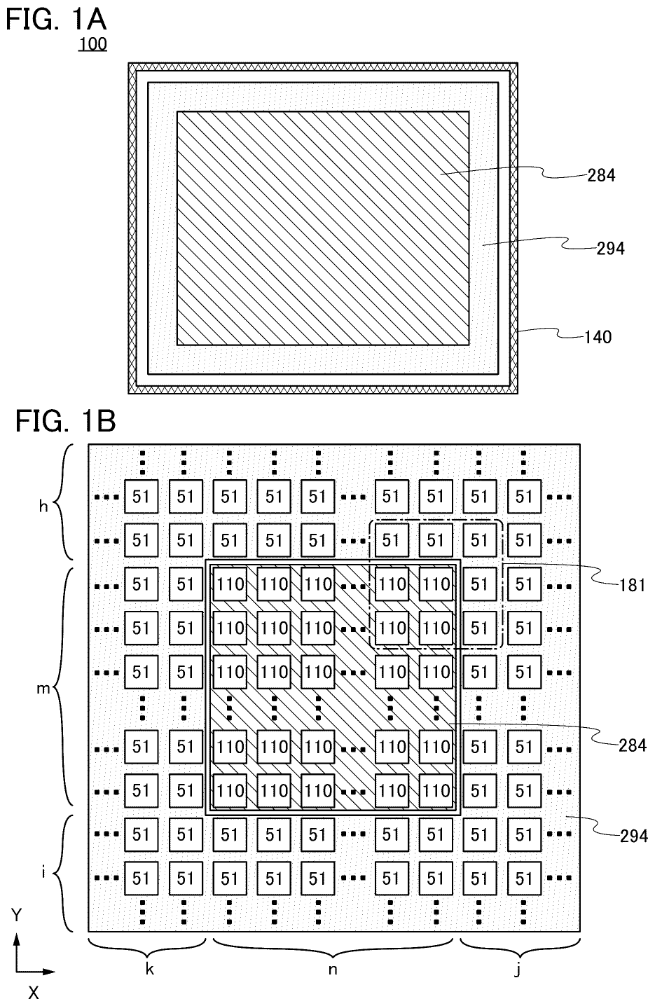

The display apparatus of one embodiment of the present invention is described with reference to FIG. 1 to FIG. 16 and the like.

FIG. 1A is a top view of a display apparatus 100. The display apparatus 100 includes a pixel portion 284 provided with a plurality of pixels 110, a dummy pixel portion 294 outside the pixel portion 284, and a connection portion 140 outside the pixel portion 284 and the dummy pixel portion 294. The connection portion 140 can also be referred to as a cathode contact portion.

The dummy pixel portion 294 is a non-display region that does not contribute to display, for example. The expression “the dummy pixel portion 294 does not contribute to display” means that, for example, light is not emitted even when voltage is applied to a stacked-layer structure in which an EL layer is held between conductive layers in the dummy pixel of the dummy pixel portion 294. As another example, the expression means that the stacked-layer structure in which the EL layer is held between the conductive layers in the pixel of the dummy pixel portion does not have a function of emitting light. As another example, the expression means a state where light from the pixel of the dummy pixel portion is blocked. The light can be blocked by providing a light-blocking portion overlapping with the dummy pixel portion, for example.

In this specification and the like, the row direction and the column direction are sometimes referred to as the X direction and the Y direction, respectively. The X direction and the Y direction intersect with each other and are, for example, orthogonal to each other (see FIG. 1B).

The display apparatus 100 includes a display portion. The display portion in the display apparatus 100 is a region of the display apparatus 100 where an image is displayed and is a region where light emitted from the pixels provided in the pixel portion 284 can be seen. It is preferable that the pixels included in the dummy pixel portion 294 not emit light. For example, even in the case where the pixels in the dummy pixel portion 294 each have a stacked-layer structure of a pixel electrode and an EL layer, it is preferable that the stacked-layer structure not function as a light-emitting device. Meanwhile, in the case where light from the dummy pixel portion 294 can be seen, a region including the dummy pixel portion 294 is sometimes referred to as a display portion.

In the case where the pixel of the dummy pixel portion 294 includes a light-emitting device and the light-emitting device emits light, at least part of light emitted from the dummy pixel portion 294 may be blocked in the display apparatus 100.

FIG. 1B illustrates the pixel portion 284 and the dummy pixel portion 294 that is placed outside the pixel portion 284. The plurality of pixels 110 are arranged in a matrix in the pixel portion 284. The plurality of dummy pixels 51 are arranged in the dummy pixel portion 294.

The plurality of pixels 110 in the pixel portion 284 are arranged in n columns, for example. The dummy pixel portion 294 is provided in a column on at least one of the left side and the right side of the plurality of pixels 110 arranged in the n columns. For example, the dummy pixels 51 are placed inj columns on the right side of the plurality of pixels 110 arranged in the n columns. As another example, the dummy pixels 51 are placed in k columns on the left side of the plurality of pixels 110 arranged in the n columns. As another example, the dummy pixels 51 are placed inj columns on the right side of the plurality of pixels 110 arranged in the n columns, and the dummy pixels are placed in k columns on the left side of the plurality of pixels 110 arranged in the n columns.

The plurality of pixels 110 in the pixel portion 284 are arranged in m rows, for example. The dummy pixel portion 294 is provided in a row at least one of above and below the plurality of pixels 110 arranged in them rows. For example, the dummy pixels 51 are placed in h rows above the plurality of pixels 110 arranged in the m rows. As another example, the dummy pixels 51 are placed in i rows below the plurality of pixels 110 arranged in the m rows. As another example, the dummy pixels 51 are placed in h rows above the plurality of pixels 110 arranged in the m rows, and the dummy pixels are placed in i rows below the plurality of pixels 110 arranged in them rows.

Here, m and n are each an integer greater than or equal to 1. Furthermore, h, i, k, and j are each an integer greater than or equal to 1, preferably an integer greater than or equal to 2, further preferably an integer greater than or equal to 3, and for example, an integer greater than or equal to 10. Alternatively, one of h and i may be 0, in which case the other is an integer greater than or equal to 1, preferably an integer greater than or equal to 2, further preferably an integer greater than or equal to 3, and for example, an integer greater than or equal to 10. In addition, one of k and j may be 0, in which case the other is an integer greater than or equal to 1, preferably an integer greater than or equal to 2, further preferably an integer greater than or equal to 3, and for example, an integer greater than or equal to 10.

In FIG. 1B, the plurality of dummy pixels 51 are arranged along a row or a column in which the plurality of pixels 110 are arranged. In other words, the pixels 110 and the dummy pixels 51 are arranged in a matrix across the pixel portion 284 and the dummy pixel portion 294.

Arranging the pixels 110 and the dummy pixels 51 in a matrix across the pixel portion 284 and the dummy pixel portion 294 around the pixel portion 284 inhibits the adverse effect of the peripheral region of the pixel portion 284 and allows the formation process of the light-emitting devices to be stably performed. Thus, the display quality of the display apparatus 100 can be improved. In addition, the reliability of the display apparatus 100 can be improved. Furthermore, the performance of the light-emitting devices included in the display apparatus 100 can be improved.

Although the dummy pixels 51 are preferably arranged along a row or a column in which the pixels 110 are arranged as illustrated in FIG. 1B, the dummy pixels 51 may be placed at slightly deviated positions. In that case, for example, the interval in the X direction and the interval in the Y direction between the plurality of dummy pixels 51 adjacent to each other are substantially the same as the interval in the X direction and the interval in the Y direction between the plurality of pixels 110 adjacent to each other, respectively.

Not all the layers of the dummy pixel 51 need to be formed in the same patterns as the layers of the pixel 110. The dummy pixel 51 may have the structure of the pixel 110 from which some layers are omitted.

The dummy pixel 51 includes a pixel electrode and an EL layer, for example. The dummy pixel 51 may include only part of the EL layer.

The pixel electrode of the dummy pixel 51 may have substantially the same top surface as the pixel electrode of the pixel 110, for example. Alternatively, the area of the pixel electrode of the dummy pixel 51 in a top view may be substantially the same as the area of the pixel electrode of the pixel 110 in the top view. For example, the difference between the area of the pixel electrode of the pixel 110 in the top view and the area of the pixel electrode of the dummy pixel 51 in the top view is preferably less than or equal to 30%, further preferably less than or equal to 20%, still further preferably less than or equal to 10% of the area of the pixel electrode of the pixel 110 in the top view.

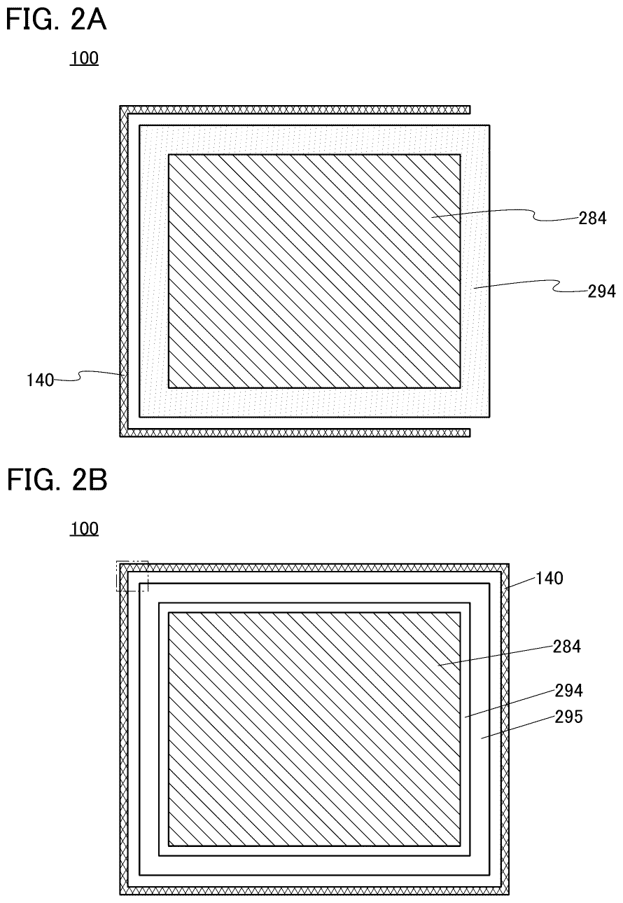

Although FIG. 1A illustrates an example in which the connection portion 140 is provided to surround the four sides of the display portion in the top view, one embodiment of the present invention is not particularly limited thereto. The connection portion 140 is provided on at least one of the upper side, the right side, the left side, and the lower side of the display portion in the top view. For example, as illustrated in FIG. 2A, the connection portion 140 may be provided along three sides. The top surface shape of the connection portion 140 can be a belt-like shape, an L shape, a U shape, a frame-like shape, or the like. The number of connection portions 140 can be one or more.

As illustrated in FIG. 2B, the display apparatus 100 may include a dummy pixel portion 295 outside the dummy pixel portion 294. The dummy pixel portion 295 includes a plurality of dummy pixels 52. Note that the shape of the dummy pixel 52 differs from that of the dummy pixel 51.

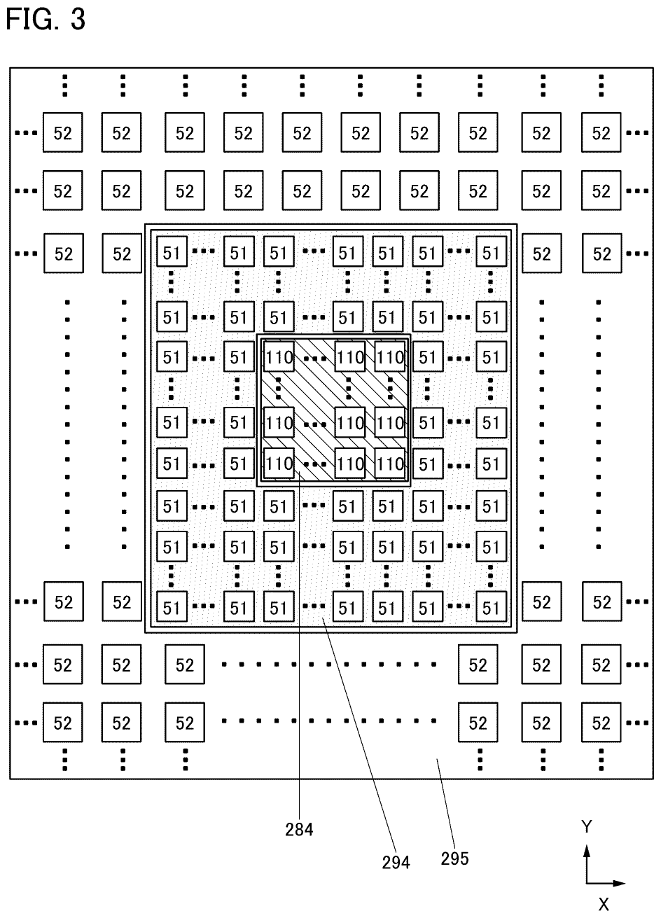

FIG. 3 illustrates the pixel portion 284, the dummy pixel portion 294 placed outside the pixel portion 284, and the dummy pixel portion 295 placed outside the dummy pixel portion 294. The plurality of dummy pixels 52 are arranged in the dummy pixel portion 295. FIG. 3 illustrates an example in which the area of the dummy pixel 52 is larger than that of the dummy pixel 51.

The dummy pixel 52 has a simpler structure than the dummy pixel 51, for example. The minimum line width in the dummy pixel portion 295 can be larger than that in the dummy pixel portion 294. Furthermore, the minimum distance between patterns can be longer in the dummy pixel portion 295 than in the dummy pixel portion 294. The dummy pixel portion 295 can be sometimes fabricated at a lower cost than the dummy pixel portion 294, for example. The pattern of the dummy pixel portion 295 can be formed using, for example, a light-exposure apparatus having lower resolution than a light-exposure apparatus for forming the pattern of the dummy pixel portion 294.

The dummy pixel electrode of the dummy pixel 52 has a simpler top surface shape than the dummy pixel electrode of the dummy pixel 51 in some cases. The top surface shape of the dummy pixel electrode of the dummy pixel 52 is tetragonal, for example. Alternatively, the top surface shape is rectangular, for example. Further alternatively, the top surface shape is square, for example. Further alternatively, the top surface shape is circular or elliptical, for example.

In the dummy pixel 52, an EL layer or a layer including part of the EL layer is not necessarily formed to have an island shape. The dummy pixel 52 does not include an EL layer in some cases.

It is preferable that the pixels included in the dummy pixel portion 295 not emit light. For example, even in the case where the pixels in the dummy pixel portion 295 each have a stacked-layer structure of a pixel electrode and an EL layer, it is preferable that the stacked-layer structure not function as a light-emitting device.

In the dummy pixel portion 295, the plurality of dummy pixels 52 are preferably arranged in a matrix. In FIG. 3, the intervals in the X direction and the Y direction at which the plurality of dummy pixels 52 are arranged are different from the intervals in the X direction and the Y direction at which the plurality of pixels 110 are arranged in the pixel portion 284.

Although the plurality of dummy pixels 52 are arranged in the X direction or the Y direction in the example illustrated in FIG. 3, the plurality of dummy pixels 52 may be arranged along a line forming an angle less than or equal to 450 with the X-axis (the axis in the X direction). Alternatively, the plurality of dummy pixels 52 may be arranged along a line forming an angle less than or equal to 45° with the Y-axis (the axis in the Y direction).

Alternatively, the plurality of dummy pixels 52 may be arranged radially.

Note that the dummy pixel portion 294 is sometimes omitted from the display apparatus 100. In such a case, for example, the dummy pixel portion 294 is not provided outside the pixel portion 284, and the dummy pixel portion 295 is placed outside and adjacent to the pixel portion 284.

The dummy pixel portion is sometimes referred to as an adhesion-improving region. Alternatively, the dummy pixel portion is sometimes referred to as a region that includes an adhesion-improving layer. The dummy pixel portion is sometimes referred to as a high adhesion region or an anchoring region.

Alternatively, the dummy pixel portion can be referred to as a region where patterned conductive layers are arranged, for example. Alternatively, the dummy pixel portion can be referred to as a region where a plurality of island-shaped conductive layers are arranged, for example. Alternatively, the dummy pixel portion can be referred to as a region where a plurality of island-shaped conductive layers and EL layers over the island-shaped conductive layers are arranged, for example.

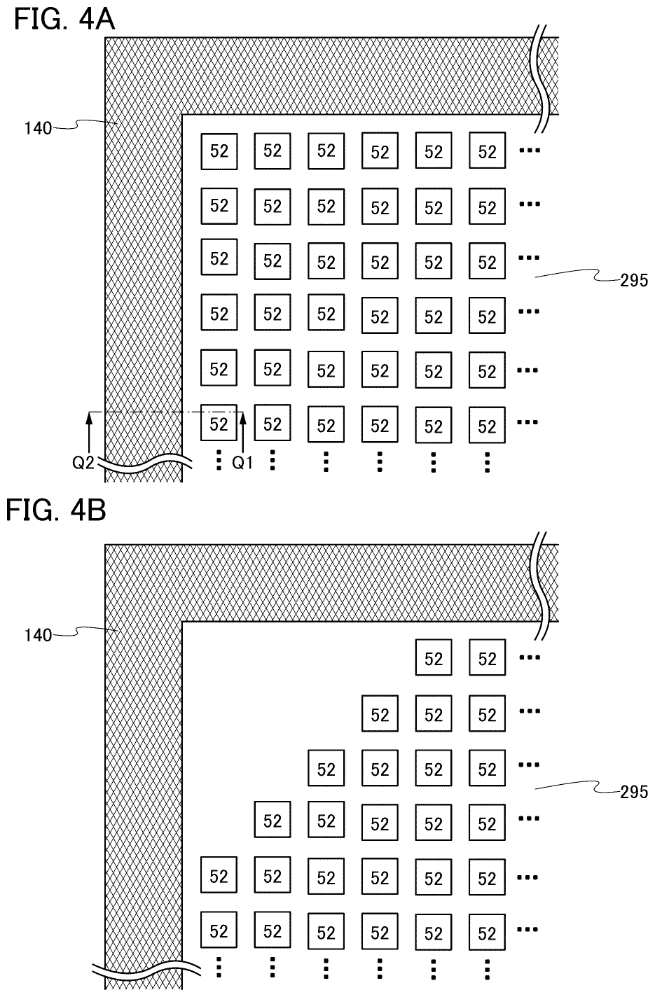

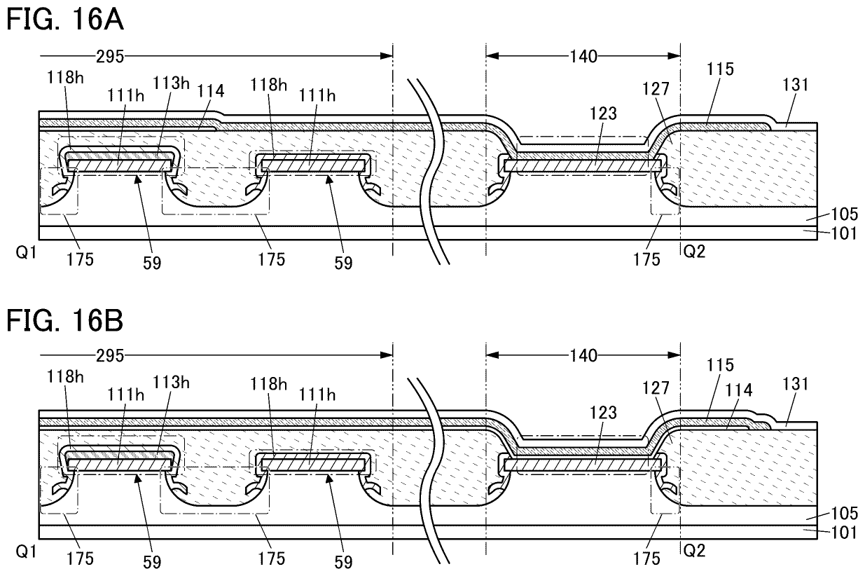

FIG. 4A and FIG. 4B are enlarged views of a region surrounded by a dashed double-dotted line in FIG. 2B. FIG. 16 illustrates examples of a cross-sectional view of a portion indicated by the dashed-dotted line Q1-Q2 in FIG. 4A. FIG. 16 will be described later.

In FIG. 4A, the dummy pixels 52 of the dummy pixel portion 295 are provided close to the connection portion 140. As illustrated in FIG. 4B, a structure may be employed in which the dummy pixels 52 are not provided in the vicinity of a corner of a region inside the connection portion 140. For example, a structure may be employed in which the dummy pixels 52 are not provided in a region within 20 μm from the corner.

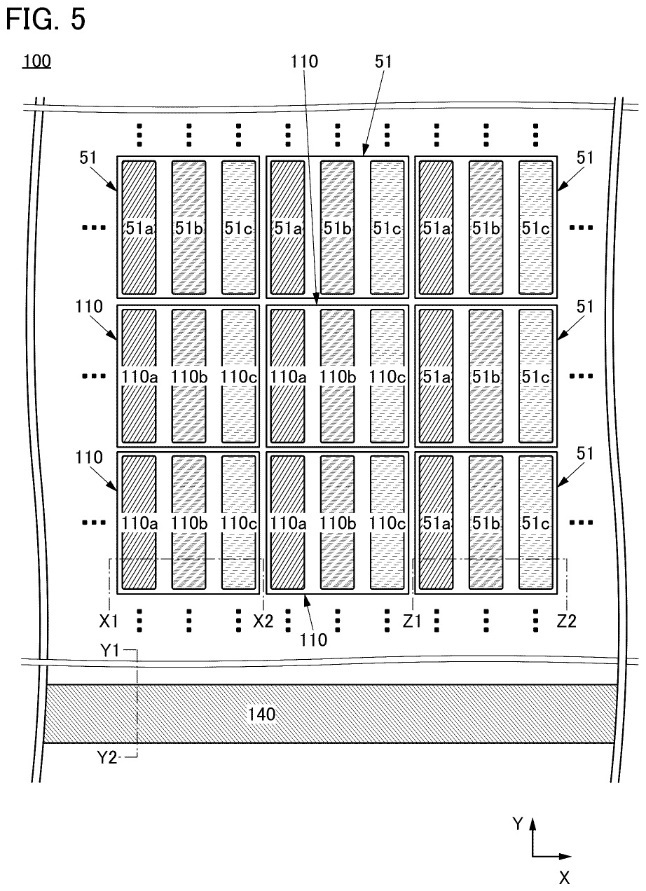

FIG. 5 is a top view of the display apparatus 100, and the top view includes an enlarged view of a region 181 surrounded by a dashed-dotted line in FIG. 1B.

The pixel 110 illustrated in FIG. 5 employs stripe arrangement. The pixel 110 illustrated in FIG. 5 is composed of three subpixels: a subpixel 110a, a subpixel 110b, and a subpixel 110c. The subpixel 110a, the subpixel 110b, and the subpixel 110c include light-emitting devices that emit light of different colors. FIG. 5 illustrates subpixels arranged in two rows and six columns, which form the pixels 110 in two rows and two columns.

The subpixels 110a, 110b, and 110c can be subpixels of three colors of red (R), green (G), and blue (B) or subpixels of three colors of yellow (Y), cyan (C), and magenta (M), for example. The number of types of subpixels is not limited to three, and four or more types of subpixels may be used. Examples of the four subpixels include subpixels of four colors of R, G, B, and white (W), subpixels of four colors of R, G, B, and Y, and four subpixels of R, G, B, and infrared light (IR).

The dummy pixel 51 illustrated in FIG. 5 is composed of three dummy subpixels 51a, 51b, and 51c. In FIG. 5, the dummy subpixels are arranged to be adjacent to the right side and the upper side of the subpixels arranged in two rows and six columns.

Each of the dummy subpixels 51a, 51b, and 51c includes a dummy light-emitting device, for example. In some cases, the dummy light-emitting device has a structure similar to that of the light-emitting device included in the subpixels 110a, 110b, and 110c and the like.

The dummy light-emitting device is not electrically connected to a driver circuit of the display apparatus in some cases. A signal from the driver circuit is not supplied to the dummy light-emitting device in some cases. A common electrode is not provided over the dummy light-emitting device in some cases.

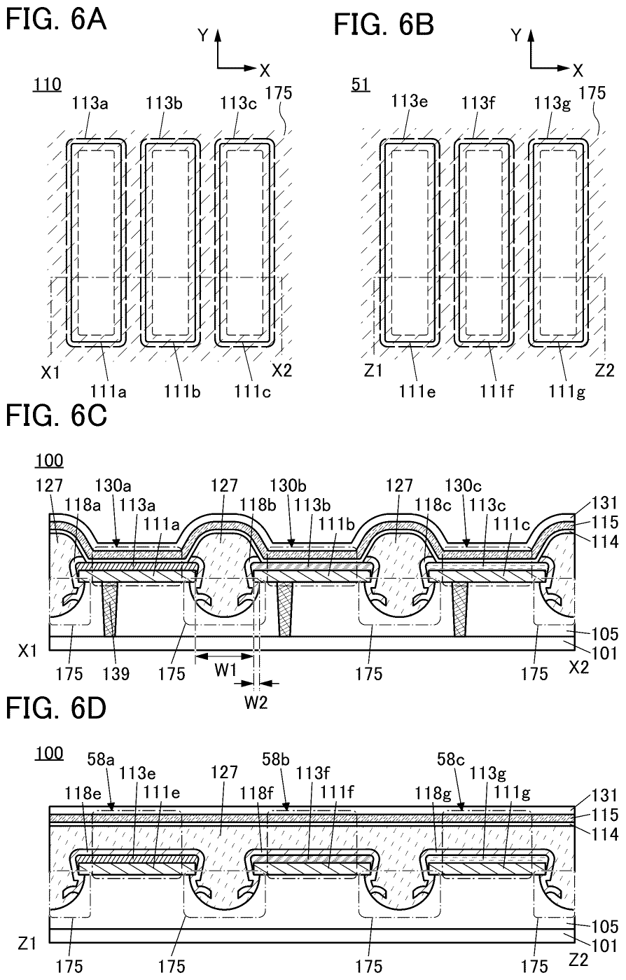

FIG. 6A illustrates an example of a top view of the pixel 110. FIG. 6B illustrates an example of atop view of the dummy pixel 51. FIG. 6C illustrates an example of a cross-sectional view of a portion indicated by the dashed-dotted line X1-X2 in FIG. 6A. FIG. 6D illustrates an example of a cross-sectional view of a portion indicated by the dashed-dotted line Z1-Z2 in FIG. 6B. Note that for clarity of the drawing, some components are omitted in the top views of FIG. 6A, FIG. 6B, and the like.

Each of the subpixels 110a, 110b, and 110c preferably includes a light-emitting device. Each of the light-emitting devices includes a pixel electrode, an EL layer, and a common electrode.

The subpixel 110a includes a light-emitting device 130a, the subpixel 110b includes a light-emitting device 130b, and the subpixel 110c includes a light-emitting device 130c. The details of the structures of the light-emitting device 130a, the light-emitting device 130b, and the light-emitting device 130c will be described later.

The light-emitting device 130a (not illustrated in FIG. 6A) includes a pixel electrode 111a and a layer 113a over the pixel electrode 111a. The light-emitting device 130b (not illustrated in FIG. 6A) includes a pixel electrode 111b and a layer 113b over the pixel electrode 111b. The light-emitting device 130c (not illustrated in FIG. 6A) includes a pixel electrode 111c and a layer 113c over the pixel electrode 111c. The layer 113a, the layer 113b, and the layer 113c are each an island-shaped layer that includes at least part of the EL layer and preferably includes a light-emitting layer.

In the pixel 110 and the like, an insulating layer 105 has a groove 175 provided to surround the light-emitting device 130. The details of the groove 175 will be described later.

FIG. 6B illustrates an example of a top view of the dummy pixel 51. It is preferable that the dummy subpixel 51a, the dummy subpixel 51b, and the dummy subpixel 51c include a dummy light-emitting device 58a, a dummy light-emitting device 58b, and a dummy light-emitting device 58c, respectively.

The dummy light-emitting device 58a (not illustrated in FIG. 6B) includes a pixel electrode 111e and a layer 113e over the pixel electrode 111e. The dummy light-emitting device 58b (not illustrated in FIG. 6B) includes a pixel electrode 111f and a layer 113f over the pixel electrode 111f. The dummy light-emitting device 58c (not illustrated in FIG. 6B) includes a pixel electrode 111g and a layer 113g over the pixel electrode 111g.

In FIG. 6A and FIG. 6B, the pixel electrodes 111a, 111b, and 111c have substantially the same top surface shapes as the pixel electrodes 111e, 111f, and 111g, respectively.

Note that the pixel electrode of the dummy light-emitting device does not have a function of an electrode in some cases. Specifically, for example, the pixel electrode of the dummy pixel is not electrically connected to a wiring or a circuit of the display apparatus in some cases.

The pixel electrode 111e and the pixel electrode 111a are formed by processing the same conductive film, for example. The pixel electrode 11 if and the pixel electrode 111b are formed by processing the same conductive film, for example. The pixel electrode 111g and the pixel electrode 111c are formed by processing the same conductive film, for example. The pixel electrodes obtained by processing the same conductive film preferably have substantially the same thickness. The difference in thickness between two pixel electrodes obtained by processing the same conductive film is preferably less than or equal to 30%, further preferably less than or equal to 20%, still further preferably less than or equal to 10% of the thickness of one of the pixel electrodes.

The layer 113e and the layer 113a can be formed by processing the same film, the layer 113f and the layer 113b can be formed by processing the same film, and the layer 113g and the layer 113c can be formed by processing the same film. In the case where the layer 113a, the layer 113b, and the layer 113c contain light-emitting materials exhibiting different colors, the layer 113e, the layer 113f, and the layer 113g contain light-emitting materials exhibiting different colors.

Alternatively, the layer 113e, the layer 113f, and the layer 113g may be formed by processing the same film as the layer 113a, i.e., a film to be the layer 113a (a film 113af described later). In this case, the layer 113e, the layer 113f, and the layer 113g contain the light-emitting material exhibiting the same color even when the layer 113a, the layer 113b, and the layer 113c contain light-emitting materials exhibiting different colors.

The layer 113e, the layer 113f, and the layer 113g may be formed by processing the same film as the layer 113b, i.e., a film to be the layer 113b (a film 113bf described later). The layer 113e, the layer 113f, and the layer 113g may be formed by processing the same film as the layer 113c, i.e., a film to be the layer 113c (a film 113cf described later).

Two layers formed by processing the same film contain the same material, for example. Two layers formed by processing the same film have the same stacked-layer structure, for example.

In FIG. 6A and FIG. 6B, the layer 113e, the layer 113f, and the layer 113g have substantially the same top surface shapes as the layer 113a, the layer 113b, and the layer 113c, respectively.

Even in the case where the dummy light-emitting device includes a layer formed of the same material as an EL layer or a layer formed of the same material as part of the EL layer, the dummy light-emitting device does not have a function of emitting light in some cases.

As illustrated in FIG. 6C, the display apparatus 100 includes the insulating layer 105, the light-emitting device 130a, the light-emitting device 130b, and the light-emitting device 130c.

The light-emitting device 130a includes the pixel electrode 111a, the layer 113a, a common layer 114, and a common electrode 115. The light-emitting device 130b includes the pixel electrode 111b, the layer 113b, the common layer 114, and the common electrode 115. The light-emitting device 130c includes the pixel electrode 111c, the layer 113c, the common layer 114, and the common electrode 115. The common layer 114 and the common electrode 115 are provided in common in the light-emitting device 130a, the light-emitting device 130b, and the light-emitting device 130c.

The layer 113a, the layer 113b, and the layer 113c each preferably contain a light-emitting organic compound. For example, it is preferable that the layer 113a contain at least a light-emitting organic compound that emits light with intensity in the red wavelength range, the layer 113b contain at least a light-emitting organic compound that emits light with intensity in the green wavelength range, and the layer 113c contain at least a light-emitting organic compound that emits light with intensity in the blue wavelength range.

The pixel electrode 111a, the pixel electrode 111b, and the pixel electrode 111c are provided for the respective light-emitting devices. The common layer 114 and the common electrode 115 are each provided as a continuous layer shared by the light-emitting devices. A conductive film having a property of transmitting visible light is used for either the pixel electrodes or the common electrode 115, and a conductive film having a reflective property is used for the other. When the pixel electrodes have a light-transmitting property and the common electrode 115 has a reflective property, a bottom-emission display apparatus can be obtained. In contrast, when the pixel electrodes have a reflective property and the common electrode 115 has a light-transmitting property, a top-emission display apparatus can be obtained. Note that when both the pixel electrodes and the common electrode 115 have a light-transmitting property, a dual-emission display apparatus can be obtained.

A protective layer 131 is provided over the common electrode 115 to cover the light-emitting device 130a, the light-emitting device 130b, and the light-emitting device 130c. The protective layer 131 has a function of preventing diffusion of impurities such as water into the light-emitting devices from above.

An insulating layer 118a, an insulating layer 118b, an insulating layer 118c, and an insulating layer 127 illustrated in FIG. 6C will be described later.

Note that hereafter, in describing matters common to the light-emitting device 130a, the light-emitting device 130b, and the light-emitting device 130c, the alphabets are omitted from the reference numerals and the term “light-emitting device 130” is used in some cases. Similarly, the pixel electrode 111a, the pixel electrode 111b, and the pixel electrode 111c are also described using the term “pixel electrode 111” in some cases. Similarly, the layer 113a, the layer 113b, and the layer 113c are described using the term “layer 113” in some cases.

The combination of colors of light emitted from the light-emitting devices 130 is not limited to the above, and for example, colors such as cyan, magenta, and yellow may also be used. Although the example of three colors of red (R), green (G), and blue (B) is shown in the above, the number of colors of light emitted from the light-emitting devices 130 included in the display apparatus 100 may be two or four or more.

The pixel electrode 111 functions as a lower electrode, and the common electrode 115 functions as an upper electrode. As the common electrode 115, an electrode having properties of transmitting and reflecting visible light can be used, for example. The layer 113 contains alight-emitting compound.

As the light-emitting device 130, it is possible to use an electroluminescent device having a function of emitting light in accordance with current flowing into the layer 113 when a potential difference is applied between the pixel electrode 111 and the common electrode 115. In particular, an organic EL element that uses a light-emitting organic compound in the layer 113 is preferably used. The light-emitting device 130 is preferably an element emitting monochromatic light, which has one peak in the visible light region of the emission spectrum. Note that the light-emitting device 130 may be an element emitting white light, which has two or more peaks in the visible light region of the emission spectrum.

A potential for controlling the amount of light emitted from the light-emitting device 130 is independently supplied to the pixel electrodes 111 provided in the light-emitting devices 130.

The layer 113 and the common layer 114 can each independently include one or more of an electron-injection layer, an electron-transport layer, a hole-injection layer, and a hole-transport layer. For example, it is possible to employ a structure in which the layer 113 has a stacked-layer structure of a hole-injection layer, a hole-transport layer, a light-emitting layer, and an electron-transport layer from the pixel electrode 111 side and the common layer 114 includes an electron-injection layer.

The common electrode 115 is formed to have properties of transmitting and reflecting visible light. For example, a metal film or an alloy film that is thin enough to transmit visible light can be used. Alternatively, a light-transmitting conductive film (e.g., a metal oxide film) may be stacked over such a film.

The insulating layer 105 has a groove provided to surround the light-emitting device 130. Part of the groove provided in the insulating layer 105 includes a region that overlaps with the pixel electrode of the light-emitting device 130 and is positioned below the pixel electrode. As illustrated in FIG. 6A, FIG. 6C, and the like, the insulating layer 105 is provided with the groove 175, and the groove 175 is provided between two adjacent light-emitting devices 130. In FIG. 6A, the groove 175 is provided, for example, between the light-emitting device 130a and the light-emitting device 130b, between the light-emitting device 130b and the light-emitting device 130c, between the light-emitting device 130c and the light-emitting device 130a, between two adjacent light-emitting devices 130a, between two adjacent light-emitting devices 130b, and between two adjacent light-emitting devices 130c.

Moreover, the insulating layer 105 has a groove provided to surround the dummy light-emitting device 58. Part of the groove provided in the insulating layer 105 includes a region that overlaps with the pixel electrode of the dummy light-emitting device 58 and is positioned below the pixel electrode. As illustrated in FIG. 6B, FIG. 6D, and the like, the insulating layer 105 is provided with the groove 175, and the groove 175 is provided between two adjacent dummy light-emitting devices 58. In FIG. 6B, the groove 175 is provided, for example, between the dummy light-emitting device 58a and the dummy light-emitting device 58b, between the dummy light-emitting device 58b and the dummy light-emitting device 58c, between the dummy light-emitting device 58c and the dummy light-emitting device 58a, between two adjacent dummy light-emitting devices 58a, between two adjacent dummy light-emitting devices 58b, and between two adjacent dummy light-emitting devices 58c.

An insulating layer 118e, an insulating layer 118f, an insulating layer 118g, and the insulating layer 127 illustrated in FIG. 6D will be described later.

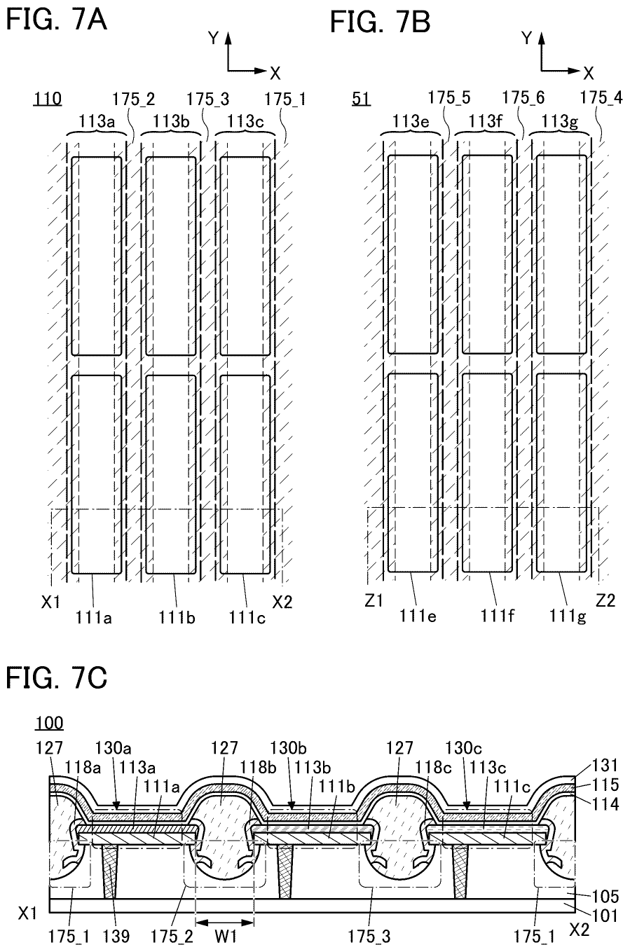

Although FIG. 6A illustrates an example in which the subpixel 110a includes one island-shaped layer 113a formed using the film 113af, the subpixels 110a arranged vertically may include one continuous island-shaped 113a as illustrated in FIG. 7A. That is, the island-shaped layer covering the pixel electrodes 111a included in a plurality of subpixels 110a arranged vertically may be formed using the film 113af. Similarly, the island-shaped layer covering the pixel electrodes 111b included in a plurality of subpixels 110b arranged vertically may be formed using the film 113bf. Similarly, the island-shaped layer covering the pixel electrodes 111c included in a plurality of subpixels 110c arranged vertically may be formed using the film 113cf.

FIG. 7A illustrates an example of a top view of the pixel 110 different from that in FIG. 6A. FIG. 7B illustrates an example of a top view of the dummy pixel 51 different from that in FIG. 6B. FIG. 7C illustrates an example of a cross-sectional view of a portion indicated by the dashed-dotted line X1-X2 in FIG. 7A.

In the top view illustrated in FIG. 7A, the layer 113a, the layer 113b, and the layer 113c have a stripe shape extending in the Y direction. The grooves 175 extend in the Y direction and are provided in a region positioned between the layer 113a and the layer 113b, a region positioned between the layer 113b and the layer 113c, and a region positioned between the layer 113c and the layer 113a. The groove 175 provided in the region positioned between the layer 113c and the layer 113a is represented as a groove 175_1 in FIG. 7A and the like. The groove 175 provided in the region positioned between the layer 113a and the layer 113b is represented as a groove 175_2 in FIG. 7A and the like. The groove 175 provided in the region positioned between the layer 113b and the layer 113c is represented as a groove 1753 in FIG. 7A and the like.

In the case where the arrangement of the light-emitting devices 130 (the pixel electrodes 111) is the stripe pattern illustrated in FIG. 7A and the like, adjacent light-emitting devices of the same color are arranged in the Y direction and adjacent light-emitting devices of different colors are arranged in the X direction, which is perpendicular to the Y direction. The X direction can be referred to as the X1-X2 direction illustrated in FIG. 7A and the like.

As illustrated in FIG. 7B, the island-shaped layer covering a plurality of dummy subpixels 51e that are arranged vertically may be formed using the film 113af Similarly, the island-shaped layer covering a plurality of dummy subpixels 51f that are arranged vertically may be formed using the film 113bf Similarly, the island-shaped layer covering a plurality of dummy subpixels 51g that are arranged vertically may be formed using the film 113cf.

The island-shaped layer covering the plurality of subpixels 110a and the plurality of dummy subpixels 51e that are arranged vertically may be formed using the film 113af. Similarly, the island-shaped layer covering the plurality of subpixels 110b and the plurality of dummy subpixels 51f that are arranged vertically may be formed using the film 113bf. Similarly, the island-shaped layer covering the plurality of subpixels 110c and the dummy subpixels 51g that are arranged vertically may be formed using the film 113cf.

In the top view illustrated in FIG. 7B, the layer 113e, the layer 113f, and the layer 113g have a stripe shape extending in the Y direction. The grooves 175 extend in the Y direction and are provided in a region positioned between the layer 113e and the layer 113f, a region positioned between the layer 113f and the layer 113g, and a region positioned between the layer 113g and the layer 113e. The groove 175 provided in the region positioned between the layer 113g and the layer 113e is represented as a groove 175_4 in FIG. 7B and the like. The groove 175 provided in the region positioned between the layer 113e and the layer 113f is represented as a groove 175_5 in FIG. 7B and the like. The groove 175 provided in the region positioned between the layer 113f and the layer 113g is represented as a groove 175_6 in FIG. 7B and the like.

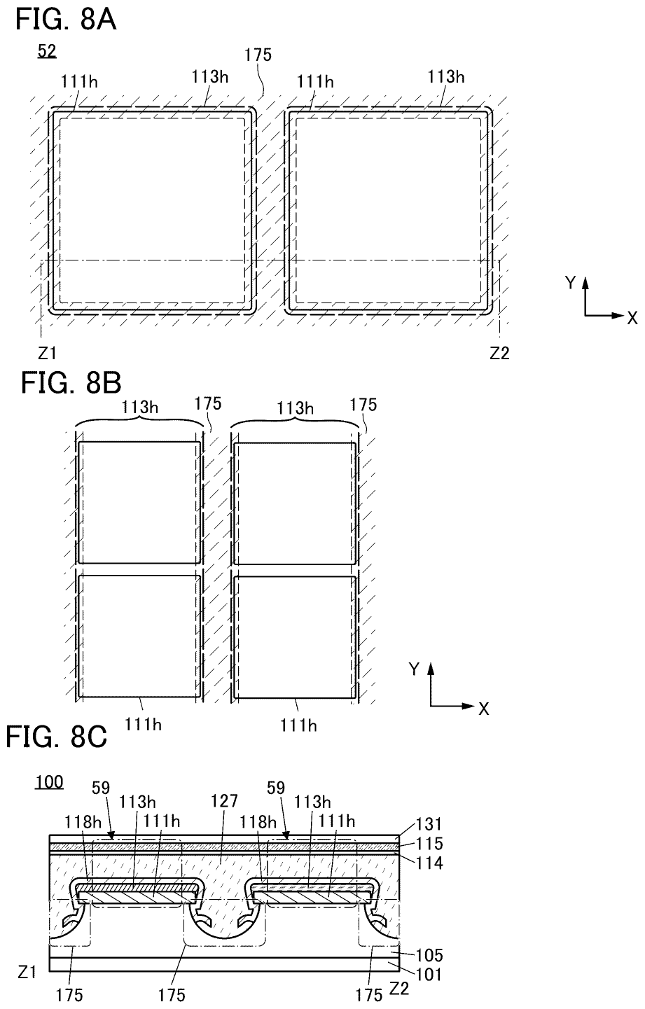

FIG. 8A illustrates an example of a top view of the dummy pixel 52. The dummy pixel 52 illustrated in FIG. 8A includes a pixel electrode 111h and a layer 113h. FIG. 8C illustrates an example of a cross-sectional view of a portion indicated by the dashed-dotted line Z1-Z2 in FIG. 8A.

In the example illustrated in FIG. 8A, the dummy pixel 52 includes no subpixel. The layer 113h is preferably formed using the same film as any one of the layers 113a, 113b, and 113c.

Alternatively, the layer 113h is sometimes formed using a film in which two or more of the film 113af, the film 113bf, and the film 113cf are stacked.

In FIG. 8A, the groove 175 is provided to surround the pixel electrode 111h. The groove 175 includes a region that is positioned below the pixel electrode 111h and overlapped by the pixel electrode 111h.

Although FIG. 8A illustrates an example in which the dummy pixel 52 includes one island-shaped layer 113h, the layer 113h may be provided to be shared by a plurality of dummy pixels without processing the layer 113h into an island shape for each dummy pixel. FIG. 8B illustrates an example in which the layer 113h has a stripe shape extending in the Y direction, a plurality of stripe-shaped layers 113h are arranged in the X direction, and the groove 175 is provided in a region positioned between two adjacent layers 113h. In FIG. 8B, the layer 113h extends in the Y direction while overlapping with the top surface of a plurality of pixel electrodes 111h arranged in the Y direction.

The shape of the pixel electrode 111h illustrated in FIG. 8A is different from that of the pixel electrode 111a or the like illustrated in FIG. 6A. The shape of the pixel electrode 111a is elongated in the Y direction, unlike the shape of the pixel electrode 111h.

The area of the pixel electrode 111h is different from the area of the pixel electrode 111a. In the top view, the pixel electrode 111h illustrated in FIG. 8A has a larger area than the pixel electrode 111a or the like illustrated in FIG. 6A. The area of the pixel electrode 111h is preferably greater than or equal to 0.6 times and less than or equal to 300 times (except one time) the area of the pixel electrode 111a, further preferably greater than or equal to two times and less than or equal to 100 times the area of the pixel electrode 111a.

The layer 113h includes at least part of an EL layer. The layer 113h can be formed by processing the same film as any of the layer 113a, the layer 113b, and the layer 113c, for example.

Hereinafter, a case is described in which pixel electrodes 111a, 111b, 111c, 111d (described later in Embodiment 3), 111e, 111f, 111g, and 111h are formed by processing the same film (hereinafter a conductive film 111af). The conductive film 111af is formed over the pixel portion 284, the dummy pixel portion 294, and the dummy pixel portion 295.

The conductive film 111af is partly removed by etching or the like to be the pixel electrodes 111a, 111b, 111c, 111d (described later in Embodiment 3), 111e, 111f, 111g, and 111h.

The layer 113a and other layers are provided over the pixel electrodes. The layer 113e and the layer 113a can be formed by processing the same film (hereinafter the film 113af), for example. The layer 113h may also be formed by processing the film 113af. The layer 113a, the layer 113e, and the layer 113h obtained by processing the film 113af preferably have substantially the same thickness. The difference in thickness between the layer 113a and the layer 113e and the difference in thickness between the layer 113a and the layer 113h are each preferably less than or equal to 30%, further preferably less than or equal to 20%, still further preferably less than or equal to 10% of the thickness of the layer 113a.

The conductive film 113af is formed over the pixel portion 284, the dummy pixel portion 294, and the dummy pixel portion 295. The adhesion of the film 113af depends on the shape of the pixel electrode as the formation surface, the size of the pixel electrode, the density of a plurality of pixel electrodes arranged, the length of the periphery of the pixel electrode, the area ratio between the region provided with the pixel electrode and the region not provided with the pixel electrode, and the like.

For example, the adhesion of the film 113af sometimes decreases in the case where, around the pixel portion 284, the conductive film 111af remains over a wide area without being patterned or the conductive film 111af is patterned to have a significantly larger area than the pixel electrode 111a or the like.

By contrast, when the conductive film 111af around the pixel portion 284 is removed and does not remain, a layer positioned below the pixel electrodes, e.g., an interlayer film, might be successively over-etched in the etching step at the time of the processing the layers 113a, 113b, and 113c formed over the pixel electrodes, which may cause a wiring, an electrode, or the like positioned below the interlayer film to be unintentionally exposed. Thus, a conductive layer such as a pixel electrode is preferably formed over the interlayer film or the like.

In the pixel 110, the ratio of the area of the region covered with the pattern of the pixel electrode to the area of the region not covered with the pattern of the pixel electrode is referred to as a ratio Sa. In the case where the pixel 110 includes subpixels, the area of the region covered with the pattern of the pixel electrode can be calculated using the sum of the areas of the regions covered with the pixel electrodes of the subpixels. In the dummy pixel 51, the ratio of the area of the region covered with the pattern of the pixel electrode to the area of the region not covered with the pattern of the pixel electrode is referred to as a ratio Sd1. In the case where the dummy pixel 51 includes subpixels, the area of the region covered with the pattern of the pixel electrode can be calculated using the sum of the areas of the regions covered with the pixel electrodes of the dummy subpixels. In the dummy pixel 52, the ratio of the area of the region covered with the pattern of the pixel electrode to the area of the region not covered with the pattern of the pixel electrode is referred to as a ratio Sd2.

The ratio Sd1 and the ratio Sd2 are each preferably greater than or equal to 0.5 times the ratio Sa, for example.

A value obtained by normalizing the length of the periphery of the pixel electrode of the pixel 110 with the area of the pixel electrode is referred to as a length La. Here, the length of the periphery is the sum of the lengths of the sides of the pixel electrode, for example. In the case where the pixel 110 includes subpixels, calculation is performed using the sum of the lengths of the peripheries of the pixel electrodes included in the subpixels. A value obtained by normalizing the length of the periphery of the pixel electrode of the dummy pixel 51 with the area of the pixel electrode is referred to as a length Ld1. In the case where the dummy pixel 51 includes dummy subpixels, calculation is performed using the sum of the lengths of the peripheries of the pixel electrodes included in the dummy subpixels. A value obtained by normalizing the length of the periphery of the pixel electrode of the dummy pixel 52 with the area of the pixel electrode is referred to as a length Ld2.

The length Ld1 and the length Ld2 are each preferably greater than or equal to 0.5 times the length La, for example.

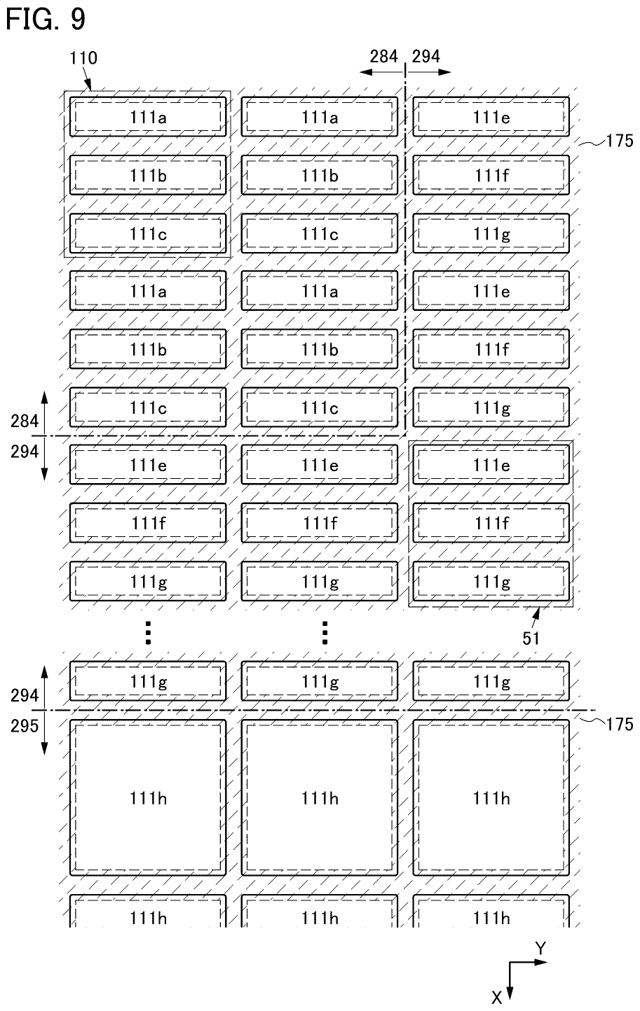

FIG. 9 is a top view of a region including the pixel portion 284, the dummy pixel portion 294, and the dummy pixel portion 295. For clarity of the drawing, FIG. 9 shows the pixel electrodes 111a, 111b, and 111c included in the light-emitting devices 130, the pixel electrodes 111e, 111f, and 111g included in the dummy light-emitting devices 58, the pixel electrode 111h included in a dummy light-emitting device 59, and the groove 175 and omits the other components.

The groove 175 is provided in a region positioned between the pixel electrodes included in two adjacent light-emitting devices 130. The groove 175 is provided in a region positioned between the pixel electrodes included in two adjacent dummy light-emitting devices 58. The groove 175 is provided in a region positioned between the pixel electrodes included in two adjacent dummy light-emitting devices 59. The groove 175 is also provided in a region positioned between the pixel electrodes included in the light-emitting device 130 and the dummy light-emitting device 58 adjacent to each other. The groove 175 is also provided in a region positioned between the pixel electrodes included in the dummy light-emitting device 58 and the dummy light-emitting device 59 adjacent to each other.

Although FIG. 9 does not show the layers 113a, 113b, and 113c, FIG. 6A, for example, can be referred to for the arrangement relation between the layers 113a, 113b, and 113c, the pixel electrodes 111a, 111b, and 111c, and the groove 175. Although FIG. 9 does not show the layers 113e, 113f, and 113g, FIG. 6B, for example, can be referred to for the arrangement relation between the layers 113e, 113f, and 113g, the pixel electrodes 111e, 111f, and 111g, and the groove 175. Although FIG. 9 does not show the layer 113h, FIG. 8A, for example, can be referred to for the arrangement relation between the layer 113h, the pixel electrode 111h, and the groove 175.

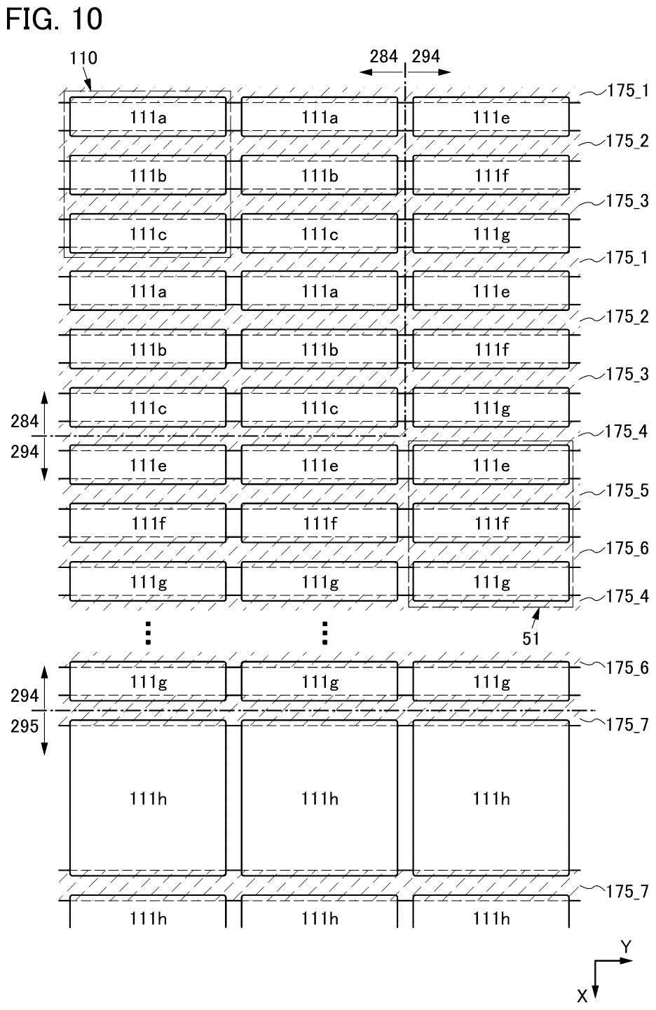

FIG. 10 is a top view of a region including the pixel portion 284, the dummy pixel portion 294, and the dummy pixel portion 295. FIG. 10 differs from FIG. 9 in that stripe-shaped grooves 175 are provided. In the structure illustrated in FIG. 10, a plurality of grooves 175 extending in the Y direction are provided. In FIG. 10, the plurality of grooves 175 are referred to as grooves 1751, 175_2, 1753, 1754, 1755, 1756, and 1757.

The groove 175 is provided in a region positioned between the pixel electrodes included in two light-emitting devices 130 adjacent in the X direction. The structure illustrated in FIG. 10 includes the groove 175_2 and the groove 175_3 that are provided to be adjacent to a plurality of pixel electrodes 111b arranged in the Y direction. The groove 175_2 is provided in a region positioned between a plurality of pixel electrodes 111a arranged in the Y direction and a plurality of pixel electrodes 111b arranged in the Y direction. The groove 175_3 is provided in a region positioned between a plurality of pixel electrodes 111b arranged in the Y direction and a plurality of pixel electrodes 111c arranged in the Y direction. The groove 175_1 is provided to include a region adjacent to a plurality of pixel electrodes 111a arranged in the Y direction, and is provided side by side with the groove 175_2, with the pixel electrodes 111a therebetween.

The groove 175 is provided in a region positioned between the pixel electrodes included in two dummy light-emitting devices 58 adjacent in the X direction. The structure illustrated in FIG. 10 includes the groove 175_5 and the groove 175_6 that are provided to be adjacent to a plurality of pixel electrodes 111f arranged in the Y direction. The groove 1755 is provided in a region positioned between a plurality of pixel electrodes 111e arranged in the Y direction and a plurality of pixel electrodes 111f arranged in the Y direction. The groove 1756 is provided in a region positioned between a plurality of pixel electrodes 111f arranged in the Y direction and a plurality of pixel electrodes 111g arranged in the Y direction. The groove 175_4 is provided to include a region adjacent to a plurality of pixel electrodes 111e arranged in the Y direction, and is provided side by side with the groove 1755, with the pixel electrodes 111e therebetween.

The groove 175 is provided in a region positioned between the pixel electrodes included in two dummy light-emitting devices 59 adjacent in the X direction. The structure illustrated in FIG. 10 includes the groove 175_7 provided to be adjacent to a plurality of pixel electrodes 111h arranged in the Y direction.

The groove 175 is also provided in a region positioned between the pixel electrodes included in the light-emitting device 130 and the dummy light-emitting device 58 adjacent to each other. In the structure illustrated in FIG. 10, part of the groove 1754 is positioned in a region at the boundary between the pixel portion 284 and the dummy pixel portion 294.

The groove 175 is also provided in a region positioned between the pixel electrodes included in the dummy light-emitting device 58 and the dummy light-emitting device 59 adjacent to each other. In the structure illustrated in FIG. 10, the groove 175_7 is positioned in a region at the boundary between the dummy pixel portion 294 and the dummy pixel portion 295.

Although FIG. 10 does not show the layers 113a, 113b, and 113c, FIG. 7A, for example, can be referred to for the arrangement relation between the layers 113a, 113b, and 113c, the pixel electrodes 111a, 111b, and 111c, and the grooves 175.

Although FIG. 10 does not show the layers 113e, 113f, and 113g, FIG. 7B, for example, can be referred to for the arrangement relation between the layers 113e, 113f, and 113g, the pixel electrodes 111e, 111f, and 111g, and the grooves 175.

Although FIG. 10 does not show the layer 113h, FIG. 8B, for example, can be referred to for the arrangement relation between the layer 113h, the pixel electrode 111h, and the groove 175.

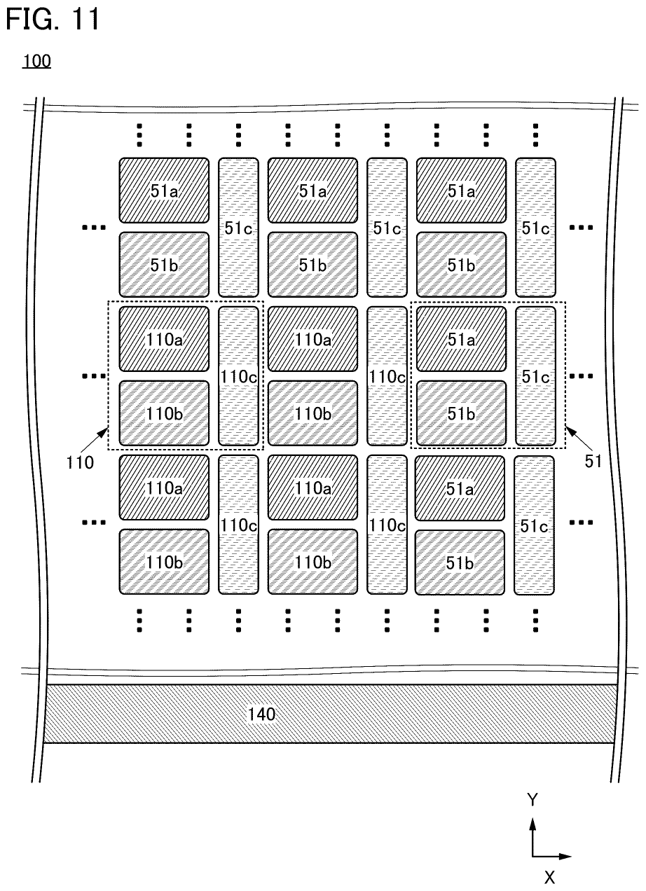

Although subpixels of different colors are arranged in the X direction and subpixels of the same color are arranged in the Y direction in the example illustrated in FIG. 5, a structure illustrated in FIG. 11 may be employed in which subpixels of a first color and subpixels of a second color are arranged alternately in the Y direction in a first column and subpixels of a third color are arranged in the Y direction in a second column, and the first column and the second column are alternately arranged. In FIG. 11, the pixel has a rectangular shape, and one pixel includes a subpixel of the first color and a subpixel of the second color that are adjacent to each other in the Y direction, and a subpixel of the third color adjacent to the two subpixels in the X direction.

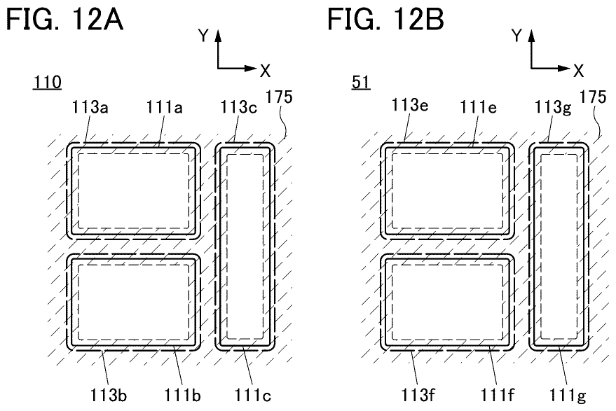

FIG. 12A is a top view illustrating a structure example of the pixel electrodes 111a, 111b, and 111c, the layers 113a, 113b, and 113c, and the groove 175 included in the pixel 110 illustrated in FIG. 11. FIG. 12B is a top view illustrating a structure example of the pixel electrodes 111e, 111f, and 111g, the layers 113e, 113f, and 113g, and the groove 175 included in the dummy pixel 51 illustrated in FIG. 11.

Note that the pixel 110, the dummy pixel 51, and the dummy pixel 52 do not necessarily have a rectangular shape. For example, the pixel 110, the dummy pixel 51, and the dummy pixel 52 may have any of a variety of shapes, including a tetragon, a triangle, a circle, and an ellipse.

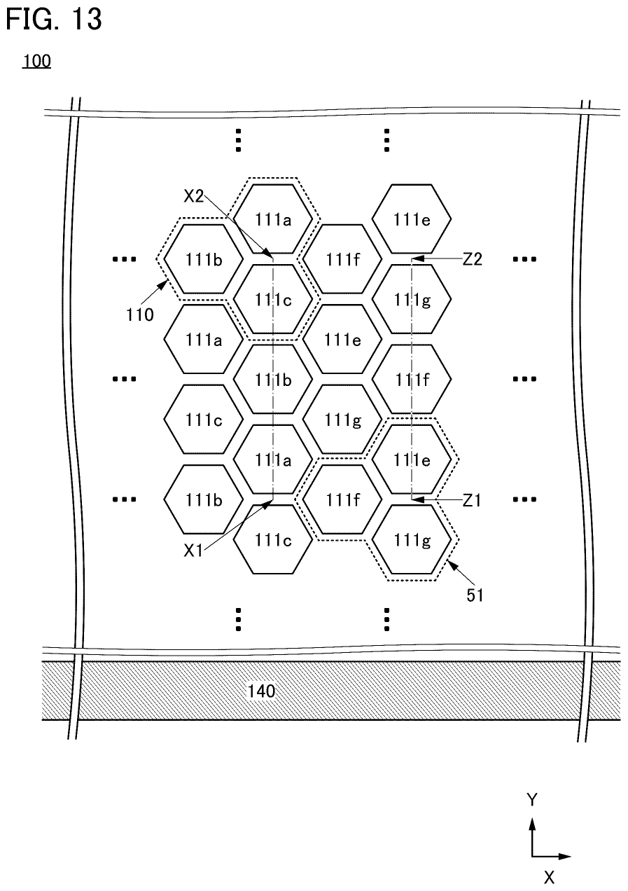

FIG. 13 illustrates an example of a structure in which the arrangement of the pixel electrodes 111 (the light-emitting devices 130) is a delta pattern.

As illustrated in FIG. 6C, FIG. 6D, FIG. 7C, and FIG. 8C, the insulating layer 105 is provided over a layer 101 in the display apparatus 100. The layer 101 is preferably a layer including transistors. The light-emitting devices 130a, 130b, and 130c and the dummy light-emitting devices 58a, 58b, 58c, and 59 are provided over the insulating layer, and the protective layer 131 is provided to cover the light-emitting devices and the dummy light-emitting devices. The dummy light-emitting device 58a corresponds to the dummy subpixel 51a, the dummy light-emitting device 58b corresponds to the dummy subpixel 51b, and the dummy light-emitting device 58c corresponds to the dummy subpixel 51c, for example. The insulating layer 127 is provided in a region between adjacent light-emitting devices. The insulating layer 127 is preferably provided to fill a depressed portion between adjacent light-emitting devices. Providing the insulating layer 127 can improve the coverage with the common electrode 115, the common layer 114, and the protective layer 131. Providing the insulating layer 127 inhibits a short circuit between the pixel electrode and the common electrode in some cases. The expression “the display apparatus 100 has an opening portion in the insulating layer 127 in a region overlapping with the pixel electrode” can be used. When the insulating layer 127 is provided with the opening portion, an upper layer of the light-emitting device, e.g., the common layer 114, can be provided to be over and in contact with an island-shaped EL layer or an island-shaped layer including part of the EL layer in the opening portion.

The insulating layer 127 includes a region provided to fill the groove 175. The effect of the shape of the groove 175 makes the insulating layer 127 less likely to peel off, hence, the adhesion between the insulating layer 127 and the insulating layer 105 can be increased in the groove 175. Thus, when the insulating layer 105 has the groove 175, peeling of the insulating layer 127 can be inhibited, so that the reliability of the display apparatus 100 can be increased. In addition, the display quality of the display apparatus 100 can be increased.

The display apparatus 100 also includes a plug 139. The layer 101 and the pixel electrode 111 of the light-emitting device 130 are electrically connected to each other through the plug 139. The plug 139 is formed to be embedded in an opening provided in the insulating layer 105. The pixel electrode 111 is provided in contact with the top surface of the plug 139.

Part of the groove 175 is preferably positioned below the pixel electrode 111. In other words, the groove 175 preferably includes a region positioned below the pixel electrode 111.

For example, the groove 175 positioned between a first pixel electrode and a second pixel electrode preferably includes a first region overlapping with the first pixel electrode, a second region overlapping with the second pixel electrode, and a third region overlapping with neither the first pixel electrode nor the second pixel electrode. The third region is positioned between the first region and the second region. The first region can be regarded as being positioned below the first pixel electrode. The second region can be regarded as being positioned below the second pixel electrode. Note that a light-emitting device including the first pixel electrode and a light-emitting device including the second pixel electrode emit light of different colors.

As illustrated in FIG. 6C and the like, the groove 175 preferably has a downward-convex arc shape in the cross-sectional view of the display apparatus 100, for example. Note that the downward-convex arc shape can be regarded as a concave curved shape. Furthermore, the downward-convex arc shape includes a downward-convex semicircular shape. With the groove 175 having such a shape, the layer 113 in the display apparatus 100 is divided between adjacent light-emitting devices of different colors. Thus, current flowing through the layer 113 (also referred to as leakage current) between adjacent light-emitting devices of different colors can be prevented. Accordingly, light emission caused by the leakage current can be inhibited, so that display with high contrast can be obtained. Furthermore, even in the case where the resolution is increased, the range of choices for materials can be widened since the layer 113 can be formed using a material with high conductivity, which facilitates an improvement in efficiency, a reduction in power consumption, and an improvement in reliability.

The layer 113 may be patterned into an island shape by deposition using a shadow mask such as a metal mask; however, it is particularly preferable to employ a processing method using no metal mask. Accordingly, an extremely fine pattern can be formed; thus, resolution and an aperture ratio can be improved as compared to the formation method using a metal mask. A typical example of such a processing method is a photolithography method. Alternatively, a formation method such as a nanoimprinting method or a sandblasting method can be used.

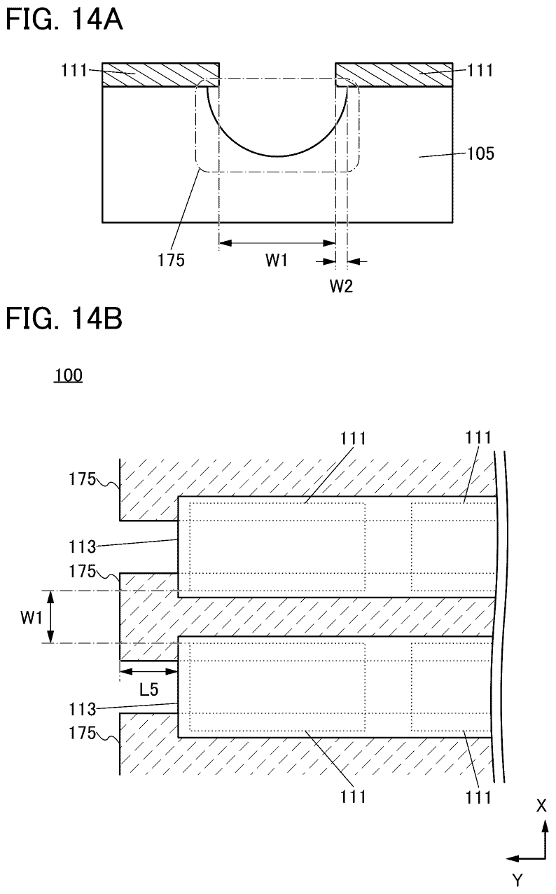

FIG. 14A is a schematic cross-sectional view of the groove 175 and its vicinity in the display apparatus 100. Note that for clarity of the drawing, some components (the layer 113, the common electrode 115, and the like) are omitted in FIG. 14A.

A width W1 illustrated in FIG. 14A is the width of the groove 175 in a region not overlapping with the pixel electrode 111 in the X1-X2 direction. Note that in the display apparatus 100 illustrated in FIG. 14A, the width W1 can be rephrased as the shortest distance between the end portions of the pixel electrodes 111 that face each other. A width W2 illustrated in FIG. 14A is the width of the groove 175 in a region overlapping with the pixel electrode 111 in the X1-X2 direction.

The width W1 is preferably greater than twice the thickness of the layer 113. In the case where the thickness of the layer 113 is 100 nm, for example, the width W1 is greater than or equal to 200 nm and less than or equal to 1200 nm, preferably greater than or equal to 200 nm and less than or equal to 1000 nm, further preferably greater than or equal to 200 nm and less than or equal to 900 nm. This enables the groove 175 to cause disconnection of the layer 113 so that the layer 113 can be formed over each pixel electrode 111. At this time, the layer 113 is placed to cover a side surface and the top surface of the pixel electrode 111. Note that in this specification and the like, a state where a layer covers a structure body indicates a state where the layer covers part of an end surface of the structure body or a state where the layer completely covers the structure body so as to surround the end surface of the structure body. Examples of the layer here include an insulating layer, an insulating film, and a conductive layer. Examples of the structure body include a conductive layer, an organic layer, a stack, and a light-emitting device.

Note that the width W1 is preferably adjusted as appropriate in accordance with the processing accuracy at the time of forming the groove 175, the deposition conditions of the layer 113, and the like. In the case where the layer 113 is formed by a vacuum evaporation method, for example, disconnection of the layer 113 might occur even when the width W1 is less than twice the thickness of the layer 113. For example, in the case where the thickness of the layer 113 is 100 nm, the width W1 may be greater than or equal to 100 nm and less than or equal to 1200 nm, less than or equal to 1000 nm, or less than or equal to 900 nm.

The width W2 is set to a width such that disconnection of the layer 113 occurs. The width W2 is preferably greater than or equal to 2 nm, greater than or equal to 5 nm, greater than or equal to 10 nm, or greater than or equal to 20 nm, and less than or equal to 500 nm, less than or equal to 300 nm, less than or equal to 200 nm, less than or equal to 150 nm, or less than or equal to 100 nm.

Accordingly, it is possible to achieve an extremely high-resolution display apparatus in which pixels including one or more light-emitting devices are arranged with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

In the display apparatus 100, the layer 113 is preferably formed so as not to be divided but to be continuous between the light-emitting devices exhibiting the same color. For example, the layer 113 is preferably formed in a stripe pattern. The common electrode 115 is preferably formed so as not to be divided but to be continuous between the light-emitting devices exhibiting the same color, and is preferably formed so as not to be divided but to be continuous between the light-emitting devices. Thus, the common electrode 115 for all the light-emitting devices can be supplied with a predetermined potential without being in a floating state.

In the cross-sectional view illustrated in FIG. 6C and the like, the end portions of the layer 113 are positioned outward from the end portions of the pixel electrode 111. The end portions of the layer 113 cover the end portions of the pixel electrode 111. When the end portions of the layer 113 are positioned outward from the end portions of the pixel electrode 111, a short circuit between the pixel electrode 111 and the common electrode 115 can be inhibited.

The display apparatus 100 includes the insulating layer 118a over the layer 113a, the insulating layer 118b over the layer 113b, the insulating layer 118c over the layer 113c, and the insulating layer 127.

Note that hereinafter, in describing matters common to the insulating layer 118a, the insulating layer 118b, and the insulating layer 118c, the alphabets are omitted from the reference numerals and the term “insulating layer 118” is used in some cases.

The insulating layer 118 is provided to cover at least part of the top surface of the layer 113. In addition, the insulating layer 118 is provided to overlap with at least part of the groove 175 near the layer 113.

As illustrated in FIG. 6C, the insulating layer 118a over the layer 113a is provided to overlap with at least part of the groove 175, the insulating layer 118b over the layer 113b is provided to overlap with at least part of the groove 175, and the insulating layer 118c over the layer 113c is provided to overlap with at least part of the groove 175.

As illustrated in FIG. 7C, the insulating layer 118a over the layer 113a is provided to overlap with at least part of the groove 175_1 and at least part of the groove 175_2, the insulating layer 118b over the layer 113b is provided to overlap with at least part of the groove 175_2 and at least part of the groove 1753, and the insulating layer 118c over the layer 113c is provided to overlap with at least part of the groove 175_3 and at least part of the groove 175_1.

In the cross-sectional view in the X1-X2 direction, the insulating layer 118 includes a region in contact with at least part of the top surface of the layer 113 and a region in contact with a side surface of the layer 113. The insulating layer 118 includes a region in contact with the insulating layer 105 below the light-emitting device 130 (specifically, the pixel electrode 111), below the dummy light-emitting device 58 (specifically, the pixel electrode 111), or below the dummy light-emitting device 59 (specifically, the pixel electrode 111).

When the insulating layer 118 is favorably attached to the insulating layer 105 in the region in contact with the insulating layer 105, separation of the insulating layer 118 from the layer 113 can be inhibited, resulting in an increase in the reliability of the display apparatus 100. In addition, the display quality of the display apparatus 100 can be increased.

The insulating layers 118a, 118b, and 118c have opening portions reaching the respective layers 113a, 113b, and 113c. In the opening portions, the layers 113a, 113b, and 113c are in contact with the common layer 114. The common electrode 115 includes regions overlapping with the layers 113a, 113b, and 113c in the opening portions.

The insulating layer 118 includes a region positioned between the insulating layer 127 and the layer 113 and functions as a protective film for preventing the insulating layer 127 from being in contact with the layer 113. In the case where a resin layer is used as the insulating layer 127, contact between the layer 113 and the insulating layer 127 might result in dissolution of the layer 113 by, for example, an organic solvent used at the time of forming the insulating layer 127. Thus, providing the insulating layer 118 between the layer 113 and the insulating layer 127 as described in this embodiment can protect the side surfaces of the layer 113.

Between adjacent light-emitting devices of different colors, the side surfaces of the layers 113 face each other with the insulating layer 127 therebetween. The insulating layer 127 is positioned between the adjacent light-emitting devices of different colors and is provided to fill a region between the end portions of the layers 113 and a region between two layers 113. The insulating layer 127 has a top surface with a smooth convex shape. The common layer 114 and the common electrode 115 are provided to cover the top surface of the insulating layer 127.

The insulating layer 127 includes a region in contact with the insulating layer 105 between the adjacent light-emitting devices of different colors. For example, the insulating layer 127 includes a region in contact with the insulating layer 105 in a portion positioned between the layer 113a and the layer 113b. The insulating layer 127 includes a region in contact with the insulating layer 105 in a portion positioned between the layer 113b and the layer 113c. The insulating layer 127 includes a region in contact with the insulating layer 105 in a portion positioned between the layer 113c and the layer 113a.

FIG. 14B is a schematic top view of end portions of the grooves 175 and their vicinities in the Y direction. Although the structure illustrated in FIG. 14B shows an example where the layer 113 has a stripe shape, the layer 113 may have an island shape. Note that for clarity of the drawing, some components are omitted in the top view of FIG. 14B.

As illustrated in FIG. 14B, the groove 175 preferably extends beyond the end portion of the layer 113 in the Y direction. In FIG. 14B, the distance between the end portion of the groove 175 and the end portion of the layer 113 is denoted by a distance L5. With this structure, the EL layers adjacent in the X direction can be separated.

Although not illustrated in FIG. 14B, the common electrode 115 preferably extends beyond the end portion of the groove 175 in the Y direction. In other words, the groove 175 is preferably shorter than the end portion of the common electrode 115 in the Y direction.

The dummy light-emitting device does not necessarily have a function of emitting light. Thus, over the dummy light-emitting device, an opening portion is not necessarily provided in the insulating layer 127. In FIG. 6D and FIG. 8C, an opening portion is not provided in the insulating layer 127. Accordingly, the insulating layer 127 widely covers, for example, the pixel electrode 111 of the dummy light-emitting device. For example, in a plan view, the insulating layer 127 does not have an opening portion overlapping with the pixel electrode 111 of the dummy light-emitting device and covers 100% of the area of the pixel electrode 111 of the dummy light-emitting device. Note that a structure may be employed in which the insulating layer 127 does not cover part of the pixel electrode 111 of the dummy light-emitting device. For example, the insulating layer 127 preferably covers 50% or more or 70% or more of the area of the pixel electrode 111.

As another example, the insulating layer 127 has an opening portion over the pixel electrode 111 of the light-emitting device, and does not have an opening portion over the pixel electrode 111 of the dummy light-emitting device. In such a case, over the pixel electrode 111 of the light-emitting device, the insulating layer 127 has an opening portion overlapping with 30% or more, preferably 50% or more of the area of the pixel electrode 111. The opening portion overlaps with a substantially middle portion of the pixel electrode 111 of the light-emitting device, for example, in which case the insulating layer 127 is not provided in the substantially middle portion of the pixel electrode 111 in the light-emitting device.

In the case where the insulating layer 127 does not have an opening portion over the pixel electrode 111 of the dummy light-emitting device, the insulating layer 127 overlaps with a substantially middle portion of the pixel electrode 111 of the dummy light-emitting device, for example.

Alternatively, the insulating layer 127 may have an opening portion overlapping with the pixel electrode 111 of the dummy light-emitting device.

In FIG. 6D and FIG. 8C, the insulating layer 127 is provided to cover the island-shaped layers 113e, 113f, 113g, and 113h of the dummy light-emitting devices, and the common layer 114 and the common electrode 115 are provided over the insulating layer 127. In each of the dummy light-emitting device 58a, the dummy light-emitting device 58b, and the dummy light-emitting device 58c in FIG. 6D, the insulating layers provided between the light-emitting layer and the common electrode inhibit carrier transfer. Thus, the dummy light-emitting devices do not have a function of emitting light in some cases.

Since the dummy light-emitting device does not necessarily have a function of emitting light, the pixel electrode 111 of the dummy light-emitting device is not necessarily electrically connected to a semiconductor element or the like provided in the layer 101. Accordingly, the plug 139 is not necessarily provided in a region overlapping with the dummy light-emitting device.

In FIG. 6C and the like, the light-emitting device 130a includes the pixel electrode 111a over the insulating layer 105, the island-shaped layer 113a over the pixel electrode 111a, the common layer 114 over the island-shaped layer 113a, and the common electrode 115 over the common layer 114. In the light-emitting device 130a, the layer 113a and the common layer 114 can be collectively referred to as an EL layer. The pixel electrode 111a is in contact with, for example, the top surface of the insulating layer 105 in at least part of a light-emitting region of the light-emitting device 130a.

In FIG. 6C and the like, the light-emitting device 130b includes the pixel electrode 111b over the insulating layer 105, the island-shaped layer 113b over the pixel electrode 111b, the common layer 114 over the island-shaped layer 113b, and the common electrode 115 over the common layer 114. In the light-emitting device 130b, the layer 113b and the common layer 114 can be collectively referred to as an EL layer. The pixel electrode 111b is in contact with, for example, the top surface of the insulating layer 105 in at least part of a light-emitting region of the light-emitting device 130b.

In FIG. 6C and the like, the light-emitting device 130c includes the pixel electrode 111c over the insulating layer 105, the island-shaped layer 113c over the pixel electrode 111c, the common layer 114 over the island-shaped layer 113c, and the common electrode 115 over the common layer 114. In the light-emitting device 130c, the layer 113c and the common layer 114 can be collectively referred to as an EL layer. The pixel electrode 111c is in contact with, for example, the top surface of the insulating layer 105 in at least part of a light-emitting region of the light-emitting device 130c.

In FIG. 6D and the like, the dummy light-emitting device 58a includes the pixel electrode 111e over the insulating layer 105, the island-shaped layer 113e over the pixel electrode 111e, the common layer 114 over the island-shaped layer 113e, and the common electrode 115 over the common layer 114. In FIG. 6D and the like, the insulating layer 118e is provided to cover the island-shaped layer 113e, and the insulating layer 127 is provided over the insulating layer 118e. The insulating layer 127 is positioned between the layer 113e and the common layer 114. Here, the insulating layer 118e can be formed using a film to be the insulating layer 118a (an insulating film 118af described later).

In FIG. 6D and the like, the dummy light-emitting device 58b includes the pixel electrode 11 if over the insulating layer 105, the island-shaped layer 113f over the pixel electrode 111f, the common layer 114 over the island-shaped layer 113f, and the common electrode 115 over the common layer 114. In FIG. 6D and the like, the insulating layer 118f is provided to cover the island-shaped layer 113f, and the insulating layer 127 is provided over the insulating layer 118f. The insulating layer 127 is positioned between the layer 113f and the common layer 114. Here, the insulating layer 118f can be formed using a film to be the insulating layer 118b (an insulating film 118bf described later).

In FIG. 6D and the like, the dummy light-emitting device 58c includes the pixel electrode 111g over the insulating layer 105, the island-shaped layer 113g over the pixel electrode 111g, the common layer 114 over the island-shaped layer 113g, and the common electrode 115 over the common layer 114. In FIG. 6D and the like, the insulating layer 118g is provided to cover the island-shaped layer 113g, and the insulating layer 127 is provided over the insulating layer 118g. The insulating layer 127 is positioned between the layer 113g and the common layer 114. Here, the insulating layer 118g can be formed using a film to be the insulating layer 118c.

Although the island-shaped layers 113 are provided in the respective dummy light-emitting devices in the example shown in FIG. 6D, the layer 113 may be shared by a plurality of dummy light-emitting devices.

The dummy light-emitting device 59 illustrated in FIG. 8C corresponds to, for example, the dummy pixel 52. The dummy light-emitting device 59 includes the pixel electrode 111h over the insulating layer 105, the layer 113h over the pixel electrode 111h, the common layer 114 over the layer 113h, and the common electrode 115 over the common layer 114. FIG. 8C illustrates an example in which the insulating layer 118h is provided to cover the island-shaped layer 113h and the insulating layer 127 is provided over the insulating layer 118h. In FIG. 8C, the insulating layer 127 is positioned between the layer 113h and the common layer 114. Here, the insulating layer 118h can be formed using the film to be the insulating layer 118a (the insulating film 118af described later).

Note that the layer 113h may be provided in only some of the dummy light-emitting devices 59.

Although FIG. 6C and the like illustrate a plurality of cross sections of the insulating layer 127, the insulating layers 127 is one continuous layer when the display apparatus 100 is seen from above. In other words, the display apparatus 100 can have a structure including one insulating layer 127, for example. Note that the display apparatus 100 may include a plurality of insulating layers 127 that are separated from each other.

The display apparatus of one embodiment of the present invention can have any of the following structures: a top-emission structure where light is emitted in a direction opposite to the substrate where the light-emitting device is formed, a bottom-emission structure where light is emitted toward the substrate where the light-emitting device is formed, and a dual-emission structure where light is emitted toward both surfaces.

The layer 101 can have a stacked-layer structure in which a plurality of transistors are provided on a substrate and an insulating layer is provided to cover these transistors, for example. The insulating layer over the transistors may have a single-layer structure or a stacked-layer structure. FIG. 6C and the like illustrate the insulating layer 105 among the insulating layers over the transistors. The insulating layer 105 may have a depressed portion between adjacent light-emitting devices.

As the insulating layer 105, a variety of inorganic insulating films, such as an oxide insulating film, a nitride insulating film, an oxynitride insulating film, and a nitride oxide insulating film, can be suitably used. As the insulating layer 105, an oxide insulating film or an oxynitride insulating film, such as a silicon oxide film, a silicon oxynitride film, or an aluminum oxide film, can be used. Alternatively, as the insulating layer 105, a nitride insulating film or a nitride oxide insulating film, such as a silicon nitride film or a silicon nitride oxide film, can be used. As the insulating layer 105, two or more types of the above-described insulating films may be stacked to be used.

The insulating layer 105 may have a structure in which an oxide insulating film or an oxynitride insulating film is used as a first layer, a nitride insulating film or a nitride oxide insulating film is used as a second layer, an oxide insulating film or an oxynitride insulating film is used as a third layer, the second layer is positioned over the first layer, and the third layer is positioned over the second layer. Specifically, it is preferred that a silicon oxide film be used as the first layer and the third layer and a silicon nitride film be used as the second layer. The second layer preferably has a function of an etching protective film.

Note that in this specification and the like, an oxynitride refers to a material in which an oxygen content is higher than a nitrogen content, and a nitride oxide refers to a material in which a nitrogen content is higher than an oxygen content. For example, silicon oxynitride refers to a material in which an oxygen content is higher than a nitrogen content, and silicon nitride oxide refers to a material in which a nitrogen content is higher than an oxygen content.

Structure examples of the layer 101 will be described in Embodiment 3 and Embodiment 4.

The light-emitting devices 130a, 130b, and 130c emit light of different colors. Preferably, the light-emitting devices 130a, 130b, and 130c emit light of three colors, red (R), green (G), and blue (B), for example.

Examples of the light-emitting devices 130a, 130b, and 130c include an OLED (Organic Light Emitting Diode) and a QLED (Quantum-dot Light Emitting Diode). Examples of a light-emitting substance contained in the light-emitting device include a substance that exhibits fluorescence (a fluorescent material), a substance that exhibits phosphorescence (a phosphorescent material), and a substance that exhibits thermally activated delayed fluorescence (a thermally activated delayed fluorescent (TADF) material). As the TADF material, a material whose singlet excited state and triplet excited state are in a thermal equilibrium state may be used. Since such a TADF material has a short emission lifetime (excitation lifetime), it inhibits a reduction in the efficiency of a light-emitting device in a high-luminance region. As the light-emitting substance contained in the EL element, not only an organic compound but also an inorganic compound (a quantum dot material or the like) can be used.

The light-emitting device includes an EL layer between a pair of electrodes. The EL layer includes at least a light-emitting layer. In this specification and the like, one of the pair of electrodes is referred to as a pixel electrode and the other is referred to as a common electrode in some cases.

One of the pair of electrodes of the light-emitting device functions as an anode, and the other electrode functions as a cathode. The case where the pixel electrode functions as an anode and the common electrode functions as a cathode will be described below as an example in some cases.

There is no particular limitation on the structure of the light-emitting device in this embodiment, and the light-emitting device can have a single structure or a tandem structure.

Note that hereafter, in describing matters common to the light-emitting device 130a, the light-emitting device 130b, and the light-emitting device 130c, the alphabets are omitted from the reference numerals and the term “light-emitting device 130” is used in some cases. Similarly, the layer 113a, the layer 113b, and the layer 113c are described using the term “layer 113” in some cases. Similarly, the pixel electrode 111a, the pixel electrode 111b, and the pixel electrode 111c are described using the term “pixel electrode 111” in some cases.

In this embodiment, in the EL layers included in the light-emitting devices, the island-shaped layers provided in the respective light-emitting devices are referred to as the layer 113a, the layer 113b, and the layer 113c, and the layer shared by the plurality of light-emitting devices is referred to as the common layer 114. In this specification and the like, only the layer 113a, the layer 113b, and the layer 113c are sometimes referred to as EL layers, in which case the common layer 114 is not included in the EL layer.

The layer 113a, the layer 113b, and the layer 113c each include at least a light-emitting layer. It is preferable that the layer 113a include a red-light-emitting layer, the layer 113b include a green-light-emitting layer, and the layer 113c include a blue-light-emitting layer, for example.

The layer 113a, the layer 113b, and the layer 113c may each include one or more of a hole-injection layer, a hole-transport layer, a hole-blocking layer, a charge-generation layer, an electron-blocking layer, an electron-transport layer, and an electron-injection layer.

The layer 113a, the layer 113b, and the layer 113c may each include a hole-injection layer, a hole-transport layer, a light-emitting layer, and an electron-transport layer in this order, for example. In addition, an electron-blocking layer may be provided between the hole-transport layer and the light-emitting layer. Furthermore, an electron-injection layer may be provided over the electron-transport layer.

The layer 113a, the layer 113b, and the layer 113c may each include an electron-injection layer, an electron-transport layer, a light-emitting layer, and a hole-transport layer in this order, for example. In addition, a hole-blocking layer may be provided between the electron-transport layer and the light-emitting layer. Furthermore, a hole-injection layer may be provided over the hole-transport layer.

The layer 113a, the layer 113b, and the layer 113c each preferably include a light-emitting layer and a carrier-transport layer (an electron-transport layer or a hole-transport layer) over the light-emitting layer. Since the surfaces of the layer 113a, the layer 113b, and the layer 113c are exposed in the manufacturing process of the display apparatus, providing the carrier-transport layer over the light-emitting layer inhibits the light-emitting layer from being exposed on the outermost surface, so that damage to the light-emitting layer can be reduced. Thus, the reliability of the light-emitting device can be increased.

Alternatively, the layer 113a, the layer 113b, and the layer 113c each include a first light-emitting unit, a charge-generation layer, and a second light-emitting unit, for example. It is preferable that the layer 113a include two or more light-emitting units that emit red light, the layer 113b include two or more light-emitting units that emit green light, and the layer 113c include two or more light-emitting units that emit blue light, for example.

The second light-emitting unit preferably includes a light-emitting layer and a carrier-transport layer (an electron-transport layer or a hole-transport layer) over the light-emitting layer. Since the surface of the second light-emitting unit is exposed in the manufacturing process of the display apparatus, providing the carrier-transport layer over the light-emitting layer inhibits the light-emitting layer from being exposed on the outermost surface, so that damage to the light-emitting layer can be reduced. Thus, the reliability of the light-emitting device can be increased.

The common layer 114 includes, for example, an electron-injection layer or a hole-injection layer. Alternatively, the common layer 114 may include a stack of an electron-transport layer and an electron-injection layer, and may include a stack of a hole-transport layer and a hole-injection layer. The common layer 114 is shared by the light-emitting devices 130a, 130b, and 130c.

In the display apparatus of one embodiment of the present invention, the thicknesses of the layer 113a to the layer 113c can be different from one another. The thicknesses may be set in accordance with optical path lengths that intensify light emitted from the layer 113a to the layer 113c. This achieves a microcavity structure, so that the color purity of each light-emitting device can be increased.

The thicknesses of the layer 113 and the like may be set such that the optical path length is mλ/2 (m is a natural number) or the neighborhood thereof, where λ is the wavelength of light obtained from the light-emitting layer of the light-emitting device.

In the case where the light-emitting device 130a exhibits red, the light-emitting device 130b exhibits green, the light-emitting device 130c exhibits blue, and these light-emitting devices have the same m of mλ/2, the layer 113a emitting light whose wavelength is the longest can have the largest thickness, and the layer 113c emitting light whose wavelength is the shortest can have the smallest thickness, for example

The same does not necessarily apply to the case where the value of m is different between the light-emitting devices. For example, the layer 113c included in the light-emitting device exhibiting blue may have the largest thickness.

Note that without limitation to the above, the thicknesses of the layers can be adjusted in consideration of the wavelengths of light emitted by the light-emitting devices, the optical characteristics of the layers included in the light-emitting devices, the electrical characteristics of the light-emitting devices, and the like.

Note that the optical path length of the light-emitting device can be adjusted not only by making the thicknesses of the layer 113a to the layer 113c different from one another but also by making the thicknesses of the pixel electrode 111a to the pixel electrode 111c different from one another. Specifically, when the pixel electrode 111 is a reflective electrode having a stacked-layer structure of a conductive material having a reflective property (a reflective conductive film) and a conductive material having a light-transmitting property (a transparent conductive film), for example, making the thickness of the transparent conductive film different between the light-emitting devices that exhibit different colors enables the optical path lengths suitable for the colors.

In the case where the layer 113a to the layer 113c each include a light-emitting layer exhibiting white, the layer 113a to the layer 113c can be formed by processing the same layer, for example. The layer 113a to the layer 113c obtained by processing the same film have substantially the same thickness, for example. In such a case, the optical path lengths are preferably adjusted by adjusting the thicknesses of the transparent conductive films included in the pixel electrodes. For example, a structure may be employed in which the pixel electrode 111a has the largest thickness, the pixel electrode 111c has the smallest thickness, and the pixel electrode 111b has a smaller thickness than the pixel electrode 111a and a larger thickness than the pixel electrode 111c.

Also in the subpixels provided in the dummy pixel portion 294, the thickness of the pixel electrode 111 can be different between the dummy subpixels. Since the dummy pixels included in the dummy pixel portion do not necessarily have a function of emitting light, the pixel electrodes of different dummy subpixels in the dummy pixel portion 294 may have substantially the same thickness, in which case the process can be simplified.

The optical path length in the light-emitting device depends on the total thickness of the transparent conductive film included in the pixel electrode 111, the layer 113, and the common layer 114, for example.

For simplicity, drawings and the like in this specification do not clearly show the difference in the thicknesses of the layer 113 and the pixel electrode 111 between the light-emitting devices in some cases; however, the thicknesses are preferably adjusted as appropriate in each light-emitting device to intensify light with a wavelength for each light-emitting device.

It is preferable that the difference between the levels of the top surfaces of the layer 113a to the layer 113c be small in the display apparatus 100. For example, a structure in which the top surfaces of the layer 113a to the layer 113c are substantially level with one another is employed.

In a top view of the display apparatus 100 that includes a plurality of light-emitting devices arranged in a matrix, the insulating layer 127 is provided to fill the depressed portion between the light-emitting devices. The depth of the depressed portion depends on the difference between the level of the top surface of the layer 113 and the level of the top surface of the insulating layer 105, for example.

When the difference between the levels of the top surfaces of the layer 113a to the layer 113c is reduced, the in-plane distribution of unevenness on the formation surface of the insulating layer 127 can be reduced. In that case, the shape of the insulating layer 127 can be suitable in the entire plane. Specifically, variation in the thickness of the insulating layer 127 can be reduced in the entire plane, for example. Furthermore, variation in the thickness of the insulating layer 127 can be reduced in the entire plane, so that the thickness of the insulating layer 127 can be reduced.

The top surface of the insulating layer 127 is preferably flat but is sometimes a gently curved surface. For example, the top surface of the insulating layer 127 may be a convex surface, a concave surface, or a flat surface.

The end portions of the pixel electrode 111a, the pixel electrode 111b, and the pixel electrode 111c each preferably have a tapered shape. When the end portions of these pixel electrodes have a tapered shape, the layer 113a, the layer 113b, and the layer 113c provided along the side surfaces of the pixel electrodes also have a tapered shape. When the side surface of the pixel electrode has a tapered shape, coverage with at least part of the EL layer provided along the side surface of the pixel electrode can be improved. Furthermore, when the side surface of the pixel electrode has a tapered shape, a foreign substance (also referred to as dust or particles, for example) in the manufacturing process is easily removed by treatment such as cleaning, which is preferable.

Note that in this specification and the like, a tapered shape refers to a shape such that at least part of a side surface of a component is inclined to a substrate surface. For example, a tapered shape preferably includes a region where the angle between the inclined side surface and the substrate surface (such an angle is also referred to as a taper angle) is less than 90°.

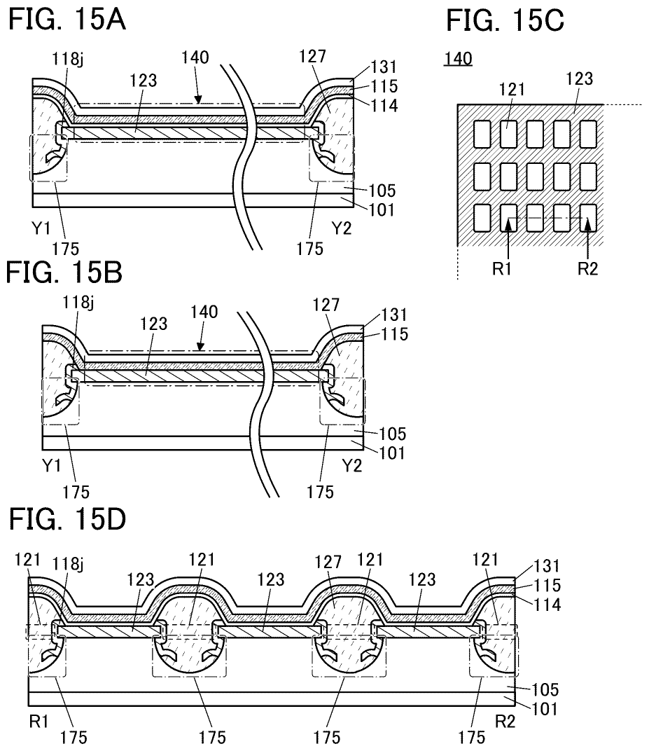

The common electrode 115 is shared by the light-emitting devices 130a, 130b, and 130c. The common electrode 115 shared by the plurality of light-emitting devices is electrically connected to a conductive layer 123 provided in the connection portion 140 (see FIG. 15A and FIG. 15B).

FIG. 15A and FIG. 15B illustrate examples of a cross-sectional view of a portion indicated by the dashed-dotted line Y1-Y2 in FIG. 5 and the like. FIG. 15B differs from FIG. 15A in that the common layer 114 is not provided in the connection portion 140.

The layers 113a, 113b, and 113c and the like are not provided in the connection portion 140 illustrated in FIG. 15A and FIG. 15B. For the conductive layer 123, it is preferable to use a conductive layer at least part of which is formed using the same material through the same step as at least one of the pixel electrode 111a to the pixel electrode 111c. An insulating layer 118j is provided to cover an end portion of the conductive layer 123. The insulating layer 118j can be formed using the film to be the insulating layer 118a (the insulating film 118af), the film to be the insulating layer 118b (the insulating film 118bf), or the film to be the insulating layer 118c.

Note that when adhesion between the insulating layers 118j and 127 and the insulating layer 105 is reduced in the periphery of the connection portion 140, separation of the common electrode 115, which is formed over these insulating layers, from the formation surface might be caused, for example. Providing the groove 175 in the peripheral portion of the connection portion 140 can increase the adhesion between the insulating layers 118j and 127 and the like and the insulating layer 105; as a result, the common electrode 115 formed over the insulating layer 118j and the insulating layer 127 can be formed with favorable adhesion to the formation surface.

In the case where the layer 113 is formed in the vicinity of the connection portion 140, providing the groove 175 in the display apparatus 100 can increase the adhesion between the insulating layer 105 and the insulating layer 118 over the layer 113 formed in the vicinity of the connection portion 140.

When the layer 113 is formed to have a pattern with a large area compared to that in the pixel portion 284 and the like, the layer 113 is easily separated from the insulating layer 105 in some cases. Even in such a case, the groove 175 included in the display apparatus 100 enables the increase in the adhesion between the insulating layer 105 and the layer 113.

FIG. 15A illustrates an example in which the common layer 114 is provided over the conductive layer 123 and the conductive layer 123 and the common electrode 115 are electrically connected to each other through the common layer 114. In the case where the common layer 114 has low conductivity, the common layer 114 is not necessarily provided in the connection portion 140. In FIG. 15B, the common layer 114 is not provided, and the conductive layer 123 and the common electrode 115 are directly connected to each other. For example, by using a mask for defining a film formation area (also referred to as an area mask, a rough metal mask, or the like to be distinguished from a fine metal mask), the common layer 114 can be formed in a region different from a region where the common electrode 115 is formed.

In the connection portion 140, an opening portion may be provided in the conductive layer 123. FIG. 15C illustrates an example in which a plurality of opening portions 121 are provided in the conductive layer 123 in the connection portion 140. FIG. 15D illustrates an example of a cross-sectional view of a portion indicated by the dashed-dotted line R1-R2 in FIG. 15C.

The groove 175 is provided to overlap with the opening portion of the conductive layer 123. The groove 175 includes a region overlapping with the conductive layer 123 below the conductive layer 123. Providing the opening portion in the conductive layer 123 enables a gas to be released to the outside through the opening portion even when gas desorption from the insulating layer included in the layer 101, the insulating layer 105, and the like occurs. Gas release occurs, for example, when heat treatment or the like is performed in a step subsequent to the formation of a conductive film to be the conductive layer 123. In particular, gas desorption is likely to occur when a resin layer is used as the insulating layer.

FIG. 16A illustrates an example of a cross-sectional view of a portion indicated by the dashed-dotted line Q1-Q2 in FIG. 4A. In the display apparatus 100, the pixel portion 284 is provided with an EL layer (e.g., the layer 113 and the common layer 114). A region outside the pixel portion 284 includes a region where the EL layer is provided and a region where the EL layer or at least part of the EL layer is not provided. In FIG. 16A, the dummy pixel portion 295 positioned outside the pixel portion 284 is provided with the dummy light-emitting device 59 including the layer 113 and the common layer 114, which are collectively the EL layer, and the dummy light-emitting device 59 not including the layer 113 and the common layer 114. A region outside the connection portion 140 includes a region where the layer 113, the common layer 114, and the common electrode 115 are not provided.

In FIG. 16B, the dummy pixel portion 295 positioned outside the pixel portion 284 is provided with the dummy light-emitting device 59 including the EL layer and the dummy light-emitting device 59 including not the layer 113 but the common layer 114 as the EL layer. In the region outside the connection portion 140, the layer 113, the common layer 114, and the common electrode 115 are not provided.

The protective layer 131 is preferably provided over the light-emitting devices 130a, 130b, and 130c. Providing the protective layer 131 can improve the reliability of the light-emitting devices. The protective layer 131 may have a single-layer structure or a stacked-layer structure of two or more layers.

There is no limitation on the conductivity of the protective layer 131. For the protective layer 131, at least one of an insulating film, a semiconductor film, and a conductive film can be used.

The protective layer 131 that includes an inorganic film can inhibit deterioration of the light-emitting devices by preventing oxidation of the common electrode 115 and inhibiting entry of impurities (e.g., moisture and oxygen) into the light-emitting devices, for example; thus, the reliability of the display apparatus can be improved.

As the protective layer 131, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can employ, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (such as water and oxygen) to the EL layer side.

Furthermore, the protective layer 131 may include an organic film. For example, the protective layer 131 may include both an organic film and an inorganic film. Examples of an organic material that can be used for the protective layer 131 include later-described organic insulating materials that can be used for the insulating layer 127.

The protective layer 131 may have a stacked-layer structure of two layers that are formed by different formation methods. Specifically, the first layer of the protective layer 131 may be formed by an ALD method, and the second layer of the protective layer 131 may be formed by a sputtering method.

In FIG. 6(C) and the like, an insulating layer covering an end portion of the top surface of the pixel electrode 111a is not provided between the pixel electrode 111a and the layer 113a. An insulating layer covering an end portion of the top surface of the pixel electrode 111b is not provided between the pixel electrode 111b and the layer 113b. Thus, the interval between adjacent light-emitting devices can be extremely short. Accordingly, the display apparatus can have high resolution or high definition.

In FIG. 6(C) and the like, the insulating layer 118a is positioned over the layer 113a of the light-emitting device 130a, the insulating layer 118b is positioned over the layer 113b of the light-emitting device 130b, and the insulating layer 118c is positioned over the layer 113c of the light-emitting device 130c. The insulating layer 118a is a remaining portion of a mask layer provided in contact with the top surface of the layer 113a when the layer 113a is processed. Similarly, the insulating layer 118b and the insulating layer 118c are remaining portions of mask layers provided when the layer 113b and the layer 113c are formed, respectively. Thus, in the display apparatus of one embodiment of the present invention, part of the mask layer used for protecting the EL layer in the manufacture of the display apparatus may remain. For any two or all of the insulating layer 118a to the insulating layer 118c, the same or different materials may be used. Note that the insulating layer 118a, the insulating layer 118b, and the insulating layer 118c are hereinafter collectively referred as the insulating layer 118 in some cases.

As the insulating layer 118, one or more of a metal film, an alloy film, a metal oxide film, a semiconductor film, an organic insulating film, and an inorganic insulating film can be used, for example. As the mask layer, a variety of inorganic insulating films that can be used as the protective layer 131 can be used. For example, an inorganic insulating material such as aluminum oxide, hafnium oxide, or silicon oxide can be used.

In FIG. 6(C) and the like, the layer 113a is formed to cover the end portion of the pixel electrode 111a. The aperture ratio of such a structure can be higher than that of the structure in which the end portions of the layer 113a, the layer 113b, and the layer 113c each having an island shape are positioned inward from the end portions of the pixel electrodes.

Covering the side surface of the pixel electrode with the layer 113a, the layer 113b, or the layer 113c inhibits contact between the pixel electrode and the common electrode 115, thereby inhibiting a short circuit in the light-emitting device. Furthermore, the distance between the light-emitting region (i.e., the region overlapping with the pixel electrode) in the EL layer and the end portion of the layer 113a, the layer 113b, or the layer 113c can be increased, resulting in higher reliability.

As the insulating layer 127, an insulating layer containing an organic material, for example, a resin layer can be used. For the resin layer, a photosensitive organic resin is preferably used; for example, a photosensitive acrylic resin can be used. The viscosity of the material for the resin layer is greater than or equal to 1 cP and less than or equal to 1500 cP, and is preferably greater than or equal to 1 cP and less than or equal to 12 cP. By setting the viscosity of the material for the resin layer in the above range, the insulating layer 127 having a tapered shape, which is to be described later, can be formed relatively easily. Note that in this specification and the like, an acrylic resin refers to not only a polymethacrylic acid ester or a methacrylic resin but also all the acrylic polymers in a broad sense in some cases.

Note that the organic material usable for the resin layer is not limited to the above description as long as the resin layer has a taper-shaped side surface as described later. For example, the resin layer can be formed using an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like in some cases. Alternatively, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin can be used for the resin layer in some cases. As the photosensitive resin, a photoresist can be used in some cases. As the photosensitive resin, a positive photosensitive material or a negative photosensitive material can be used in some cases.

The resin layer may be formed using a material absorbing visible light. When the resin layer absorbs light from the light-emitting device, leakage of light (stray light) from the light-emitting device to the adjacent light-emitting device through the resin layer can be inhibited. Thus, the display quality of the display apparatus can be improved. Since the display quality of the display apparatus can be improved without using a polarizing plate in the display apparatus, the weight and thickness of the display apparatus can be reduced.

Examples of the material absorbing visible light include a material containing a pigment of black or the like, a material containing a dye, a resin material with a light-absorbing property (e.g., polyimide), and a resin material that can be used for a color filter (a color filter material). Using a resin material obtained by stacking or mixing color filter materials of two or three or more colors is particularly preferable to enhance the effect of blocking visible light. In particular, mixing color filter materials of three or more colors makes it possible to form a black or nearly black resin layer.

For example, the resin layer can be formed by a wet film formation method such as spin coating, dipping, spray coating, ink-jetting, dispensing, screen printing, offset printing, a doctor knife method, slit coating, roll coating, curtain coating, or knife coating. Specifically, an organic insulating film that is to be the resin layer is preferably formed by spin coating.

The resin layer used as the insulating layer 127 is formed at a temperature lower than the upper temperature limit of the layer 113. The typical substrate temperature in formation of the resin layer used as the insulating layer 127 is lower than or equal to 200° C., preferably lower than or equal to 180° C., further preferably lower than or equal to 160° C., still further preferably lower than or equal to 150° C., yet still further preferably lower than or equal to 140° C.

In the display apparatus of this embodiment, the distance between the light-emitting devices can be narrowed. Specifically, the distance between the light-emitting devices, the distance between the layers 113, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where the interval between two adjacent island-shaped layers 113 is less than or equal to 1 μm, preferably less than or equal to 0.5 μm (500 nm), further preferably less than or equal to 100 nm.

For the insulating layer 127, an insulating layer containing an inorganic material can be used to be stacked with the above-described resin layer. For example, the insulating layer 127 can have a stacked-layer structure of an insulating layer containing an inorganic material and a resin layer over the insulating layer. Here, the insulating layer 127 includes a region in contact with the side surface of the island-shaped layer 113a, the island-shaped layer 113b, or the island-shaped layer 113c and functions as a protective insulating layer of the layer 113a, the layer 113b, or the layer 113c. With the insulating layer 127 containing an inorganic material, entry of impurities (such as oxygen and moisture) from the side surface of the island-shaped layer 113a, the layer 113b, or the layer 113c into its inside can be inhibited, and thus a highly reliable display apparatus can be obtained.

As the insulating layer containing an inorganic material, an inorganic insulating film such as an oxide insulating film, a nitride insulating film, an oxynitride insulating film, or a nitride oxide insulating film can be used, for example. The insulating layer containing an inorganic material can have either a single-layer structure or a stacked-layer structure. Examples of the oxide insulating film include a silicon oxide film, an aluminum oxide film, a magnesium oxide film, an indium-gallium-zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferably used because it has high selectivity with respect to the layer 113 in etching and has a function of protecting the layer 113 during the formation of the resin layer which is to be described later. In particular, when an inorganic insulating film such as an aluminum oxide film, a hafnium oxide film, or a silicon oxide film formed by an ALD method is used, the insulating layer 127 having few pinholes and an excellent function of protecting the layer 113 can be formed. The insulating layer 127 may have a stacked-layer structure of a film formed by an ALD method and a film formed by a sputtering method. For example, the insulating layer 127 may have a stacked-layer structure of an aluminum oxide film formed by an ALD method and a silicon nitride film formed by a sputtering method.

The insulating layer containing an inorganic material, which can be used for the insulating layer 127, preferably has a function of a barrier insulating layer against at least one of water and oxygen. The insulating layer containing an inorganic material, which can be used for the insulating layer 127, preferably has a function of inhibiting diffusion of at least one of water and oxygen. The insulating layer containing an inorganic material, which can be used for the insulating layer 127, preferably has a function of capturing or fixing (also referred to as gettering) at least one of water and oxygen.

When the insulating layer containing an inorganic material, which can be used for the insulating layer 127, has a function of a barrier insulating layer or a gettering function, entry of impurities (typically, at least one of water and oxygen) that might diffuse into the light-emitting devices from the outside can be inhibited. With this structure, a highly reliable light-emitting device and a highly reliable display apparatus can be provided.

The insulating layer containing an inorganic material, which can be used for the insulating layer 127, preferably has a low impurity concentration. In that case, deterioration of the layer 113 due to entry of impurities from the insulating layer 127 into the layer 113 can be inhibited. In addition, when having a low impurity concentration, the insulating layer 127 can have a high barrier property against at least one of water and oxygen. For example, the insulating layer containing an inorganic material preferably has one of a sufficiently low hydrogen concentration and a sufficiently low carbon concentration, desirably has both of them.

Examples of the formation method of the insulating layer containing an inorganic material, which can be used for the insulating layer 127, include a sputtering method, a CVD method, a pulsed laser deposition (PLD) method, and an ALD method. The insulating layer containing an inorganic material is preferably formed by an ALD method achieving good coverage.

When the substrate temperature in forming the insulating layer containing an inorganic material, which can be used for the insulating layer 127, is increased, the formed insulating layer containing an inorganic material, even with a small thickness, can have a low impurity concentration and a high barrier property against at least one of water and oxygen. Therefore, the substrate temperature is preferably higher than or equal to 60° C., further preferably higher than or equal to 80° C., still further preferably higher than or equal to 100° C., yet still further preferably higher than or equal to 120° C. Meanwhile, the insulating layer containing an inorganic material, which can be used for the insulating layer 127, is formed after formation of the island-shaped layer 113, and thus is preferably formed at a temperature lower than the upper temperature limit of the layer 113. Therefore, the substrate temperature is preferably lower than or equal to 200° C., further preferably lower than or equal to 180° C., still further preferably lower than or equal to 160° C., still further preferably lower than or equal to 150° C., yet still further preferably lower than or equal to 140° C.

Examples of indicators of the upper temperature limit are the glass transition point, the softening point, the melting point, the thermal decomposition temperature, and the 5% weight loss temperature. The upper temperature limit of the layer 113 can be, for example, any of the above temperatures, preferably the lowest temperature thereof.

For the insulating layer containing an inorganic material, which can be used for the insulating layer 127, an insulating film is preferably formed to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The resin layer provided over the insulating layer containing an inorganic material, which can be used for the insulating layer 127, has a function of reducing extreme unevenness on the insulating layer containing an inorganic material, which is formed between adjacent light-emitting devices. In other words, the insulating layer 127 brings about an effect of improving the planarity of the formation surface of the common electrode 115.

For the pixel electrode 111, for example, a metal material such as aluminum, gold, platinum, silver, nickel, tungsten, chromium, molybdenum, iron, cobalt, copper, or palladium or an alloy containing any of these metal materials can be used. Copper is preferable because of its high reflectance with respect to visible light. Aluminum is preferable because an aluminum electrode is easily etched and thus is easily processed, and aluminum has high reflectance with respect to visible light and near-infrared light. Lanthanum, neodymium, germanium, or the like may be added to the above metal material and alloy. Alternatively, an alloy (an aluminum alloy) containing aluminum and titanium, nickel, or neodymium may be used. An alloy containing silver and copper, palladium, or magnesium may be used. An alloy containing silver and copper is preferable because of its high heat resistance. Lanthanum, neodymium, germanium, or the like may be added to the above metal material and alloy. Alternatively, an alloy containing aluminum (an aluminum alloy) and titanium, nickel, or neodymium may be used. Alternatively, an alloy containing silver and copper, palladium, or magnesium may be used. An alloy containing silver and copper is preferable because of its high heat resistance.

Alternatively, for the pixel electrode 111, for example, indium oxide, indium tin oxide, indium zinc oxide, zinc oxide, or zinc oxide to which gallium is added can be used. Alternatively, any of the following materials formed thin enough to have a light-transmitting property can be used: a metal material such as gold, silver, platinum, magnesium, nickel, tungsten, chromium, molybdenum, iron, cobalt, copper, palladium, or titanium; an alloy containing any of these metal materials; a nitride of any of these metal materials (e.g., titanium nitride); and the like. Furthermore, a stacked-layer film of the above materials can be used as a conductive layer. For example, a stacked-layer film of an alloy of silver and magnesium and indium tin oxide is preferably used, in which case conductivity can be increased. Further alternatively, graphene or the like may be used.

For the pixel electrode 111, a single-layer structure or a stacked-layer structure of a film containing the material exemplified above can be employed.

The pixel electrode 111 may have a structure in which a conductive metal oxide film is stacked over a conductive film that reflects visible light. Such a structure can inhibit oxidation and corrosion of the conductive film that reflects visible light. When a metal film or a metal oxide film is stacked in contact with an aluminum film or an aluminum alloy film, for example, oxidation can be inhibited. Examples of a material for the metal film or the metal oxide film include titanium and titanium oxide. Alternatively, the aforementioned conductive film transmitting visible light and a film containing a metal material may be stacked. For example, a stacked-layer film of silver and indium tin oxide or a stacked-layer film of an alloy of silver and magnesium and indium tin oxide can be used.

Examples of a material that can be used for the plug 139 include metals such as aluminum, titanium, chromium, nickel, copper, yttrium, zirconium, molybdenum, gold, silver, platinum, magnesium, iron, cobalt, palladium, tantalum, and tungsten; an alloy containing any of these metal materials; and a nitride of any of these metal materials. As the plug 139, a single layer or a stacked-layer structure including a film containing any of these materials can be used. Examples include a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which an aluminum film or a copper film is stacked over a titanium film or a titanium nitride film and a titanium film or a titanium nitride film is formed thereover, and a three-layer structure in which an aluminum film or a copper film is stacked over a molybdenum film or a molybdenum nitride film and a molybdenum film or a molybdenum nitride film is formed thereover. Note that an oxide such as indium oxide, tin oxide, or zinc oxide may be used. Copper containing manganese is preferably used because it increases controllability of a shape by etching.

Here, the expression “the top surfaces are substantially level with each other” for the layers 113 included in the light-emitting devices 130 refers to, for example, the difference between the level of one top surface and the level of the other top surface being preferably less than or equal to 100 nm, further preferably less than or equal to 50 nm, still further preferably less than or equal to 30 nm. In the case where the sum of the thicknesses in a region of a stacked-layer structure in one light-emitting device 130 is substantially the same as that in another light-emitting device 130 or the sum of the thickness and the distance in a region of a stacked-layer structure in one light-emitting device 130 is substantially the same as that in another light-emitting device 130, the difference between the value of one sum and the value of the other sum is preferably less than or equal to 100 nm, further preferably less than or equal to 50 nm. The value of the one sum is preferably greater than or equal to 0.8 times and less than or equal to 1.2 times the value of the other sum. The value of the one sum is further preferably greater than or equal to 0.9 times and less than or equal to 1.1 times the value of the other sum.

The thickness of the layer 113 is, for example, greater than or equal to 10 nm and less than or equal to 1000 nm. Here, the case where the insulating layer containing an inorganic material is provided between two adjacent light-emitting devices 130 (hereinafter referred to as a first light-emitting device and a second light-emitting device) in a top view is considered. The insulating layer containing an inorganic material is preferably in contact with the side surfaces of the layers 113 in the two light-emitting devices 130. In the case where the interval between the side surface of the layer 113 that is in contact with the insulating layer containing an inorganic material in the first light-emitting device (hereinafter a first side surface) and the side surface of the layer 113 that is in contact with the insulating layer containing an inorganic material in the second light-emitting device (hereinafter a second side surface) is small, the distance between the first side surface and the top surface of the insulating layer 127 and the distance between the first side surface and the top surface of the insulating layer 127 decrease, and consequently the layers 113 might be more likely to be affected by a stress change due to the shrinkage of the insulating layer 127.

Therefore, the structure of one embodiment of the present invention sometimes has a more significant effect especially in the case where the interval between the first side surface and the second side surface is small. For example, the structure of one embodiment of the present invention sometimes has a more significant effect in a display apparatus having extremely high resolution.

For example, the structure of one embodiment of the present invention sometimes has a more significant effect in the case where the interval between the first side surface and the second side surface is small with respect to the thickness of the layer 113.

Specifically, for example, the structure of one embodiment of the present invention sometimes has a more significant effect in the case where the interval between the first side surface and the second side surface is less than or equal to 2000 nm or less than or equal to 1000 nm.

Note that the interface between the common layer 114 and the layer 113 is sometimes difficult to determine in cross-sectional observation of the light-emitting device 130. Accordingly, for example, the total thickness of the layer 113 and the common layer 114 may be used for the evaluation. Here, the layer 113a and the common layer 114 can be collectively referred to as the EL layer of the light-emitting device 130a. The layer 113b and the common layer 114 can be collectively referred to as the EL layer of the light-emitting device 130b. The layer 113c and the common layer 114 can be collectively referred to as the EL layer of the light-emitting device 130c.

In addition, the interface between the common layer 114 and the layer 113 is sometimes difficult to determine in cross-sectional observation of the light-emitting device 130. Thus, the thickness may be calculated using the interface that can be more clearly observed. For example, the thickness of the layer between the pixel electrode and the common electrode can be calculated by calculating the distance between the top surface of the pixel electrode and the bottom surface of the common electrode.

Note that in the case where the thicknesses of the pixel electrode 111, the layer 113, the common layer 114, and the common electrode 115 are evaluated and the layers are each formed to have an island shape, for example, the evaluation may be performed using the center of each of the island-shaped layers and the vicinity of the center in the cross-sectional observation image.

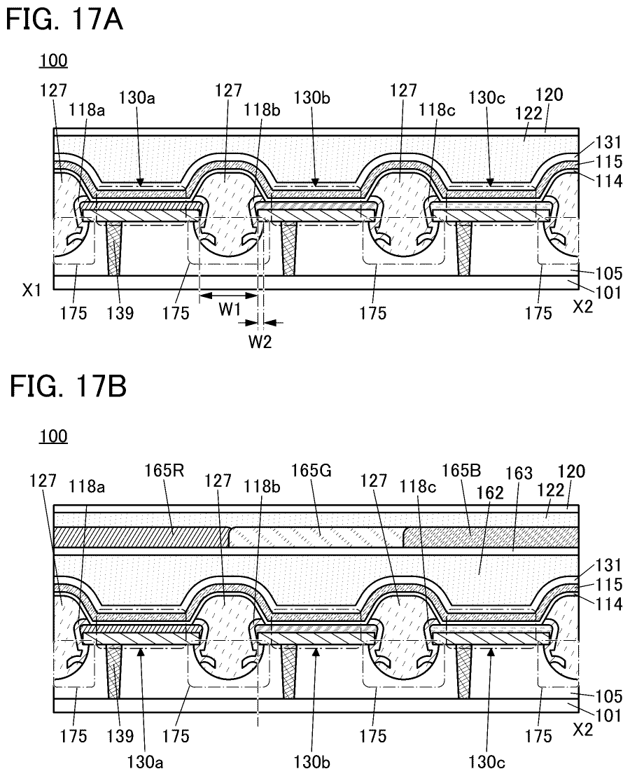

FIG. 17A illustrates an example of a cross section of the display apparatus 100 including a substrate 120. In the display apparatus 100, the substrate 120 may be attached onto the protective layer 131 by a resin layer 122 as illustrated in FIG. 17A. A light-blocking layer may be provided on a surface of the substrate 120 that faces the resin layer 122. The light-blocking layer may be provided to overlap with a region between the light-emitting regions of adjacent light-emitting devices, for example. The light-blocking layer may be provided to overlap with the dummy light-emitting device, for example. Specifically, for example, the light-blocking layer can be provided to overlap with the entire dummy pixel portion. Alternatively, the light-blocking layer can be provided to overlap with some of the dummy light-emitting devices included in the dummy pixel portion.

In the case where the dummy light-emitting device does not have a function of emitting light, the light-blocking layer is not necessarily provided in a region overlapping with the dummy light-emitting device.

A variety of optical members can be provided on the outer surface of the substrate 120. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film suppressing the attachment of stain, a hard coat film inhibiting generation of a scratch caused by the use, an impact-absorbing layer, or the like may be provided as a surface protective layer on the outer surface of the substrate 120. For example, a glass layer or a silica layer (SiOₓ layer) is preferably provided as the surface protective layer to inhibit the surface contamination and generation of a scratch. The surface protective layer may be formed using DLC (diamond like carbon), aluminum oxide (AlOₓ), a polyester-based material, a polycarbonate-based material, or the like. For the surface protective layer, a material having high visible-light transmittance is preferably used. The surface protective layer is preferably formed using a material with high hardness.

For the substrate 120, glass, quartz, ceramic, sapphire, a resin, a metal, an alloy, a semiconductor, or the like can be used. The substrate on the side from which light from the light-emitting device is extracted is formed using a material that transmits the light. When the substrate 120 is formed using a flexible material, the flexibility of the display apparatus can be increased. Furthermore, a polarizing plate may be used as the substrate 120.

For the substrate 120, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 120.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a film having high optical isotropy include a triacetyl cellulose (TAC, also referred to as cellulose triacetate) film, a cycloolefin polymer (COP) film, a cycloolefin copolymer (COC) film, and an acrylic film.

In the case where a film is used for the substrate and the film absorbs water, the shape of the display apparatus might be changed, e.g., creases are generated. Thus, for the substrate, a film with a low water absorption rate is preferably used. For example, the water absorption rate of the film is preferably lower than or equal to 1%, further preferably lower than or equal to 0.1%, still further preferably lower than or equal to 0.01%.

For the resin layer 122, any of a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

FIG. 17B illustrates an example of a cross section of the display apparatus 100 including a coloring layer and the like in addition to the substrate 120 and the resin layer 122. In the display apparatus 100 illustrated in FIG. 17B, an insulating layer 162 is provided over the protective layer 131, an insulating layer 163 is provided over the insulating layer 162, and a coloring layer 165R overlapping with the light-emitting device 130a, a coloring layer 165G overlapping with the light-emitting device 130b, and a coloring layer 165B overlapping with the light-emitting device 130c are provided over the insulating layer 163.

As the insulating layer 162, an organic insulating film having a high light-transmitting property can be used. Using an organic insulating film as the insulating layer 162 can reduce the influence of an uneven shape below the insulating layer 162, so that the formation surface of the insulating layer 163 can be a smooth surface. In that case, a defect such as a pinhole is less likely to be generated in the insulating layer 163, leading to higher moisture permeability of the insulating layer 163.

The description of the protective layer 131 can be referred to for the material and structure that can be used for the insulating layer 163.

Note that the structure of the protective layer covering the light-emitting device 130 is not limited thereto, and a single-layer structure or a two-layer structure may be employed or a stacked-layer structure of four or more layers may be employed.

For example, the coloring layer 165R transmits red light, the coloring layer 165G transmits green light, and the coloring layer 165B transmits blue light. This can increase the color purity of light from each light-emitting element, so that the display apparatus can have higher display quality.

The coloring layers may be formed on the substrate 120, and bonding may be performed with an adhesive layer. Forming the coloring layers on the substrate 120 can simplify the structure over the layer 101. Meanwhile, in the case where the coloring layers are formed over the insulating layer 163, the position alignment of the light-emitting units and the coloring layers is easier than in the case where the coloring layers are formed on the substrate 120; hence, the display apparatus can have extremely high resolution.

Since the pixels included in the dummy pixel portion do not necessarily have a function of emitting light, the coloring layer may be omitted in the dummy pixel portion. Alternatively, the coloring layer may be provided in the dummy pixel portion.

The display apparatus of one embodiment of the present invention may include a light-receiving device in the pixel. For example, among a plurality of subpixels included in the pixel, one or more subpixels may be a light-emitting device and one or more subpixels may be a light-receiving device.

For example, a pn or pin photodiode can be used as the light-receiving device. The light-receiving device functions as a photoelectric conversion device (also referred to as a photoelectric conversion element) that detects light entering the light-receiving device and generates electric charge. The amount of electric charge generated from the light-receiving device depends on the amount of light entering the light-receiving device.

It is particularly preferable to use an organic photodiode including a layer containing an organic compound, as the light-receiving device. An organic photodiode, which is easily made thin, lightweight, and large in area and has a high degree of freedom for shape and design, can be used in a variety of display apparatuses.

In one embodiment of the present invention, an organic EL device can be used as the light-emitting device, and an organic photodiode can be used as the light-receiving device. The organic EL device and the organic photodiode can be formed over the same substrate. Thus, the organic photodiode can be incorporated in the display apparatus using the organic EL device.

The light-receiving device includes at least an active layer that functions as a photoelectric conversion layer between a pair of electrodes. In this specification and the like, one of the pair of electrodes is referred to as a pixel electrode and the other is referred to as a common electrode in some cases.

One of the pair of electrodes of the light-receiving device functions as an anode, and the other electrode functions as a cathode. Hereinafter, the case where the pixel electrode functions as an anode and the common electrode functions as a cathode is described as an example. When the light-receiving device is driven by application of reverse bias between the pixel electrode and the common electrode, light entering the light-receiving device can be detected and electric charge can be generated and extracted as current. Alternatively, the pixel electrode may function as a cathode and the common electrode may function as an anode.

By replacing the layer 113 with an active layer (also referred to as a photoelectric conversion layer) of a photoelectric conversion device, the light-emitting device 130 can function as a light-receiving device.

A manufacturing method similar to that of the light-emitting device can be employed for the light-receiving device. The island-shaped active layers included in the light-receiving devices are formed not by using a fine metal mask but in the following manner: a film to be the active layers is formed on the entire surface and is then processed. Thus, the island-shaped active layers can have a uniform thickness. In addition, a mask layer provided over the active layer can reduce damage to the active layer in the manufacturing process of the display apparatus, increasing the reliability of the light-receiving device.

Here, a layer shared by the light-receiving device and the light-emitting device may have different functions in the light-emitting device and the light-receiving device. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. In some cases, a layer shared by the light-receiving device and the light-emitting device have the same function in both the light-emitting device and the light-receiving device. The hole-transport layer functions as a hole-transport layer in both the light-emitting device and the light-receiving device, and the electron-transport layer functions as an electron-transport layer in both the light-emitting device and the light-receiving device.

The display apparatus whose pixel includes the light-emitting device and the light-receiving device can detect contact or proximity of an object while displaying an image because the pixel has a light-receiving function. For example, all the subpixels included in the display apparatus can display an image; alternatively, some of the subpixels can emit light as a light source, and the other subpixels can display an image.

In the display apparatus of one embodiment of the present invention, the light-emitting devices are arranged in a matrix in the display portion, and an image can be displayed on the display portion. Furthermore, the light-receiving devices are arranged in a matrix in the display portion, and the display portion has one or both of an image capturing function and a sensing function in addition to an image displaying function. The display portion can be used as an image sensor or a touch sensor. That is, by detecting light with the display portion, an image can be captured or proximity or contact of an object (e.g., a finger, a hand, or a pen) can be detected. Furthermore, in the display apparatus of one embodiment of the present invention, the light-emitting devices can be used as a light source of the sensor. Accordingly, a light-receiving portion and a light source do not need to be provided separately from the display apparatus; hence, the number of components of an electronic device can be reduced. For example, a fingerprint authentication device, a capacitive touch panel for scroll operation, or the like is not necessarily provided separately from an electronic device. Thus, with the use of the display apparatus of one embodiment of the present invention, an electronic device can be provided with reduced manufacturing cost.

In the display apparatus of one embodiment of the present invention, when an object reflects (or scatters) light emitted from the light-emitting device included in the display portion, the light-receiving device can detect the reflected light (or scattered light); thus, image capturing or touch detection is possible even in a dark place.

In the case where the light-receiving device is used as an image sensor, the display apparatus can capture an image with the use of the light-receiving device. For example, the display apparatus of this embodiment can be used as a scanner.

For example, data on biological information such as a fingerprint or a palm print can be obtained with the use of the image sensor. That is, a biometric authentication sensor can be incorporated in the display apparatus. When the display apparatus incorporates a biometric authentication sensor, the number of components of an electronic device can be reduced as compared with the case where a biometric authentication sensor is provided separately from the display apparatus; thus, the size and weight of the electronic device can be reduced.

In the case where the light-receiving device is used as the touch sensor, the display apparatus can detect proximity or contact of an object with the use of the light-receiving device.

The display apparatus of one embodiment of the present invention can have one or both of an image capturing function and a sensing function in addition to an image displaying function. Thus, the display apparatus of one embodiment of the present invention can be regarded as being highly compatible with the function other than the display function.

Next, materials that can be used for the light-emitting device will be described.

A conductive film transmitting visible light is used as the electrode through which light is extracted, which is either the pixel electrode or the common electrode. A conductive film that reflects visible light is preferably used as the electrode through which light is not extracted. In the case where the display apparatus includes a light-emitting device emitting infrared light, a conductive film transmitting visible light and infrared light is preferably used as the electrode through which light is extracted, and a conductive film reflecting visible light and infrared light is preferably used as the electrode through which light is not extracted.

A conductive film transmitting visible light may be used also as the electrode through which light is not extracted. In that case, this electrode is preferably provided between a reflective layer and the EL layer. In other words, light emitted by the EL layer may be reflected by the reflective layer to be extracted from the display apparatus.

As a material that forms the pair of electrodes (the pixel electrode and the common electrode) of the light-emitting device, a metal, an alloy, an electrically conductive compound, a mixture thereof, or the like can be used as appropriate. Specific examples include indium tin oxide (In—Sn oxide, also referred to as ITO), In—Si—Sn oxide (also referred to as ITSO), indium zinc oxide (In—Zn oxide), In—W—Zn oxide, an alloy containing aluminum (an aluminum alloy) such as an alloy of aluminum, nickel, and lanthanum (Al—Ni—La), and an alloy of silver, palladium, and copper (Ag—Pd—Cu, also referred to as APC). In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use a Group 1 element or a Group 2 element in the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

The light-emitting device preferably employs a micro optical resonator (microcavity) structure. Therefore, one of the pair of electrodes of the light-emitting device is preferably an electrode having properties of transmitting and reflecting visible light (a transflective electrode), and the other is preferably an electrode having a property of reflecting visible light (a reflective electrode). When the light-emitting device has a microcavity structure, light obtained from the light-emitting layer can be resonated between the electrodes, whereby light emitted from the light-emitting device can be intensified.

The transflective electrode can have a stacked-layer structure of a reflective electrode and an electrode having a property of transmitting visible light (also referred to as a transparent electrode).

The light transmittance of the transparent electrode is higher than or equal to 40%. For example, an electrode having a visible light (light with wavelengths greater than or equal to 400 nm and less than 750 nm) transmittance higher than or equal to 40% is preferably used in the light-emitting device. The visible light reflectance of the transflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity lower than or equal to 1×10⁻² Ωcm.

The light-emitting layer contains a light-emitting material (also referred to as a light-emitting substance). The light-emitting layer can include one or more kinds of light-emitting substances. As the light-emitting substance, a substance that exhibits an emission color of blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer preferably includes, for example, a phosphorescent material and a combination of a hole-transport material and an electron-transport material that easily forms an exciplex. With such a structure, light emission can be efficiently obtained by ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of the lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

In addition to the light-emitting layer, the layer 113a, the layer 113b, and the layer 113c may further include layers containing a substance with a high hole-injection property, a substance with a high hole-transport property, a hole-blocking material, a substance with a high electron-transport property, a substance with a high electron-injection property, an electron-blocking material, a substance with a bipolar property (a substance with a high electron-transport property and a high hole-transport property), and the like.

Either a low molecular compound or a high molecular compound can be used in the light-emitting device, and an inorganic compound may also be included. Each layer included in the light-emitting device can be formed by a method such as an evaporation method (including a vacuum evaporation method), a transfer method, a printing method, an ink-jet method, or a coating method.

For example, the layer 113a, the layer 113b, and the layer 113c may each include one or more of a hole-injection layer, a hole-transport layer, a hole-blocking layer, an electron-blocking layer, an electron-transport layer, and an electron-injection layer.

The common layer 114 can include one or more of a hole-injection layer, a hole-transport layer, a hole-blocking layer, an electron-blocking layer, an electron-transport layer, and an electron-injection layer. For example, a carrier-injection layer (a hole-injection layer or an electron-injection layer) may be formed as the common layer 114. Note that the light-emitting device does not necessarily include the common layer 114.

The layer 113a, the layer 113b, and the layer 113c each preferably include a light-emitting layer and a carrier-transport layer over the light-emitting layer. In that case, the light-emitting layer is inhibited from being exposed on the outermost surface in the manufacturing process of the display apparatus 100, so that damage to the light-emitting layer can be reduced. Thus, the reliability of the light-emitting devices can be increased.

A hole-injection layer is a layer that injects holes from an anode to a hole-transport layer and contains a material with a high hole-injection property. Examples of the material with a high hole-injection property include an aromatic amine compound and a composite material containing a hole-transport material and an acceptor material (electron-accepting material).

A hole-transport layer is a layer that transports holes, which are injected from an anode by a hole-injection layer, to a light-emitting layer. The hole-transport layer is a layer that contains a hole-transport material. As the hole-transport material, a substance having a hole mobility higher than or equal to 1×10⁻⁶ cm²/Vs is preferable. Note that other substances can also be used as long as the substances have a hole-transport property higher than an electron-transport property. As the hole-transport material, a material having a high hole-transport property, such as a π-electron rich heteroaromatic compound (e.g., a carbazole derivative, a thiophene derivative, or a furan derivative) or an aromatic amine (a compound having an aromatic amine skeleton), is preferable.

An electron-transport layer is a layer that transports electrons, which are injected from a cathode by an electron-injection layer, to a light-emitting layer. The electron-transport layer is a layer that contains an electron-transport material. As the electron-transport material, a substance having an electron mobility higher than or equal to 1×10⁻⁶ cm²/Vs is preferable. Note that other substances can also be used as long as the substances have an electron-transport property higher than a hole-transport property. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

An electron-injection layer is a layer that injects electrons from a cathode to an electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used. Note that it is preferable that the material with a high electron-injection property be a material whose lowest unoccupied molecular orbital (LUMO) level value has a small difference from the work function value of a material used for the common electrode; for example, the difference between the values is preferably less than or equal to 0.5 eV.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ), or cesium carbonate, for example. In addition, the electron-injection layer may have a stacked-layer structure of two or more layers. In the stacked-layer structure, for example, lithium fluoride can be used for the first layer and ytterbium can be used for the second layer.

Alternatively, the electron-injection layer may be formed using an electron-transport material. For example, a compound having an unshared electron pair and a π-electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital level of the organic compound having an unshared electron pair is preferably higher than or equal to −3.6 eV and lower than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-α:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition temperature (Tg) than BPhen and thus has high heat resistance.

In the case of manufacturing a tandem light-emitting device, a charge-generation layer (also referred to as an intermediate layer) is provided between two light-emitting units. The intermediate layer has a function of injecting electrons into one of the two light-emitting units and injecting holes to the other when voltage is applied between the pair of electrodes.

For the charge-generation layer, for example, a material that can be used for the electron-injection layer, such as lithium, can be suitably used. For the charge-generation layer, for example, a material that can be used for the hole-injection layer can be suitably used. As the charge-generation layer, a layer containing a hole-transport material and an acceptor material (electron-accepting material) can be used. As the charge-generation layer, a layer containing an electron-transport material and a donor material can be used. Forming such a charge-generation layer can inhibit an increase in the driving voltage in the case of stacking light-emitting units.

### [Example 1 of Method for Manufacturing Display Apparatus]

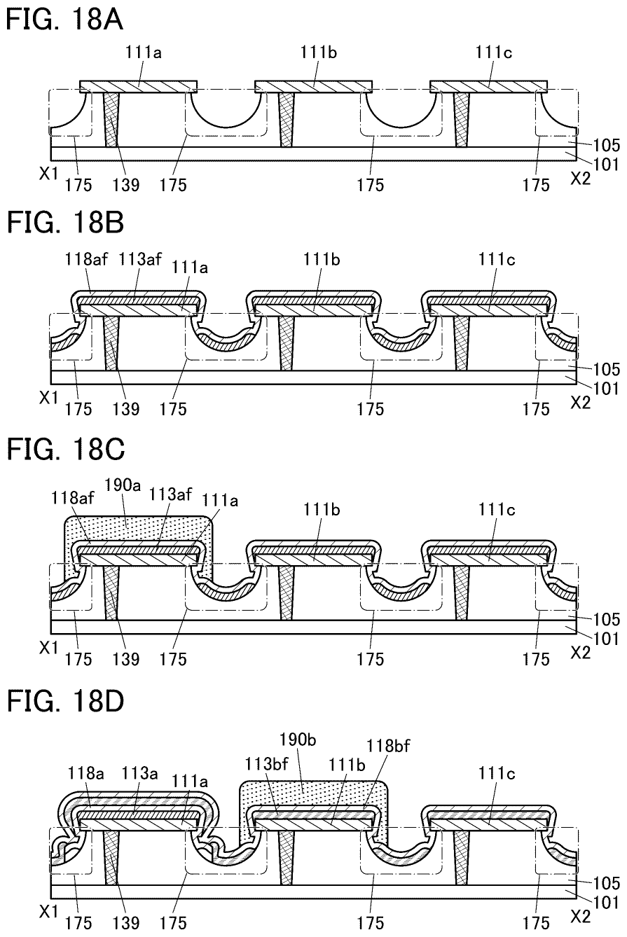

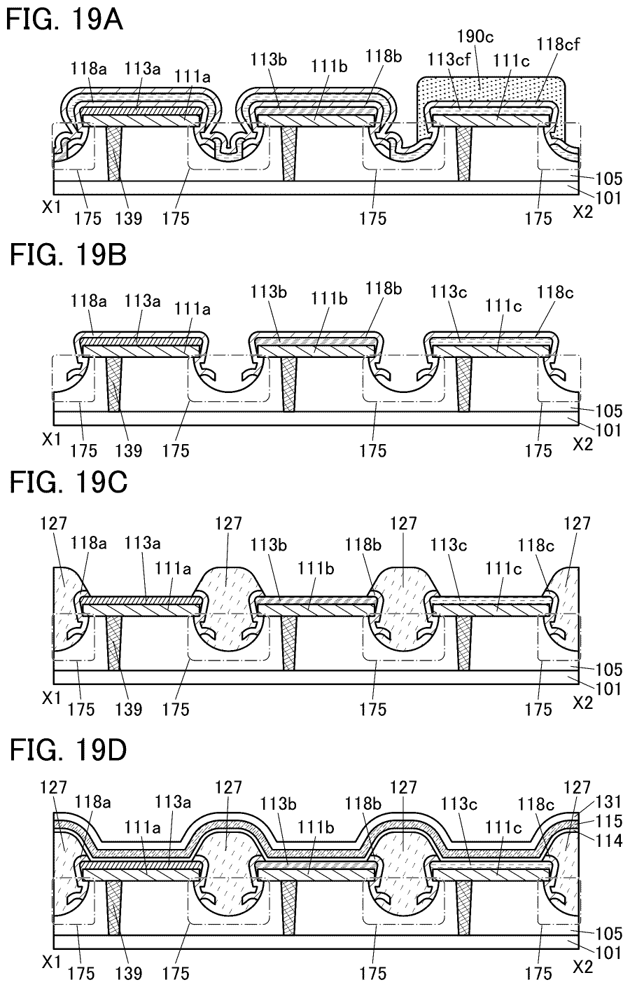

Next, an example of a method for manufacturing the display apparatus 100 illustrated in FIG. 6C and the like will be described with reference to FIG. 18A to FIG. 19D.

Thin films (e.g., insulating films, semiconductor films, and conductive films) included in the display apparatus can be formed by a sputtering method, a chemical vapor deposition (CVD) method, a vacuum evaporation method, a pulsed laser deposition (PLD) method, an ALD method, or the like. Examples of a CVD method include a plasma-enhanced chemical vapor deposition (PECVD) method and a thermal CVD method. An example of a thermal CVD method is a metal organic chemical vapor deposition (MOCVD) method.

Alternatively, thin films (e.g., insulating films, semiconductor films, and conductive films) included in the display apparatus can be formed by a method such as spin coating, dipping, spray coating, ink-jetting, dispensing, screen printing, offset printing, a doctor knife method, slit coating, roll coating, curtain coating, or knife coating.

Specifically, for fabrication of the light-emitting device, a vacuum process such as an evaporation method and a solution process such as a spin coating method or an ink-jet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, the functional layers (e.g., the hole-injection layer, the hole-transport layer, the light-emitting layer, the electron-transport layer, and the electron-injection layer) included in the EL layers can be formed by an evaporation method (e.g., a vacuum evaporation method), a coating method (e.g., a dip coating method, a die coating method, a bar coating method, a spin coating method, or a spray coating method), a printing method (e.g., an ink-jet method, a screen printing (stencil) method, an offset printing (planography) method, a flexography (relief printing) method, a gravure printing method, or a micro-contact printing method), or the like.

Thin films that constitute the display apparatus can be processed by a photolithography method or the like. Alternatively, thin films may be processed by a nanoimprinting method, a sandblasting method, a lift-off method, or the like. Alternatively, island-shaped thin films may be directly formed by a film formation method using a shielding mask such as a metal mask.

There are the following two typical examples of a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As the light used for light exposure in the photolithography method, for example, an i-line (wavelength: 365 nm), a g-line (wavelength: 436 nm), an h-line (wavelength: 405 nm), or combined light of any of them can be used. Alternatively, ultraviolet light, KrF laser light, ArF laser light, or the like can be used. In addition, light exposure may be performed by liquid immersion exposure technique. As the light used for the light exposure, extreme ultraviolet (EUV) light or X-rays may be used. Furthermore, instead of the light used for the light exposure, an electron beam can also be used. Extreme ultraviolet light, X-rays, or an electron beam is preferably used to enable extremely minute processing. Note that in the case of performing light exposure by scanning of a beam such as an electron beam, a photomask is not needed.

For etching of thin films, a dry etching method, a wet etching method, a sandblast method, or the like can be used.

### {Preparation for Layer 101}

For the layer 101, a substrate that has heat resistance high enough to withstand at least the following heat treatment can be used. In the case where an insulating substrate is used as the layer 101, a glass substrate, a quartz substrate, a sapphire substrate, a ceramic substrate, or the like can be used. Alternatively, a single crystal semiconductor substrate or a polycrystalline semiconductor substrate using silicon, silicon carbide, or the like as a material, a compound semiconductor substrate of silicon germanium or the like, a semiconductor substrate such as an SOI substrate, or the like can be used.

For the layer 101, it is particularly preferable to use the semiconductor substrate or the insulating substrate where a semiconductor circuit including a semiconductor element such as a transistor is formed. The semiconductor circuit preferably forms a pixel circuit, a gate line driver circuit (gate driver), a source line driver circuit (source driver), or the like. In addition to the above, an arithmetic circuit, a memory circuit, or the like may be formed.

In this embodiment, a substrate including at least a pixel circuit is used as the layer 101.

### {Formation of Insulating Layer 105, Plug 139, and Pixel Electrode 111}

An insulating film to be the insulating layer 105 is formed over the layer 101. Next, an opening reaching the layer 101 is formed in the insulating layer 105 at a position where the plug 139 is to be formed. The opening is preferably an opening reaching an electrode or a wiring provided in the layer 101. Subsequently, a conductive film is formed to fill the opening and then, planarization treatment is performed to expose the top surface of the insulating layer 105. In this manner, the plug 139 embedded in the insulating layer 105 can be formed.

A conductive film is formed over the insulating layer 105 and the plug 139, and an unnecessary portion of the conductive film is removed while a portion overlapping with the plug 139 remains, thereby forming the pixel electrode 111 (the pixel electrodes 111a, 111b, 111c, 111e, 111f, 111g, and 111h) electrically connected to the plug 139. An etching method, for example, is preferably used to remove the unnecessary portion of the conductive film. At this time, the conductive layer 123 included in the connection portion 140 can also be formed.

### {Formation of Groove 175}

Next, the groove 175 is formed in the insulating layer 105 (see FIG. 18A). The groove 175 can be formed by an isotropic etching method. For example, wet etching treatment or isotropic plasma etching treatment can be used. In particular, in the case where an insulating layer containing an inorganic material is used as the insulating layer 105, wet etching treatment is preferably used. In the case where an insulating layer containing an organic material is used as the insulating layer 105, isotropic dry etching treatment is preferably used. Thus, the groove 175 part of which is positioned below the pixel electrode 111 can be formed.

Note that one groove 175 is provided between different light-emitting devices. As illustrated in FIG. 7A, the grooves 175 are provided between the pixel electrode 111a and the pixel electrode 111b, between the pixel electrode 111b and the pixel electrode 111c, and between the pixel electrode 111c and the pixel electrode 111a. Although not illustrated, the groove 175 is also provided between adjacent dummy light-emitting devices.

{Formation of layer 113a, insulating layer 118a, and the like}Next, the film 113af is formed over the insulating layer 105, the pixel electrode 111a, the pixel electrode 111b, and the pixel electrode 111c. Then, the insulating film 118af is formed over the film 113af (see FIG. 18B).

The film 113af is a film containing a first light-emitting compound. Although not illustrated, the film 113af is also formed over the pixel electrodes (the pixel electrodes 111e, 111f, 111g, and 111h) included in the dummy light-emitting devices.

The film containing the first light-emitting compound can be formed by, for example, an evaporation method, specifically a vacuum evaporation method. The film may be formed by a method such as a transfer method, a printing method, an ink-jet method, or a coating method.

In the formation of the film 113af, disconnection occurs in the film 113af by the groove 175. As a result, an island-shaped layer is formed over the pixel electrode 111a. The layer 113a, the layer 113e, and the layer 113h can be formed by removing an unnecessary region of the film 113af other than the island-shaped layers over the pixel electrode 111a, the pixel electrode 111e, and the pixel electrode 111h, for example.

Next, the insulating film 118af is formed over the film 113af and the insulating layer 105. The insulating film 118af can be formed by a sputtering method, a CVD method, an MBE method, a PLD method, an ALD method, or the like as appropriate. It is necessary to form the insulating film 118af to have good coverage on the bottom surface and the side surface of the groove 175 provided in the insulating layer 105. By an ALD method, an atomic layer can be deposited one by one on the bottom surface and the side surface of the groove 175, whereby the insulating film 118af can be formed on the groove 175 with good coverage. In addition, deposition damage can be reduced. Preferably, the insulating film 118af is also formed over the conductive layer 123 included in the connection portion 140.

For the insulating film 118af, it is possible to use, for example, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material. It is particularly preferable to use a low-melting-point material such as aluminum or silver. The use of a metal material capable of blocking ultraviolet light for the insulating film 118af is preferable, in which case the EL layer can be inhibited from being irradiated with ultraviolet light and deteriorating.

For the insulating film 118af, a metal oxide such as In—Ga—Zn oxide can be used. As the insulating film 118af, an In—Ga—Zn oxide film can be formed by a sputtering method, for example. Furthermore, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like can be used. Alternatively, indium tin oxide containing silicon can also be used, for example.

In addition, in place of gallium described above, an element M(M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used. In particular, M is preferably one or more selected from gallium, aluminum, and yttrium.

As the insulating film 118af, a variety of inorganic insulating films that can be used as the protective layer 131 can be used. As the insulating film 118af, a variety of inorganic insulating films that can be used as the insulating layer containing an inorganic material can be used. In particular, an oxide insulating film is preferable because its adhesion to the EL layer is higher than that of a nitride insulating film. For example, an inorganic insulating material such as aluminum oxide, hafnium oxide, or silicon oxide can be used for the insulating film 118af. As the insulating film 118af, an aluminum oxide film can be formed by an ALD method, for example. The use of an ALD method is preferable, in which case damage to a base (in particular, the EL layer or the like) can be reduced.

In this embodiment, aluminum oxide is deposited as the insulating film 118af by an ALD method. It is necessary to form the insulating film 118af to have good coverage on the bottom surface and the side surface of the groove 175 provided in the insulating layer 105. By an ALD method, an atomic layer can be deposited one by one on the bottom surface and the side surface of the groove 175, whereby the insulating film 118af can be formed on the groove 175 with good coverage. In addition, deposition damage can be reduced.

For example, in the case where aluminum oxide is deposited by an ALD method, two kinds of gases, H₂O as an oxidizer and a source gas that is obtained by vaporizing liquid containing a solvent and an aluminum precursor compound (trimethylaluminum (TMA, Al(CH₃)₃) or the like) are used. Examples of another material include tris(dimethylamide)aluminum, triisobutylaluminum, and aluminum tris(2,2,6,6-tetramethyl-3,5-heptanedionate).

Note that the insulating film 118af may be formed by a sputtering method, a CVD method, or a PECVD method that provides a higher deposition rate than an ALD method. Thus, a highly reliable display apparatus can be fabricated with high productivity.

The insulating film 118af may have a stacked-layer structure of two or more layers.

For example, it is possible to employ a two-layer structure in which an inorganic insulating film (e.g., an aluminum oxide film) formed by an ALD method is used as the lower layer, and an inorganic film (e.g., an In—Ga—Zn oxide film, an aluminum film, or a tungsten film) formed by a sputtering method is used as the upper layer.

Then, a resist mask 190a is formed over the insulating film 118af (FIG. 18C). At this time, the resist mask 190a is formed in a portion overlapping with a region to be the layer 113a and part of the groove 175. Although not illustrated, the resist mask 190a is also formed in a portion overlapping with a region to be the layer 113e and a portion overlapping with a region to be the layer 113h. Preferably, the resist mask 190a is also formed in a portion overlapping with the conductive layer 123 included in the connection portion 140.

The end portion of the resist mask 190a is perpendicular to the surface of the layer 101 in FIG. 18C; however, the shape of the end portion of the resist mask 190a is not limited thereto. The end portion of the resist mask 190a may have a tapered shape or an inverse tapered shape.

Next, part of the insulating film 118af that is not covered with the resist mask 190a is removed, whereby the insulating layer 118a, the insulating layer 118e, and the insulating layer 118h can be formed. A dry etching method or a wet etching method can be used to remove the part of the insulating film 118af. At this time, in the connection portion 140, the insulating layer 118j is preferably formed in a portion overlapping with the conductive layer 123.

After that, the resist mask 190a is removed.

Next, part of the film 113af is removed by etching treatment using the insulating layer 118a, the insulating layer 118e, and the insulating layer 118h as hard masks, whereby the layer 113a, the layer 113e, and the layer 113h are formed. Thus, a stacked-layer structure of the layer 113a and the insulating layer 118a, a stacked-layer structure of the layer 113e and the insulating layer 118e, and a stacked-layer structure of the layer 113h and the insulating layer 118h remain over the pixel electrode 111a, the pixel electrode 111e, and the pixel electrode 111h, respectively.

Since the film 113af in the groove 175 is divided from a region to be the layer 113a, the film 113af in the groove 175 may remain without being removed.

In the above manner, the layer 113a and the pixel electrode 111a can be sealed with the insulating layer 105 and the insulating layer 118a. In addition, the layer 113e and the pixel electrode 111e can be sealed. The layer 113h and the pixel electrode 111h can be sealed.

During etching of the insulating film 118af, the insulating layer 105 is sometimes etched in a region where the insulating layer 105 is exposed without being covered with the pixel electrode, the EL layer, part of the EL layer, or the like. The etching rate of the insulating layer 105 in the case where the pixel electrode is provided moderately is sometimes different from that in the case where the insulating layer 105 is exposed widely. For example, when the pattern of the pixel electrode is provided moderately over the insulating layer 105, the etching rate of the insulating layer 105 at the time of etching the insulating film 118af can be reduced in some cases.

In the case where the insulating layer 105 is etched excessively, a conductive layer such as a wiring, an electrode, or a plug included in the layer 101 might be exposed, causing a short circuit between the conductive layer and the common electrode 115 in an unintended region.

The dummy pixel portion provided around the pixel portion 284 can inhibit excessive etching of the insulating layer 105, for example, and stabilize and improve the performance of the display apparatus 100.

### {Formation of Layer 113b, Insulating Layer 118b, and the Like}

The film 113bf is formed over the pixel electrode 111b, the pixel electrode 111c, the insulating layer 105, and the insulating layer 118a. The film 113bf is a film containing a second light-emitting compound. Although not illustrated, the film 113bf is also formed over the pixel electrode 11 if and the pixel electrode 111g.

The film containing the second light-emitting compound can be formed by, for example, an evaporation method, specifically a vacuum evaporation method. The film may be formed by a method such as a transfer method, a printing method, an ink-jet method, or a coating method.

In the formation of the film 113bf, disconnection occurs in the film 113bf by the groove 175. As a result, an island-shaped layer is formed over the pixel electrode 111b and the pixel electrode 111f. The layer 113b and the layer 113f can be formed by removing an unnecessary region of the film 113bf other than the island-shaped layers over the pixel electrode 111b and the pixel electrode 111f, for example.

Next, the insulating film 118bf is formed over the film 113bf and the insulating layer 105. The insulating film 118bf can be formed by a sputtering method, a CVD method, an MBE method, a PLD method, an ALD method, or the like as appropriate. The description of the insulating film 118af can be referred to for the insulating film 118bf.

Note that when patterns having similar structures are provided in the pixel portion 284 and the dummy pixel portion 294, the adhesion to the formation surface can be uniform in the formation step of the film 113bf.

In the formation of the film 113bf, it is preferable that the proportion of the area where the pixel electrodes are exposed, the proportion of the area where the insulating layer 105 is exposed, and the proportion of the area where the layers formed by processing the film 113af (the layer 113a and the layer 113e) are exposed be substantially the same as one another in the pixel portion 284 and the dummy pixel portion 294. Specifically, for example, when patterns of the pixel electrodes 111 are arranged in a matrix in the pixel portion 284 and similar patterns are arranged in a matrix in the dummy pixel portion 294, the adhesion to the formation surface can be uniform within the substrate plane in the formation step of the film 113bf, as compared to the case where the pixel electrode pattern is not provided in the dummy pixel portion 294. In the case where the pixel electrode pattern is not provided in the dummy pixel portion 294, a conductive layer that is the same layer as the pixel electrode is not provided in the dummy pixel portion 294 and the insulating layer 105 is widely exposed in some cases, for example. As another example, in the case where the pixel electrode pattern is not provided in the dummy pixel portion 294, a conductive layer that is the same layer as the pixel electrode is formed in the dummy pixel portion 294 as an electrode having a much larger area than the pattern of the pixel electrode 111.

Note that the pixels included in the dummy pixel portion do not necessarily have a function of emitting light. Accordingly, even in the case where the pixel portion 284 includes a plurality of kinds of light-emitting layers corresponding to different colors, all the pixels in the dummy pixel portion may include one kind of light-emitting layer corresponding to one color.

Next, a resist mask 190b is formed over the insulating film 118bf (FIG. 18D).

Then, the insulating film 118bf in a portion not covered with the resist mask 190b is removed, so that the insulating layer 118b and the insulating layer 118f can be formed. A dry etching method or a wet etching method can be used to remove part of the insulating film 118bf.

After that, the resist mask 190b is removed.

Next, part of the film 113bf is removed by etching treatment using the insulating layer 118b and the insulating layer 118f as hard masks, whereby the layer 113b and the layer 113f are formed. Thus, a stacked-layer structure of the layer 113b and the insulating layer 118b and a stacked-layer structure of the layer 113f and the insulating layer 118f remain over the pixel electrode 111b and the pixel electrode 111f, respectively.

In the above manner, the layer 113b and the pixel electrode 111b can be sealed with the insulating layer 105 and the insulating layer 118b. Moreover, the layer 113f and the pixel electrode 111f can be sealed.

### {Formation of Layer 113c, Insulating Layer 118c, and the Like}

The film 113cf is formed over the pixel electrode 111c, the insulating layer 105, the insulating layer 118a, and the insulating layer 118b. The film 113cf is a film containing a third light-emitting compound. Although not illustrated, the film 113cf is also formed over the pixel electrode 111g.

The film containing the third light-emitting compound can be formed by, for example, an evaporation method, specifically a vacuum evaporation method. The film may be formed by a method such as a transfer method, a printing method, an ink-jet method, or a coating method.

In the formation of the film 113cf, disconnection occurs in the film 113cf by the groove 175. As a result, an island-shaped layer is formed over the pixel electrode 111c and the pixel electrode 111g. The layer 113c and the layer 113g can be formed by removing an unnecessary region of the film 113cf other than the island-shaped layers over the pixel electrode 111c and the pixel electrode 111g, for example.

Next, an insulating film 118cf is formed over the film 113cf and the insulating layer 105. The insulating film 118cf can be formed by a sputtering method, a CVD method, an MBE method, a PLD method, an ALD method, or the like as appropriate. The description of the insulating film 118af can be referred to for the insulating film 118cf.

Then, a resist mask 190c is formed over the insulating film 118cf (FIG. 19A).

Subsequently, the insulating film 118cf in a portion not covered with the resist mask 190c is removed, so that the insulating layer 118c and the insulating layer 118g can be formed. A dry etching method or a wet etching method can be used to remove part of the insulating film 118cf.

After that, the resist mask 190c is removed.

Next, part of the film 113cf is removed by etching treatment using the insulating layer 118c and the insulating layer 118g as hard masks, whereby the layer 113c and the layer 113g are formed (FIG. 19B). Thus, a stacked-layer structure of the layer 113c and the insulating layer 118c and a stacked-layer structure of the layer 113g and the insulating layer 118g remain over the pixel electrode 111c and the pixel electrode 111g, respectively.

In the above manner, the layer 113c and the pixel electrode 111c can be sealed with the insulating layer 105 and the insulating layer 118c. Moreover, the layer 113g and the pixel electrode 111g can be sealed.

### {Formation of Insulating Layer 127, Common Layer 114, and Common Electrode 115}

Subsequently, a film to be the insulating layer 127 is formed over the insulating layer 105, the insulating layer 118a, the insulating layer 118b, the insulating layer 118c, the insulating layer 118e, the insulating layer 118f, the insulating layer 118g, and the insulating layer 118h. At this time, in the connection portion 140, the film to be the insulating layer 127 is preferably formed over the insulating layer 118j.

For the insulating layer 127, an insulating layer containing an organic material, for example, a resin layer can be used. For the insulating layer 127, an insulating layer containing an inorganic material can be used to be stacked with a resin layer. For example, the insulating layer 127 can have a stacked-layer structure of an insulating layer containing an inorganic material and a resin layer over the insulating layer.

The resin layer included in the insulating layer 127 is formed at a temperature lower than the upper temperature limit of the layer 113. The resin layer is preferably formed at a substrate temperature higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

The resin layer included in the insulating layer 127 is preferably formed by the aforementioned wet film formation method. The resin layer is preferably formed by, for example, spin coating using a photosensitive material; more specifically, the resin layer is preferably formed using a photosensitive resin composition containing an acrylic resin.

The resin layer is preferably formed using a resin composition containing a polymer, an acid-generating agent, and a solvent, for example. The polymer is formed using one or more kinds of monomers and has a structure in which one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

In the formation of the resin layer, heat treatment (also referred to as prebaking) is preferably performed after the formation. The heat treatment is performed at a temperature lower than the upper temperature limit of the layer 113a, the layer 113b, and the layer 113c. The substrate temperature during the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, a solvent contained in the resin layer can be removed.

Then, light exposure is performed such that part of the film to be the resin layer is exposed to visible rays or ultraviolet rays. Here, in the case where a positive photosensitive resin composition containing an acrylic resin is used for the insulating film, a region where the resin layer is not formed in a later step is irradiated with visible rays or ultraviolet rays. The resin layer included in the insulating layer 127 is formed in a region located between the pixel electrodes 111 of adjacent light-emitting devices. Thus, the pixel electrode 111 is irradiated with visible rays or ultraviolet rays. Note that in the case where a negative photosensitive material is used for the resin film, a region where the resin layer included in the insulating layer 127 is to be formed is irradiated with visible rays or ultraviolet rays.

The width of the insulating layer 127 can be controlled in accordance with a light-exposure region of the film to be the resin layer. In this embodiment, processing is performed such that the insulating layer 127 includes a region overlapping with the top surface of the pixel electrode 111.

Light used for the light exposure preferably includes the i-line (wavelength: 365 nm). Light used for the light exposure may include at least one of the g-line (wavelength: 436 nm) and the h-line (wavelength: 405 nm).

Next, development is performed to remove the light-exposure region of the film to be the resin layer, whereby the resin layer is formed. Here, in the case where an acrylic resin is used for the insulating film, an alkaline solution is preferably used as a developer, and for example, an aqueous solution of tetramethyl ammonium hydroxide (TMAH) can be used.

Then, a residue (scum) due to the development may be removed. For example, the residue can be removed by ashing using oxygen plasma.

Note that etching may be performed to adjust the surface level of the resin layer. The resin layer may be processed by ashing using oxygen plasma, for example. In the case where a non-photosensitive material is used for the resin film to be the resin layer, the surface level of the insulating film can be adjusted by the ashing, for example.

In the case where the resin layer is used as the insulating layer 127, etching treatment is subsequently performed using the insulating layer 127 as a mask, thereby removing part of the insulating layer 118a, part of the insulating layer 118b, part of the insulating layer 118c, part of the insulating layer 118e, part of the insulating layer 118f, part of the insulating layer 118g, and part of the insulating layer 118h.

Thus, an opening portion is formed in the insulating layer 118a so that the top surface of the layer 113a is exposed. An opening portion is formed in the insulating layer 118b so that the top surface of the layer 113b is exposed. An opening portion is formed in the insulating layer 118c so that the top surface of the layer 113c is exposed (FIG. 19C). At this time, it is preferable to form an opening portion in the insulating layer 118j so that the top surface of the conductive layer 123 is exposed, by removing part of the insulating layer 118j.

At this time, when an opening portion is not provided in the resin layer over the layer 113e, the layer 113f, the layer 113g, and the layer 113h although the structure is not illustrated, the dummy light-emitting devices 58a, 58b, and 58c illustrated in FIG. 6D and the dummy light-emitting device 59 illustrated in FIG. 8C can be fabricated.

The etching treatment is performed by wet etching. Using a wet etching method can reduce damage to the layer 113a, the layer 113b, and the layer 113c, as compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a mixed solution containing two or more of these acids, for example. In the case of using a wet etching method, a mixed acid chemical solution containing water, phosphoric acid, diluted hydrofluoric acid, and nitric acid may be used. A chemical solution used for the wet etching treatment may be alkaline or acid.

Note that in the case where the insulating layer 127 employs a stacked-layer structure of an insulating layer containing an inorganic material (hereinafter referred to as an insulating layer 127(1)) and a resin layer (hereinafter referred to as a resin layer 127(2)) over the insulating layer, first, a film to be the insulating layer 127(1) is formed over the insulating layer 105, the insulating layer 118a, the insulating layer 118b, and the insulating layer 118c.

Next, the resin layer 127(2) is formed by the above-described method. Then, etching treatment is performed using the resin layer 127(2) as a mask, thereby removing part of the film to be the insulating layer 127(1), part of the insulating layer 118a, part of the insulating layer 118b, part of the insulating layer 118c, part of the insulating layer 118e, part of the insulating layer 118f, part of the insulating layer 118g, and part of the insulating layer 118h.

Thus, an opening portion is formed in the film to be the insulating layer 127(1) and the insulating layer 118a so that the top surface of the layer 113a is exposed. An opening portion is formed in the film to be the insulating layer 127(1) and the insulating layer 118b so that the top surface of the layer 113b is exposed. An opening portion is formed in the film to be the insulating layer 127(1) and the insulating layer 118c so that the top surface of the layer 113c is exposed (FIG. 19C). At this time, it is preferable to form an opening portion in the film to be the insulating layer 127(1) and the insulating layer 118j so that the top surface of the conductive layer 123 is exposed, by removing part of the insulating layer 118j.

At this time, when an opening portion is not provided in the insulating layer 127 over the layer 113e, the layer 113f, the layer 113g, and the layer 113h although the structure is not illustrated, the dummy light-emitting devices 58a, 58b, and 58c illustrated in FIG. 6D and the dummy light-emitting device 59 illustrated in FIG. 8C can be fabricated.

After parts of the layers 113 are exposed, additional heat treatment may be performed. By the heat treatment, water contained in the layer 113, water adsorbed on the surface of the layer 113, and the like can be removed. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case dehydration at a lower temperature is possible. Note that the temperature range of the heat treatment is preferably set as appropriate in consideration of the upper temperature limit of the layer 113. In consideration of the upper temperature limit of the layer 113, a temperature higher than or equal to 70° C. and lower than or equal to 120° C. is particularly preferable in the above temperature ranges.

Then, the common layer 114 is formed over the layer 113 and the insulating layer 127. The common layer 114 can be formed by a method such as an evaporation method (including a vacuum evaporation method), a transfer method, a printing method, an ink-jet method, or a coating method.

Next, the common electrode 115 is formed over the common layer 114. The common electrode 115 can be formed by a sputtering method, a vacuum evaporation method, or the like. Alternatively, the common electrode 115 may be formed in such a manner that a film formed by an evaporation method and a film formed by a sputtering method are stacked.

The common electrode 115 is formed to overlap with the layer 113a, the layer 113b, the layer 113c, and the conductive layer 123 in opening portions formed in the insulating layer 127 and the insulating layer 118a.

In the above manner, the light-emitting devices 130a, 130b, and 130c, the dummy light-emitting device 58a, 58b, and 58c, and the dummy light-emitting device 59 can be formed.

Next, the protective layer 131 is formed over the common electrode 115 (FIG. 19D). The protective layer 131 can be formed by a vacuum evaporation method, a sputtering method, a CVD method, an ALD method, or the like.

Through the above process, the display apparatus 100 having the structure of one embodiment of the present invention can be manufactured.

According to the above manufacturing method example, when being sealed with the insulating layer 105 and the insulating layer 118, the layer 113 is not exposed to a chemical solution or the like used in removing the resist mask. Thus, the display apparatus of one embodiment of the present invention can be fabricated without using a metal mask for forming the layer 113.

Note that in the display apparatus of one embodiment of the present invention or the method for manufacturing the display apparatus, there is no particular limitation on the screen ratio (aspect ratio) of a display portion in the display apparatus. For example, the display apparatus is compatible with a variety of screen ratios such as 1:1 (a square), 3:4, 16:9, and 16:10.

This embodiment can be combined with the other embodiments as appropriate.

### Embodiment 2

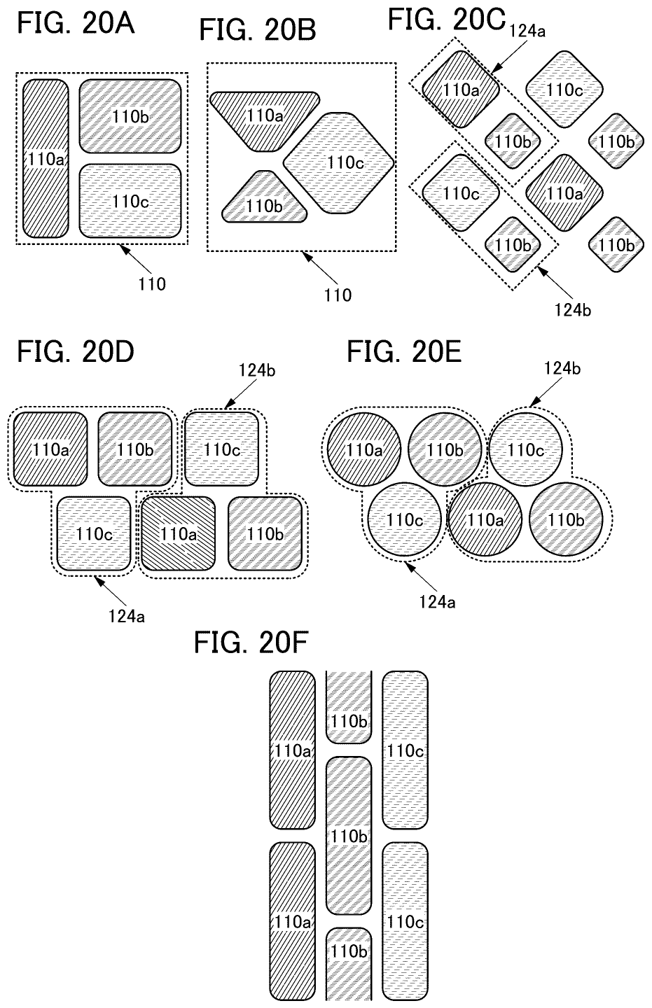

In this embodiment, a display apparatus of one embodiment of the present invention will be described with reference to FIG. 20 to FIG. 23.

### [Pixel Layout]

In this embodiment, pixel layouts different from that in FIG. 5 are mainly described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

Examples of the top surface shape of the subpixel include polygons such as a triangle, a tetragon (including a rectangle and a square), and a pentagon; polygons with rounded corners; an ellipse; and a circle. Here, the top surface shape of the subpixel corresponds to the top surface shape of a light-emitting region of the light-emitting device.

The range of the circuit layout for forming the subpixels is not limited to the range of the subpixels illustrated in a diagram, and the layout may be placed outside the range of the subpixels. For example, transistors included in the subpixel 110a may be positioned within the range of the subpixel 110b illustrated in a diagram, or some or all of the transistors may be positioned outside the range of the subpixel 110a.

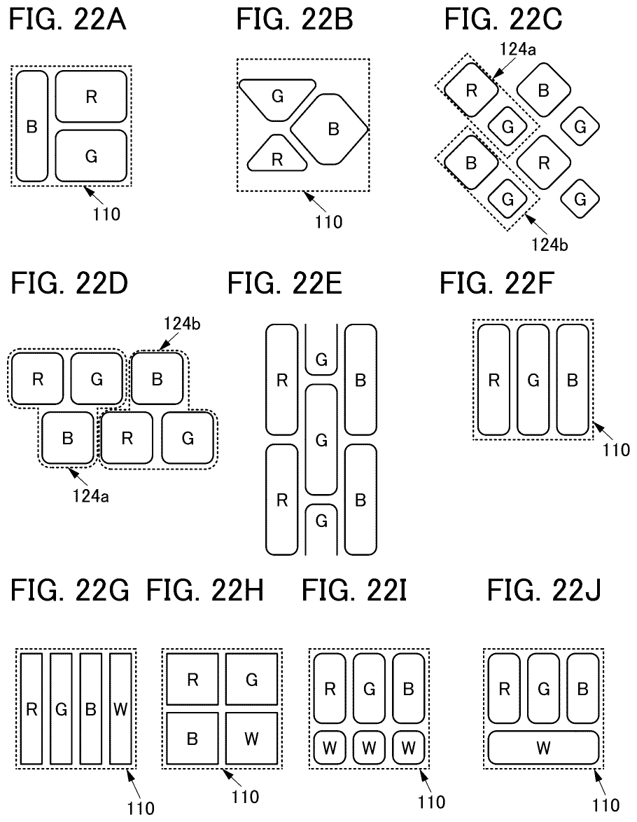

The pixel 110 illustrated in FIG. 20A employs S-stripe arrangement. The pixel 110 illustrated in FIG. 20A is composed of three subpixels 110a, 110b, and 110c. For example, as illustrated in FIG. 22A, the subpixel 110a may be a blue subpixel B, the subpixel 110b may be a red subpixel R, and the subpixel 110c may be a green subpixel G.

The pixel 110 illustrated in FIG. 20B includes the subpixel 110a whose top surface has a substantially trapezoidal shape with rounded corners, the subpixel 110b whose top surface has a substantially triangle shape with rounded corners, and the subpixel 110c whose top surface has a substantially tetragonal or substantially hexagonal shape with rounded corners. The subpixel 110a has a larger light-emitting area than the subpixel 110b. In this manner, the shapes and sizes of the subpixels can be determined independently. For example, the size of a subpixel including a light-emitting device with higher reliability can be smaller. For example, as illustrated in FIG. 22B, the subpixel 110a may be the green subpixel G, the subpixel 110b may be the red subpixel R, and the subpixel 110c may be the blue subpixel B.

Pixels 124a and 124b illustrated in FIG. 20C employ PenTile arrangement. FIG. 20C illustrates an example in which the pixels 124a each including the subpixel 110a and the subpixel 110b and the pixels 124b each including the subpixel 110b and the subpixel 110c are alternately arranged. For example, as illustrated in FIG. 22C, the subpixel 110a may be the red subpixel R, the subpixel 110b may be the green subpixel G, and the subpixel 110c may be the blue subpixel B.

The pixels 124a and 124b illustrated in FIG. 20D and FIG. 20E employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row). For example, as illustrated in FIG. 22D, the subpixel 110a may be the red subpixel R, the subpixel 110b may be the green subpixel G, and the subpixel 110c may be the blue subpixel B.

FIG. 20D illustrates an example in which the top surface of each subpixel has a substantially tetragonal shape with rounded corners, and FIG. 20E illustrates an example in which the top surface shape of each subpixel is circular.

FIG. 20F illustrates an example in which subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in the top view. For example, as illustrated in FIG. 22E, the subpixel 110a may be the red subpixel R, the subpixel 110b may be the green subpixel G, and the subpixel 110c may be the blue subpixel B.

In a photolithography method, as a pattern to be formed by processing becomes finer, the influence of light diffraction becomes more difficult to ignore; accordingly, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel may have a polygonal shape with rounded corners, an elliptical shape, a circular shape, or the like.

In the method for manufacturing the display apparatus of one embodiment of the present invention, an EL layer or an island-shaped layer including part of the EL layer may be processed into an island shape with the use of a resist mask. A resist film formed over the EL layer or the island-shaped layer including the part of the EL layer needs to be cured at a temperature lower than the upper temperature limit of the EL layer or the island-shaped layer including the part of the EL layer. Thus, the resist film is insufficiently cured in some cases depending on the upper temperature limit of the material of the EL layer or the island-shaped layer including the part of the EL layer and the curing temperature of the resist material. An insufficiently cured resist film may have a shape different from a desired shape when processed. As a result, the top surface of the EL layer or the island-shaped layer including the part of the EL layer sometimes has a polygonal shape with rounded corners, an elliptical shape, a circular shape, or the like. For example, when a resist mask with a square top surface shape is intended to be formed, a resist mask with a circular top surface shape might be formed and the top surface shape of the EL layer or the island-shaped layer including the part of the EL layer might be circular.

Note that to obtain a desired top surface shape of the EL layer or the island-shaped layer including the part of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

Also in the pixel 110 illustrated in FIG. 5, which employs stripe arrangement, for example, the subpixel 110a can be the red subpixel R, the subpixel 110b can be the green subpixel G, and the subpixel 110c can be the blue subpixel B as illustrated in FIG. 22F.

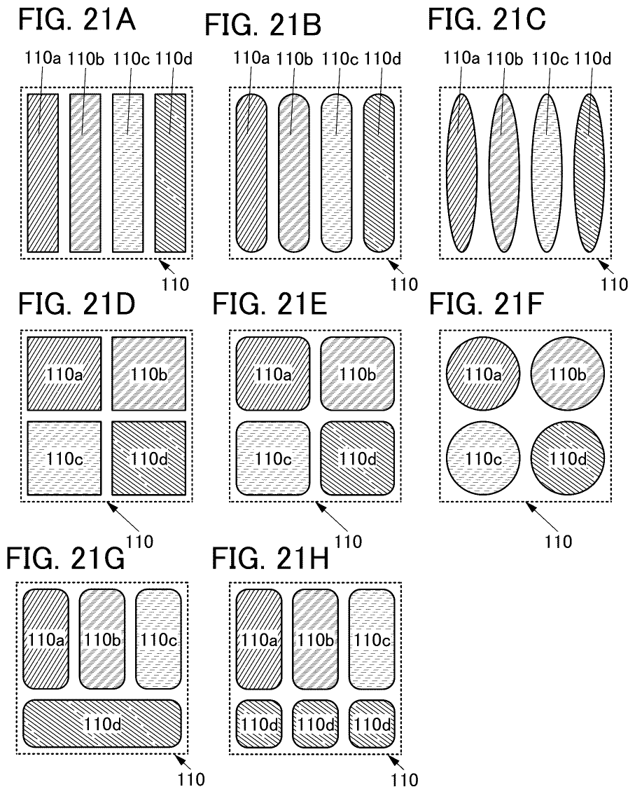

As illustrated in FIG. 21A to FIG. 21H, the pixel can include four types of subpixels.

The pixels 110 illustrated in FIG. 21A to FIG. 21C employ stripe arrangement.

FIG. 21A illustrates an example in which each subpixel has a rectangular top surface shape, FIG. 21B illustrates an example in which each subpixel has a top surface shape formed by combining two half circles and a rectangle, and FIG. 21C illustrates an example in which each subpixel has an elliptical top surface shape.

The pixels 110 illustrated in FIG. 21D to FIG. 21F employ matrix arrangement.

FIG. 21D illustrates an example in which each subpixel has a square top surface shape, FIG. 21E illustrates an example in which each subpixel has a substantially square top surface shape with rounded corners, and FIG. 21F illustrates an example in which each subpixel has a circular top surface shape.

FIG. 21G and FIG. 21H each illustrate an example in which one pixel 110 is composed of two rows and three columns.

The pixel 110 illustrated in FIG. 21G includes three subpixels (the subpixels 110a, 110b, and 110c) in the upper row (first row) and one subpixel (a subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 21H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and another subpixel 110d in the center column (second column), and the subpixel 110c and another subpixel 110d in the right column (third column). Aligning the positions of the subpixels in the upper row and the lower row as illustrated in FIG. 21H enables dust and the like that would be produced in the manufacturing process to be removed efficiently. Thus, a display apparatus with high display quality can be provided.

The pixels 110 illustrated in FIG. 21A to FIG. 21H are each composed of the four subpixels 110a, 110b, 110c, and 110d. The subpixels 110a, 110b, 110c, and 110d include light-emitting devices that emit light of different colors. The subpixels 110a, 110b, 110c, and 110d can be subpixels of four colors of R, G, B, and white (W), subpixels of four colors of R, G, B, and Y, or subpixels of R, G, B, and infrared light (IR), for example. For example, the subpixels 110a, 110b, 110c, and 110d can be red, green, blue, and white subpixels, respectively, as illustrated in FIG. 22G to FIG. 22J.

The display apparatus of one embodiment of the present invention may include a light-receiving device (also referred to as light-receiving element) in the pixel.

Three of the four subpixels included in the pixel 110 illustrated in FIG. 22G to FIG. 22J may each include a light-emitting device and the other one may include a light-receiving device.

For example, the subpixels 110a, 110b, and 110c may be subpixels of three colors of R, G, and B, and the subpixel 110d may be a subpixel including a light-receiving device.

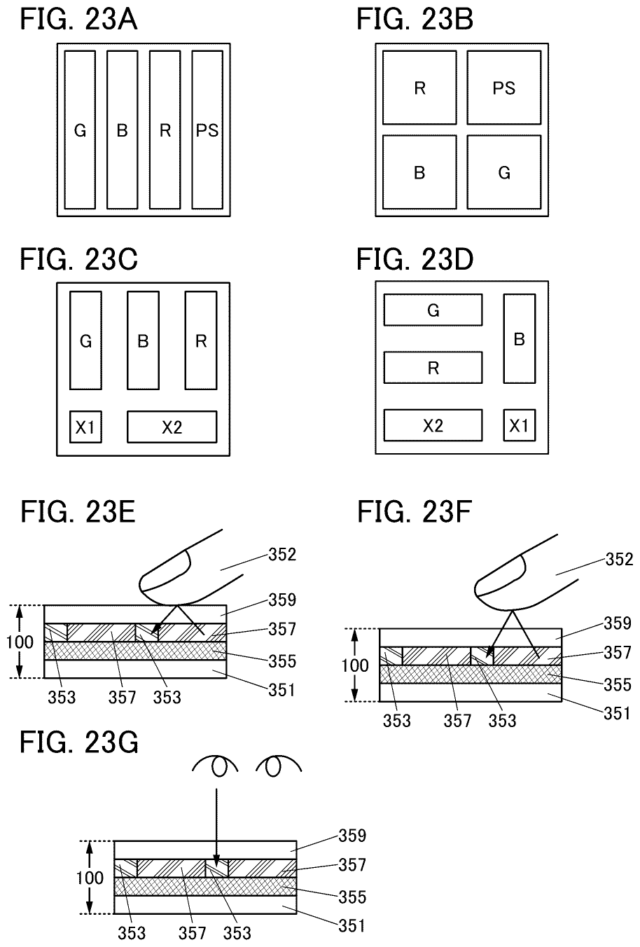

Pixels illustrated in FIG. 23A and FIG. 23B each include the subpixel G, the subpixel B, the subpixel R, and a subpixel PS. Note that the arrangement order of the subpixels is not limited to the structures illustrated in the drawings and can be determined as appropriate. For example, the positions of the subpixel G and the subpixel R may be interchanged with each other.

The pixel illustrated in FIG. 23A employs stripe arrangement. The pixel illustrated in FIG. 23B employs matrix arrangement.

The subpixel R includes a light-emitting device that emits red light. The subpixel G includes a light-emitting device that emits green light. The subpixel B includes a light-emitting device that emits blue light.

The subpixel PS includes a light-receiving device. There is no particular limitation on the wavelength of light detected by the subpixel PS. The subpixel PS can have a structure capable of detecting one or both of infrared light and visible light.

Pixels illustrated in FIG. 23C and FIG. 23D each include the subpixel G, the subpixel B, the subpixel R, a subpixel X1, and a subpixel X2. Note that the arrangement order of the subpixels is not limited to the structures illustrated in the drawings and can be determined as appropriate. For example, the positions of the subpixel G and the subpixel R may be interchanged with each other.

FIG. 23C illustrates an example where one pixel is provided in two rows and three columns. Three subpixels (the subpixel G, the subpixel B, and the subpixel R) are provided in the upper row (first row). In FIG. 23C, two subpixels (the subpixel X1 and the subpixel X2) are provided in the lower row (second row).

FIG. 23D illustrates an example where one pixel is composed of three rows and two columns. In FIG. 23D, the pixel includes the subpixel G in the first row, the subpixel R in the second row, and the subpixel B across these two rows. In addition, two subpixels (the subpixel X1 and the subpixel X2) are provided in the third row. In other words, the pixel illustrated in FIG. 23D includes three subpixels (the subpixel G, the subpixel R, and the subpixel X2) in the left column (first column) and two subpixels (the subpixel B and the subpixel X1) in the right column (second column).

The layout of the subpixels R, G, and B illustrated in FIG. 23C is stripe arrangement. The layout of the subpixels R, G, and B illustrated in FIG. 23D is what is called S-stripe arrangement. Thus, high display quality can be achieved.

At least one of the subpixel X1 and the subpixel X2 preferably includes the light-receiving device (i.e., at least one of the subpixel X1 and the subpixel X2 is preferably the subpixel PS).

Note that the pixel layout including the subpixel PS is not limited to the structures in FIG. 23A to FIG. 23D.

The subpixel X1 or the subpixel X2 can include a light-emitting device that emits infrared light (IR), for example. In that case, the subpixel PS preferably detects infrared light. For example, with one of the subpixel X1 and the subpixel X2 used as a light source, reflected light of light emitted by the light source can be detected by the other of the subpixel X1 and the subpixel X2 while an image is displayed using the subpixels R, G, and B.

A structure that includes a light-receiving device can be used for both the subpixel X1 and the subpixel X2. In that case, the wavelength range of light detected by the subpixel X1 may be the same as, different from, or partially the same as the wavelength range of light detected by the subpixel X2. For example, one of the subpixel X1 and the subpixel X2 may mainly detect visible light and the other may mainly detect infrared light.

The light-receiving area of the subpixel X1 is smaller than the light-receiving area of the subpixel X2. A smaller light-receiving area leads to a narrower image-capturing range, inhibits a blur in a captured image, and improves the definition. Thus, the use of the subpixel X1 enables higher-resolution or higher-definition image capturing than the use of the light-receiving device included in the subpixel X2. For example, image capturing for personal authentication with the use of a fingerprint, a palm print, the iris, the shape of a blood vessel (including the shape of a vein and the shape of an artery), a face, or the like is possible by using the subpixel X1.

The light-receiving device included in the subpixel PS preferably detects visible light, and preferably detects one or more colors of blue, violet, bluish violet, green, yellowish green, yellow, orange, red, and the like. The light-receiving device included in the subpixel PS may detect infrared light.

In the case where the subpixel X2 has a structure that includes the light-receiving device, the subpixel X2 can be used in a touch sensor (also referred to as a direct touch sensor), a near touch sensor (also referred to as a hover sensor, a hover touch sensor, a contactless sensor, or a touchless sensor), or the like. The wavelength of light detected by the subpixel X2 can be determined as appropriate depending on the application purpose. For example, the subpixel X2 preferably detects infrared light. In that case, a touch can be detected even in a dark place.

Here, a touch sensor or a near touch sensor can detect proximity or contact of an object (e.g., a finger, a hand, or a pen).

The touch sensor can detect an object when the display apparatus and the object come in direct contact with each other. The near touch sensor can detect an object even when the object is not in contact with the display apparatus. For example, the display apparatus is preferably capable of detecting an object when the distance between the display apparatus and the object is greater than or equal to 0.1 mm and less than or equal to 300 mm, preferably greater than or equal to 3 mm and less than or equal to 50 mm. With this structure, the display apparatus can be operated without an object directly contacting with the display apparatus; in other words, the display apparatus can be operated in a contactless (touchless) manner. With the above-described structure, the display apparatus can have a reduced risk of being dirty or damaged, or can be operated without the object directly touching a dirt (e.g., dust or a virus) attached to the display apparatus.

The refresh rate of the display apparatus of one embodiment of the present invention can be variable. For example, the refresh rate is adjusted (adjusted within the range of 1 Hz to 240 Hz, for example) in accordance with contents displayed on the display apparatus, whereby power consumption can be reduced. The driving frequency of the touch sensor or the near touch sensor may be changed in accordance with the refresh rate. In the case where the refresh rate of the display apparatus is 120 Hz, for example, the driving frequency of the touch sensor or the near touch sensor can be higher than 120 Hz (typically 240 Hz). This structure reduces power consumption and increases the response speed of the touch sensor or the near touch sensor.

The display apparatus 100 illustrated in FIG. 23E to FIG. 23G includes a layer 353 including alight-receiving device, a functional layer 355, and a layer 357 including a light-emitting device, between a substrate 351 and a substrate 359.

The functional layer 355 includes a circuit for driving the light-receiving device and a circuit for driving the light-emitting device. A switch, a transistor, a capacitor, a resistor, a wiring, a terminal, and the like can be provided in the functional layer 355. Note that in the case where the light-emitting devices and the light-receiving devices are driven by a passive-matrix method, a structure not provided with a switch or a transistor may be employed.

For example, after light emitted from the light-emitting device in the layer 357 including a light-emitting device is reflected by a finger 352 that touches the display apparatus 100 as illustrated in FIG. 23E, the light-receiving device in the layer 353 including a light-receiving device senses the reflected light. Thus, the touch of the finger 352 on the display apparatus 100 can be detected.

The display apparatus may have a function of detecting an object that is close to (i.e., not touching) the display apparatus as illustrated in FIG. 23F and FIG. 23G or capturing an image of such an object. FIG. 23F illustrates an example in which a human finger is detected, and FIG. 23G illustrates an example in which information on the surroundings, surface, or inside of the human eye (e.g., the number of blinks, the movement of an eyeball, and the movement of an eyelid) is detected.

In the display apparatus of this embodiment, an image of the periphery of an eye, the surface of the eye, or the inside (fundus or the like) of the eye of a user of a wearable device can be captured with the use of the light-receiving device. Therefore, the wearable device can have a function of detecting one or more selected from a blink, movement of an iris, and movement of an eyelid of the user.

As described above, the pixel composed of the subpixels each including the light-emitting device can employ any of a variety of layouts in the display apparatus of one embodiment of the present invention. The display apparatus of one embodiment of the present invention can have a structure in which the pixel includes both a light-emitting device and a light-receiving device. Also in that case, any of a variety of layouts can be employed.

This embodiment can be combined with the other embodiments as appropriate.

### Embodiment 3

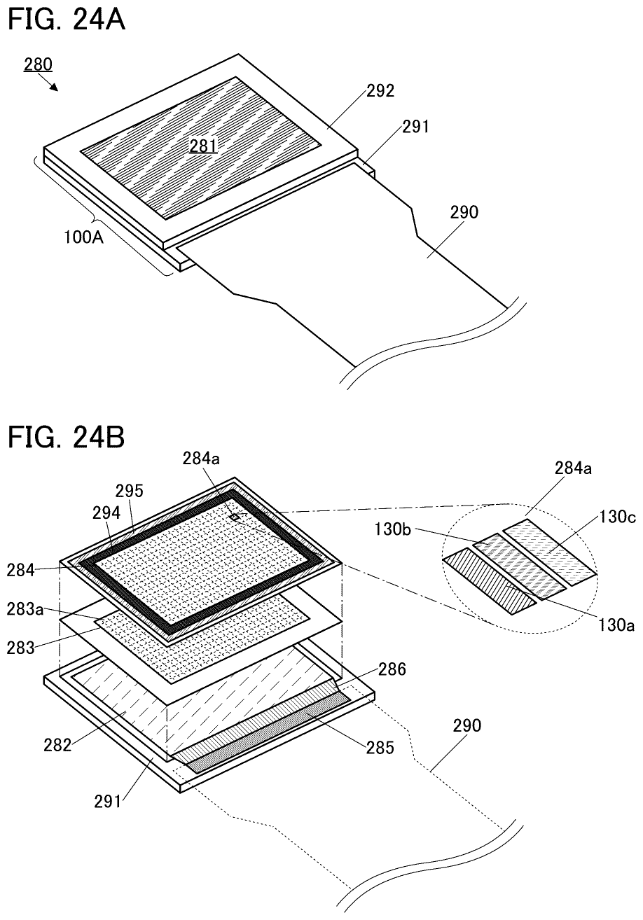

In this embodiment, display apparatuses of embodiments of the present invention will be described with reference to FIG. 24 to FIG. 33.

The display apparatus of this embodiment can be a high-resolution display apparatus. Accordingly, the display apparatus of this embodiment can be used for display portions of information terminals (wearable devices) such as watch-type and bracelet-type information terminals and display portions of wearable devices that can be worn on a head, such as a VR device like a head-mounted display and a glasses-type AR device.

The display apparatus of this embodiment can be a high-definition display apparatus or a large-sized display apparatus. Accordingly, the display apparatus of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

### [Display Module]

FIG. 24A is a perspective view of a display module 280. The display module 280 includes a display apparatus 100A and an FPC 290. Note that the display apparatus included in the display module 280 is not limited to the display apparatus 100A and may be any of a display apparatus 100B to a display apparatus 100F described later.

The display module 280 includes a substrate 291 and a substrate 292. The display module 280 includes a display portion 281. The display portion 281 is a region of the display module 280 where an image is displayed, and is a region where light emitted from pixels provided in the pixel portion 284 described later can be seen.

FIG. 24B is a perspective view schematically illustrating a structure on the substrate 291 side. Over the substrate 291, a circuit portion 282, a pixel circuit portion 283 over the circuit portion 282, and the pixel portion 284, the dummy pixel portion 294, and the dummy pixel portion 295 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings. Note that the display module 280 may employ a structure in which either the dummy pixel portion 294 or the dummy pixel portion 295 is not provided.

The pixel portion 284 includes a plurality of pixels 284a arranged periodically. An enlarged view of one pixel 284a is illustrated on the right side of FIG. 24B. The pixel 284a includes the light-emitting device 130a, the light-emitting device 130b, and the light-emitting device 130c. The light-emitting device 130a is a light-emitting device that emits red light, for example. The light-emitting device 130b is a light-emitting device that emits green light, for example. The light-emitting device 130c is a light-emitting device that emits blue light, for example.

The pixel circuit portion 283 includes a plurality of pixel circuits 283a arranged periodically.

One pixel circuit 283a is a circuit controlling light emission of the three light-emitting devices included in one pixel 284a. One pixel circuit 283a may be provided with three circuits for controlling light emission of the respective light-emitting devices. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active-matrix display apparatus is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The dummy pixel portion 294 includes a plurality of dummy pixels. The dummy pixels included in the dummy pixel portion 294 are not electrically connected to the circuit portion 282 in some cases. A structure can alternatively be employed in which some of the plurality of dummy pixels included in the dummy pixel portion 294 are electrically connected to the circuit portion 282, and the other dummy pixels are not electrically connected to the circuit portion 282.

In the case where the dummy pixels included in the dummy pixel portion 294 are not electrically connected to the circuit portion 282, a later-described plug 256 and the like are not provided under the pixel electrodes of the dummy pixels in some cases.

Alternatively, even when the dummy pixels included in the dummy pixel portion 294 are not electrically connected to the circuit portion 282, the later-described plugs 256 may be provided under the pixel electrodes of the dummy pixels. In the case where the plugs 256 are provided, the plugs 256 are not necessarily electrically connected to transistors 310. Alternatively, the plugs 256 provided may be electrically connected to the transistors 310.

Each of the dummy pixels in the dummy pixel portion 294 includes a pixel electrode and an EL layer, for example. Each of the dummy pixels in the dummy pixel portion 294 has a structure similar to that of the pixel 284a in some cases.

To each of the dummy pixels included in the dummy pixel portion 294, the structure of the dummy pixel 51 or the like described in the above embodiment can be applied.

The dummy pixel portion 295 includes a plurality of dummy pixels.

The dummy pixels included in the dummy pixel portion 295 are not electrically connected to the circuit portion 282 in some cases. A structure can alternatively be employed in which some of the plurality of dummy pixels included in the dummy pixel portion 295 are electrically connected to the circuit portion 282, and the other dummy pixels are not electrically connected to the circuit portion 282. In the case where the dummy pixels included in the dummy pixel portion 295 are not electrically connected to the circuit portion 282, the later-described plugs 256 and the like are not provided under the pixel electrodes of the dummy pixels in some cases. Alternatively, even when the dummy pixels included in the dummy pixel portion 295 are not electrically connected to the circuit portion 282, the later-described plugs 256 may be provided under the pixel electrodes of the dummy pixels. In the case where the plugs 256 are provided, the plugs 256 are not necessarily electrically connected to the transistors 310. Alternatively, the plugs 256 provided may be electrically connected to the transistors 310.

To each of the dummy pixels included in the dummy pixel portion 295, the structure of the dummy pixel 52 or the like described in the above embodiment can be applied.

The display module 280 can have a structure in which one or both of the pixel circuit portion 283 and the circuit portion 282 are provided to be stacked below the pixel portion 284; thus, the aperture ratio (effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as a head-mounted display or a glasses-type AR device. For example, even with a structure where the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be suitably used for a display portion of a wearable electronic device, such as a watch.

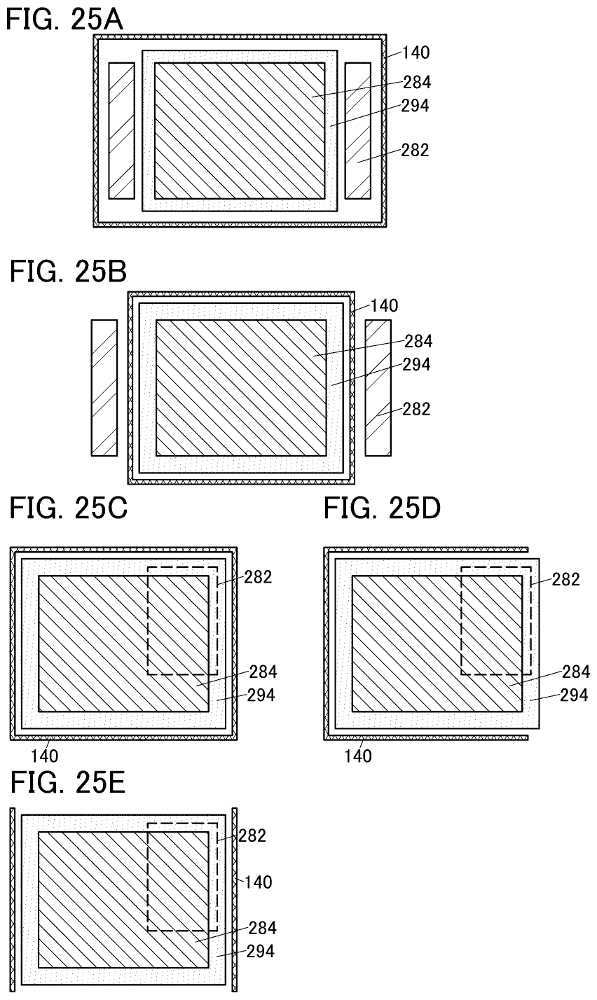

FIG. 25A to FIG. 25D are top views each illustrating a positional relation between the pixel portion 284, the dummy pixel portion 294, the circuit portion 282, and the connection portion 140 seen from above.

FIG. 25A illustrates an example in which the circuit portions 282 are provided on the left and right sides of the pixel portion 284, the connection portion 140 is placed along the four sides of a tetragon, and the pixel portion 284, the dummy pixel portion 294, and the circuit portions 282 are provided inside the tetragonal region surrounded by the connection portion 140.

FIG. 25B illustrates an example in which the circuit portions 282 are provided on the left and right sides of the pixel portion 284, the connection portion 140 is placed along the four sides of a tetragon, the pixel portion 284 and the dummy pixel portion 294 are provided inside the tetragonal region surrounded by the connection portion 140, and the circuit portions 282 are provided outside the tetragonal region.

FIG. 25C illustrates an example in which the connection portion 140 is placed along the four sides of a tetragon, the pixel portion 284 and the dummy pixel portion 294 are provided inside the tetragonal region surrounded by the connection portion 140, and the circuit portion 282 is provided to overlap with the pixel portion 284 and the dummy pixel portion 294.

FIG. 25D is different from FIG. 25C mainly in that the connection portion 140 is placed along three sides of a tetragon.

FIG. 25E is different from FIG. 25C mainly in that the connection portions 140 are placed along two opposite sides of a tetragon.

### [Display Apparatus 100A]

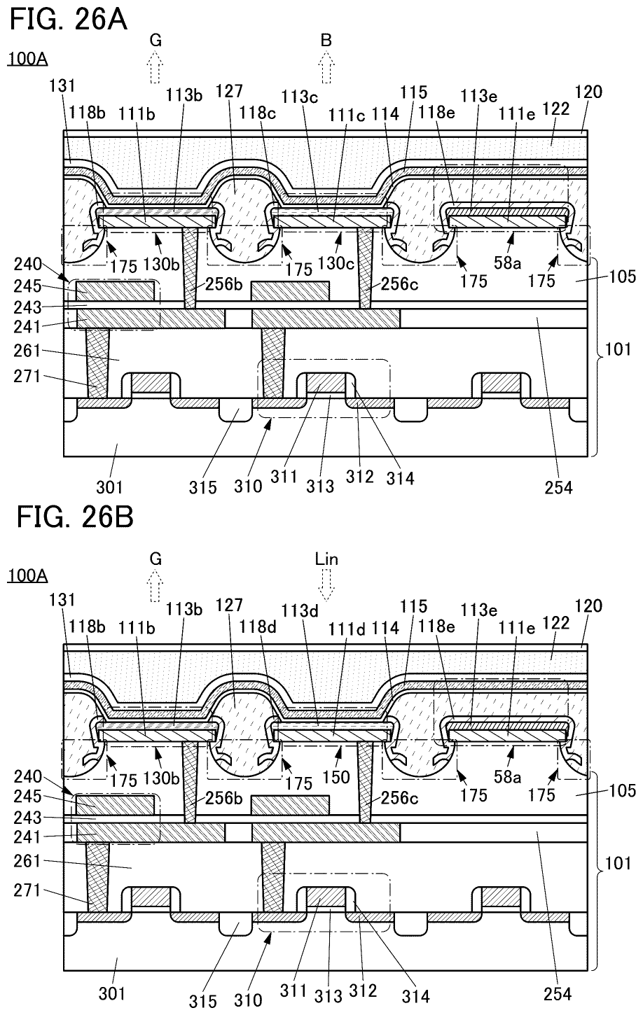

The display apparatus 100A illustrated in FIG. 26A includes a substrate 301, the light-emitting device 130b, the light-emitting device 130c, the dummy light-emitting device 58a, a capacitor 240, and the transistor 310. Although not illustrated, the display apparatus 100A includes the light-emitting device 130a, the dummy light-emitting device 58b, the dummy light-emitting device 58c, and the like over the substrate 301. The light-emitting device 130a emits red light, for example. The light-emitting device 130b emits green light (G), for example. The light-emitting device 130c emits blue light (B), for example.

The substrate 301 corresponds to the substrate 291 in FIG. 24A and FIG. 24B. The layer 101 and the insulating layer 105 thereover that are described in Embodiment 1 can be applied to the stacked-layer structure that includes the substrate 301 and the components thereover up to the insulating layer 105. The plug 139 can be applied to a plug 256b and a plug 256c.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311 and functions as an insulating layer.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

The insulating layer 105 is provided to cover the capacitor 240.

In FIG. 26A, the light-emitting device 130b, the light-emitting device 130c, and the dummy light-emitting device 58a are provided over the insulating layer 105. FIG. 26A illustrates an example where the light-emitting device 130b and the light-emitting device 130c each have the stacked-layer structure illustrated in FIG. 6C and the dummy light-emitting device 58a has the stacked-layer structure illustrated in FIG. 6D.

Since the layer 113b and the layer 113c are separated and are apart from each other in the display apparatus 100A, generation of crosstalk between adjacent subpixels can be inhibited even when the display apparatus 100A has high resolution. Accordingly, the display apparatus can have high resolution and high display quality.

The groove 175 is provided in the insulating layer 105 in a region between adjacent light-emitting devices. Moreover, the insulating layer 127 is provided in the region between the adjacent light-emitting devices.

The layer 113e of the dummy light-emitting device 58a is covered with the insulating layer 118e and the insulating layer 127, and the common layer 114 and the common electrode 115 are provided over the insulating layer 127.

The insulating layer 118b is positioned over the layer 113b of the light-emitting device 130b, and the insulating layer 118c is positioned over the layer 113c of the light-emitting device 130c.

The pixel electrode 111b and the pixel electrode 111c of the light-emitting devices are each electrically connected to the one of the source and the drain of the transistor 310 through a plug such as the plug 256b or the plug 256c embedded in the insulating layer 105, the conductive layer 241 embedded in the insulating layer 254, and the plug 271 embedded in the insulating layer 261. The top surface of the insulating layer 105 is level with or substantially level with the top surfaces of the plugs 256.

Meanwhile, it is preferable that the dummy light-emitting device 58a not have a function of emitting light. Thus, a structure is employed in which a plug embedded in the insulating layer 105 is not provided below the dummy light-emitting device 58a.

The protective layer 131 is provided over the light-emitting device 130b, the light-emitting device 130c, and the dummy light-emitting device 58a. The substrate 120 is attached to the protective layer 131 with the resin layer 122. The substrate 120 corresponds to the substrate 292 in FIG. 24A.

Although the display apparatus 100A includes the light-emitting device 130b and the light-emitting device 130c in this example, the display apparatus of this embodiment may further include a light-receiving device.

FIG. 26B illustrates an example of a display apparatus that includes the light-emitting device 130b, a light-receiving device 150, and the dummy light-emitting device 58a. The light-receiving device 150 includes the pixel electrode 111d, a layer 113d, the common layer 114, and the common electrode 115 that are stacked. The pixel electrode 111d can be formed by processing a layer to be the pixel electrode 111a. The layer 113d preferably functions as an active layer. Light (Lin) enters the light-receiving device 150 from the outside of the display apparatus.

### [Display Apparatus 100B]

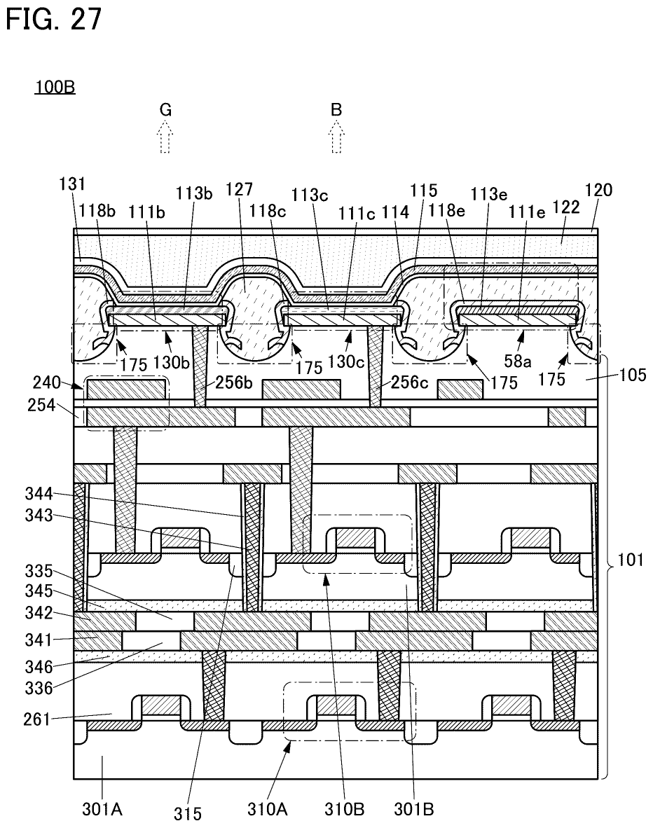

The display apparatus 100B illustrated in FIG. 27 has a structure where a transistor 310A and a transistor 310B in each of which a channel is formed in a semiconductor substrate are stacked. Note that in the description of the display apparatus below, portions similar to those of the above-mentioned display apparatus are not described in some cases.

In the display apparatus 100B, a substrate 301B provided with the transistor 310B, the capacitor 240, and the light-emitting devices is attached to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layers 345 and 346 are insulating layers functioning as protective layers and can inhibit diffusion of impurities into the substrate 301B and the substrate 301A. For the insulating layers 345 and 346, an inorganic insulating film that can be used for the protective layer 131 or an insulating layer 332 can be used.

The substrate 301B is provided with a plug 343 that penetrates the substrate 301B and the insulating layer 345. An insulating layer 344 is preferably provided to cover the side surface of the plug 343. The insulating layer 344 is an insulating layer functioning as a protective layer and can inhibit diffusion of impurities into the substrate 301B. For the insulating layer 344, an inorganic insulating film that can be used for the protective layer 131 can be used.

A conductive layer 342 is provided to cover at least part of the insulating layer 345 on the rear surface of the substrate 301B (the surface opposite to the substrate 120). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

Over the substrate 301A, a conductive layer 341 is provided over the insulating layer 346. The conductive layer 341 is preferably provided to be embedded in an insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the planarity of a plane formed by the conductive layer 342 and the insulating layer 335 and a plane formed by the conductive layer 341 and the insulating layer 336 allows the conductive layer 341 and the conductive layer 342 to be attached to each other favorably.

The conductive layer 341 and the conductive layer 342 are preferably formed using the same conductive material. For example, it is possible to use a metal film containing an element selected from Al, Cr, Cu, Ta, Ti, Mo, and W, a metal nitride film containing any of the above elements as a component (a titanium nitride film, a molybdenum nitride film, or a tungsten nitride film), or the like. Copper is particularly preferably used for the conductive layer 341 and the conductive layer 342. In that case, it is possible to employ Cu-to-Cu (copper-to-copper) direct bonding technique (a technique for achieving electrical continuity by connecting Cu (copper) pads).

### [Display Apparatus 100C]

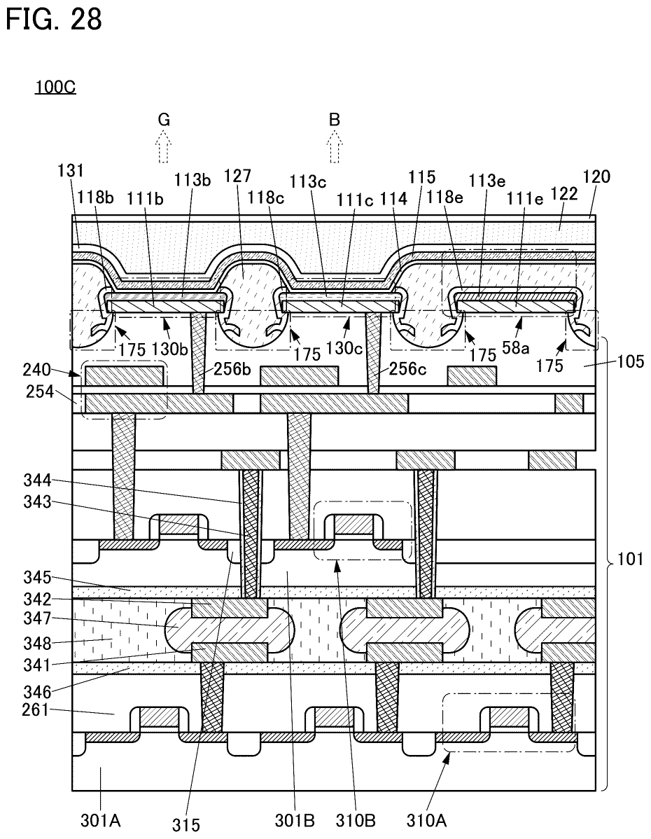

The display apparatus 100C illustrated in FIG. 28 has a structure in which the conductive layer 341 and the conductive layer 342 are bonded to each other through a bump 347.

As illustrated in FIG. 28, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Apparatus 100D]

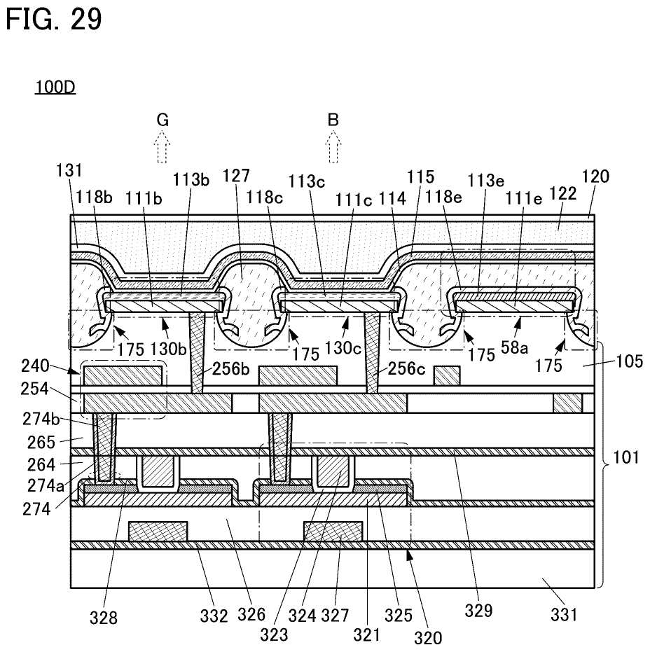

The display apparatus 100D illustrated in FIG. 29 differs from the display apparatus 100A mainly in a structure of a transistor.

A transistor 320 is a transistor that contains a metal oxide (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 24A and FIG. 24B. A stacked-layer structure including the substrate 331 and the components thereover up to the insulating layer 105 corresponds to the layer 101 in Embodiment 1. As the substrate 331, an insulating substrate or a semiconductor substrate can be used.

The insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. For the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film having semiconductor characteristics. The pair of conductive layers 325 are provided over and in contact with the semiconductor layer 321 and function as a source electrode and a drain electrode.

An insulating layer 328 is provided to cover the top surfaces and the side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water and hydrogen from the insulating layer 264 and the like into the semiconductor layer 321 and release of oxygen from the semiconductor layer 321. For the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are subjected to planarization treatment so that they are level with or substantially level with one another, and an insulating layer 329 and an insulating layer 265 are provided to cover these layers.

The insulating layer 264 and the insulating layer 265 function as interlayer insulating layers. The insulating layer 329 functions as a barrier layer that prevents diffusion of impurities such as water and hydrogen from the insulating layer 265 or the like into the transistor 320. For the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers the side surface of an opening formed in the insulating layer 265, the insulating layer 329, the insulating layer 264, and the insulating layer 328 and part of the top surface of the conductive layer 325, and a conductive layer 274b in contact with the top surface of the conductive layer 274a. For the conductive layer 274a, a conductive material that does not easily allow diffusion of hydrogen and oxygen is preferably used.

### [Display Apparatus 100E]

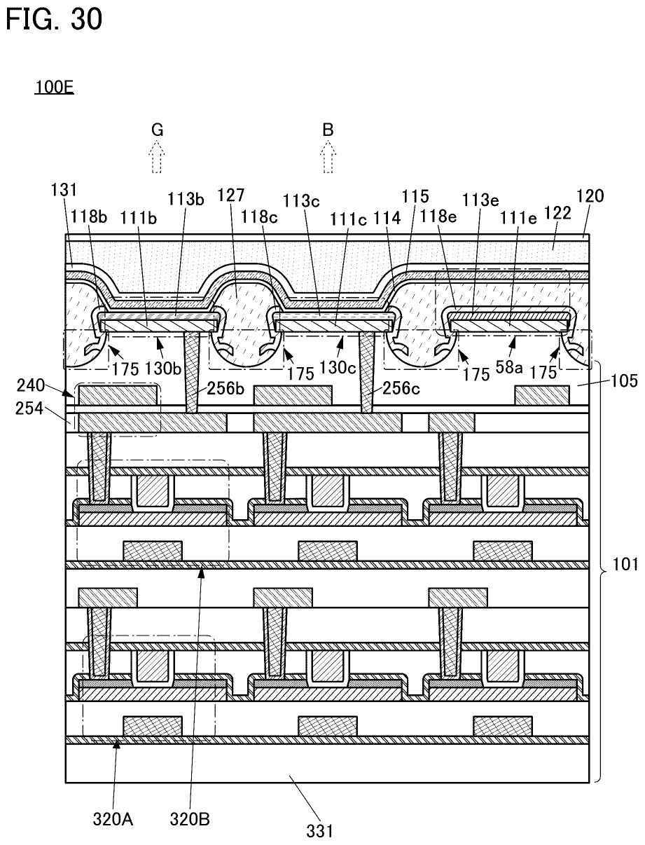

The display apparatus 100E illustrated in FIG. 30 has a structure in which a transistor 320A and a transistor 320B each including an oxide semiconductor in a semiconductor where a channel is formed are stacked.

The description of the display apparatus 100D can be referred to for the transistor 320A, the transistor 320B, and the components around them.

Although the structure where two transistors including an oxide semiconductor are stacked is described here, the present invention is not limited thereto. For example, three or more transistors may be stacked.

### [Display Apparatus 100F]

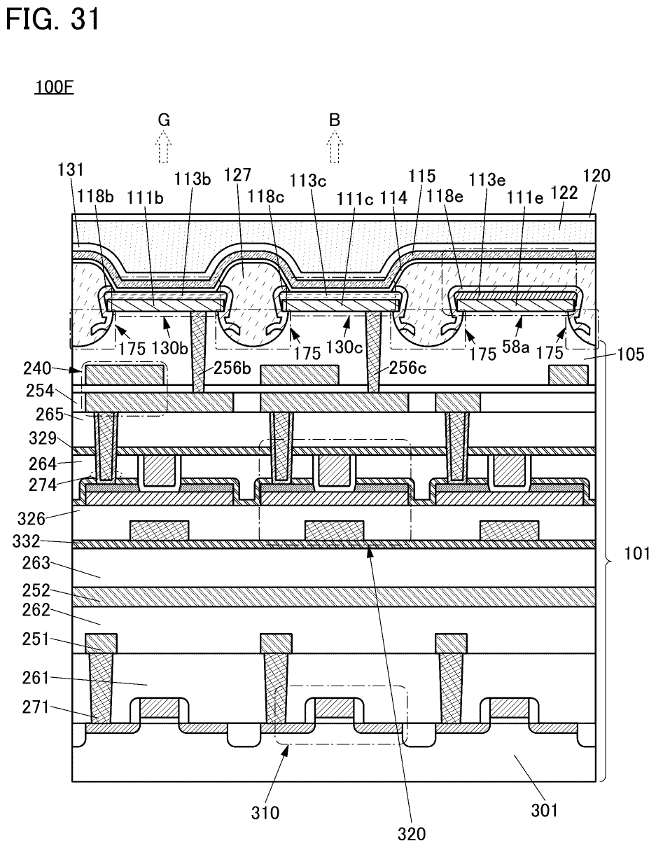

The display apparatus 100F illustrated in FIG. 31 has a structure in which the transistor 310 whose channel is formed in the substrate 301 and the transistor 320 containing a metal oxide in a semiconductor layer where a channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 310 and the transistor 320 can also be used as transistors included in a variety of circuits such as an arithmetic circuit and a memory circuit.

With such a structure, not only the pixel circuit but also the driver circuit or the like can be formed directly under the light-emitting devices; thus, the display apparatus can be downsized as compared to the case where a driver circuit is provided around a display region.

### [Display Apparatus 100G]

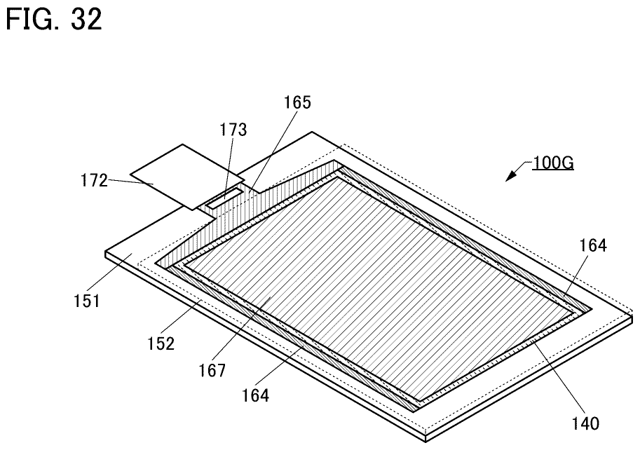

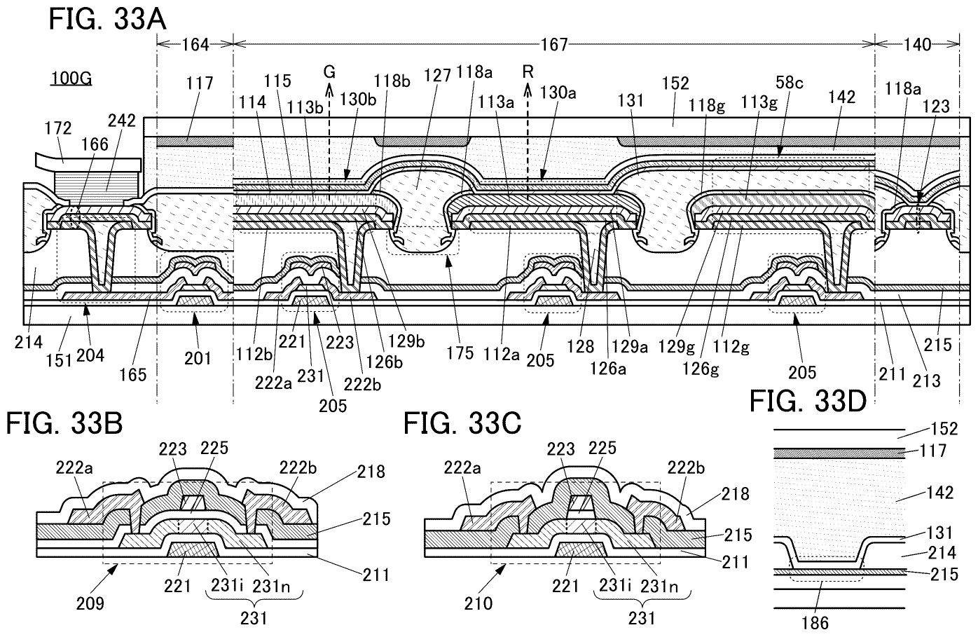

FIG. 32 is a perspective view of a display apparatus 100G, and FIG. 33A is a cross-sectional view of the display apparatus 100G.

In the display apparatus 100G, a substrate 152 and a substrate 151 are attached to each other. In FIG. 32, the substrate 152 is denoted by a dashed line.

The display apparatus 100G includes a display portion 167, the connection portion 140, a circuit 164, a wiring 165, and the like. FIG. 32 illustrates an example in which an IC 173 and an FPC 172 are mounted on the display apparatus 100G. Thus, the structure illustrated in FIG. 32 can also be regarded as a display module including the display apparatus 100G, the IC (integrated circuit), and the FPC.

The connection portion 140 is provided outside the display portion 167. The connection portion 140 can be provided along one or more sides of the display portion 167. The number of connection portions 140 may be one or more. FIG. 32 illustrates an example in which the connection portion 140 is provided to surround the four sides of the display portion. A common electrode of a light-emitting device is electrically connected to a conductive layer in the connection portion 140, so that a potential can be supplied to the common electrode.

As the circuit 164, a scan line driver circuit can be used, for example.

The wiring 165 has a function of supplying a signal and power to the display portion 167 and the circuit 164. The signal and power are input to the wiring 165 from the outside through the FPC 172 or input to the wiring 165 from the IC 173.

FIG. 32 illustrates an example where the IC 173 is provided over the substrate 151 by a COG (Chip On Glass) method, a COF (Chip on Film) method, or the like. An IC including a scan line driver circuit, a signal line driver circuit, or the like can be used as the IC 173, for example. Note that the display apparatus 100G and the display module are not necessarily provided with an IC. The IC may be mounted on the FPC by a COF method or the like.

FIG. 33A illustrates an example of cross sections of part of a region including the FPC 172, part of the circuit 164, part of the display portion 167, and part of the connection portion 140 of the display apparatus 100G.

The display apparatus 100G illustrated in FIG. 33A includes a transistor 201, a transistor 205, the light-emitting device 130b, the light-emitting device 130a, the dummy light-emitting device 58c, and the like between the substrate 151 and the substrate 152. The light-emitting device 130a is alight-emitting device that emits red light, for example. The light-emitting device 130b is a light-emitting device that emits green light, for example. Although not illustrated, the display apparatus 100G includes the light-emitting device 130c, the dummy light-emitting device 58a, the dummy light-emitting device 58b, and the like between the substrate 151 and the substrate 152. The light-emitting device 130c is a light-emitting device that emits blue light, for example.

The structure of each of the light-emitting device 130a and the light-emitting device 130b is similar to the stacked-layer structure illustrated in FIG. 6C except for the structure of the pixel electrode. The structure of the dummy light-emitting device 58c is similar to the stacked-layer structure illustrated in FIG. 6D except for the structure of the pixel electrode. Embodiment 1 can be referred to for the details of the light-emitting devices. The light-emitting device 130a, the light-emitting device 130b, and the dummy light-emitting device 58c are provided over an insulating layer 214.

The insulating layer 214 is provided with the grooves 175. The groove 175 is provided between two adjacent light-emitting devices. Another groove 175 is provided between two adjacent dummy light-emitting devices. Another groove 175 is provided between the light-emitting device and the dummy light-emitting device adjacent to each other.

The groove 175 provided between the two adjacent light-emitting devices includes regions overlapping with the pixel electrodes of these light-emitting devices. Moreover, the groove 175 includes a region that does not overlap with the pixel electrodes of the two adjacent light-emitting devices.

The groove 175 provided between the two adjacent dummy light-emitting devices includes regions overlapping with the pixel electrodes of these dummy light-emitting devices. Moreover, the groove 175 includes a region that does not overlap with the pixel electrodes of the two adjacent dummy light-emitting devices.

The groove 175 provided between the light-emitting device and the dummy light-emitting device adjacent to each other includes regions overlapping with the pixel electrodes of the light-emitting device and the dummy light-emitting device adjacent to each other. Moreover, the groove 175 includes a region that does not overlap with the pixel electrodes of the light-emitting device and the dummy light-emitting device.

Since the layer 113a, the layer 113b, and the layer 113c are separated from each other in the display apparatus 100G, crosstalk generated between adjacent subpixels can be inhibited even when the display apparatus 100G has high resolution. Accordingly, the display apparatus can have high resolution and high display quality.

The light-emitting device 130a includes a conductive layer 112a, a conductive layer 126a over the conductive layer 112a, and a conductive layer 129a over the conductive layer 126a. All of the conductive layers 112a, 126a, and 129a can be referred to as a pixel electrode, or one or two of them can be referred to as a pixel electrode.

The light-emitting device 130b includes a conductive layer 112b, a conductive layer 126b over the conductive layer 112b, and a conductive layer 129b over the conductive layer 126b.

The dummy light-emitting device 58c includes a conductive layer 112g, a conductive layer 126g over the conductive layer 112g, and a conductive layer 129g over the conductive layer 126g.

The conductive layer 112a is connected to a conductive layer 222b of the transistor 205 through an opening provided in the insulating layer 214. An end portion of the conductive layer 126a is positioned outward from an end portion of the conductive layer 112a. The end portion of the conductive layer 126a and an end portion of the conductive layer 129a are aligned or substantially aligned with each other. For example, a conductive layer functioning as a reflective electrode can be used as the conductive layer 112a and the conductive layer 126a, and a conductive layer functioning as a transparent electrode can be used as the conductive layer 129a.

The conductive layer 112b is connected to the conductive layer 222b of the transistor 205 through an opening provided in the insulating layer 214. An end portion of the conductive layer 126b is positioned outward from an end portion of the conductive layer 112b. The end portion of the conductive layer 126b and an end portion of the conductive layer 129b are aligned or substantially aligned with each other. For example, a conductive layer functioning as a reflective electrode can be used as the conductive layer 112b and the conductive layer 126b, and a conductive layer functioning as a transparent electrode can be used as the conductive layer 129b.

The conductive layer 112g is connected to the conductive layer 222b of the transistor 205 through an opening provided in the insulating layer 214. An end portion of the conductive layer 126g is positioned outward from an end portion of the conductive layer 112g. The end portion of the conductive layer 126g and an end portion of the conductive layer 129g are aligned or substantially aligned with each other. For example, a conductive layer functioning as a reflective electrode can be used as the conductive layer 112g and the conductive layer 126g, and a conductive layer functioning as a transparent electrode can be used as the conductive layer 129g.

The conductive layers 112a, 112b, and 112g each include a depressed portion covering the opening provided in the insulating layer 214. A layer 128 is embedded in each of the depressed portions.

The layer 128 has a planarization function for the depressed portions of the conductive layers 112a, 112b, and 112g. The conductive layer 126a, the conductive layer 126b, and the conductive layer 126g electrically connected to the conductive layer 112a, the conductive layer 112b, and the conductive layer 112g, respectively, are provided over the conductive layers 112a, 112b, and 112g and the layer 128. Thus, regions overlapping with the depressed portions of the conductive layers 112a, 112b, and 112g can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

As the layer 128, an insulating layer containing an organic material can be suitably used. For example, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used for the layer 128. A photosensitive resin can also be used for the layer 128. As the photosensitive resin, a positive material or a negative material can be used.

When a photosensitive resin is used, the layer 128 can be formed through only light-exposure and development steps, reducing the influence of dry etching, wet etching, or the like on the surfaces of the conductive layers 112a, 112b, and 112g. When the layer 128 is formed using a negative photosensitive resin, the layer 128 can sometimes be formed using the same photomask (light-exposure mask) as the photomask used for forming the opening in the insulating layer 214.

The protective layer 131 is provided over the light-emitting device 130a, the light-emitting device 130b, and the dummy light-emitting device 58c. The protective layer 131 covering the light-emitting devices can inhibit an impurity such as water from entering the light-emitting devices, and increase the reliability of the light-emitting devices.

The protective layer 131 and the substrate 152 are bonded to each other with an adhesive layer 142. A solid sealing structure, a hollow sealing structure, or the like can be employed to seal the light-emitting devices. In FIG. 33A, a solid sealing structure is employed in which a space between the substrate 152 and the substrate 151 is filled with the adhesive layer 142. Alternatively, a hollow sealing structure in which the space is filled with an inert gas (e.g., nitrogen or argon) may be employed. Here, the adhesive layer 142 may be provided not to overlap with the light-emitting devices. The space may be filled with a resin different from that of the frame-like adhesive layer 142.

The conductive layer 123 is provided over the insulating layer 214 in the connection portion 140. An example is described in which the conductive layer 123 has a stacked-layer structure of a conductive film obtained by processing the same conductive film as the conductive layers 112a, 112b, and 112g; a conductive film obtained by processing the same conductive film as the conductive layers 126a, 126b, and 126g; and a conductive film obtained by processing the same conductive film as the conductive layers 129a, 129b, and 129g. An end portion of the conductive layer 123 is covered with the insulating layer 118a and the insulating layer 127. The common layer 114 is provided over the conductive layer 123, and the common electrode 115 is provided over the common layer 114. The conductive layer 123 and the common electrode 115 are electrically connected to each other through the common layer 114. Note that the common layer 114 is not necessarily formed in the connection portion 140. In this case, the conductive layer 123 and the common electrode 115 are in direct contact with each other to be electrically connected to each other.

The display apparatus 100G has a top-emission structure. Light emitted by the light-emitting device is emitted toward the substrate 152. For the substrate 152, a material having a high visible-light-transmitting property is preferably used. The pixel electrode contains a material that reflects visible light, and the counter electrode (the common electrode 115) contains a material that transmits visible light.

A stacked-layer structure including the substrate 151 and the components thereover up to the insulating layer 214 corresponds to the stacked-layer structure of the layer 101 and the insulating layer 105 in Embodiment 1, for example.

The transistor 201 and the transistor 205 are formed over the substrate 151. These transistors can be fabricated using the same material in the same process.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material that does not easily allow diffusion of impurities such as water and hydrogen is preferably used for at least one of the insulating layers that cover the transistors. This is because such an insulating layer can function as a barrier layer. Such a structure can effectively inhibit diffusion of impurities into the transistors from the outside and can increase the reliability of the display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, an aluminum nitride film, or the like can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably has a function of an etching protective layer. Accordingly, a depressed portion can be prevented from being formed in the insulating layer 214 at the time of processing the conductive layer 112a, the conductive layer 126a, the conductive layer 129a, or the like. Alternatively, a depressed portion may be formed in the insulating layer 214 at the time of processing the conductive layer 112a, the conductive layer 126a, the conductive layer 129a, or the like.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, an inverted staggered transistor, or the like can be used. A top-gate transistor structure or a bottom-gate transistor structure may be employed. Alternatively, gates may be provided above and below the semiconductor layer where a channel is formed.

The transistor 201 and the transistor 205 employ a structure where the semiconductor layer where a channel is formed is provided between two gates. The two gates may be connected to each other and supplied with the same signal to drive the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of transistor characteristics can be inhibited.

The semiconductor layer of the transistor preferably includes a metal oxide (also referred to as an oxide semiconductor). That is, a transistor containing a metal oxide in its channel formation region (hereinafter an OS transistor) is preferably used for the display apparatus of this embodiment.

Examples of the oxide semiconductor having crystallinity include a CAAC (c-axis aligned crystalline)-OS and an nc (nanocrystalline)-OS.

Alternatively, a transistor using silicon in a channel formation region (a Si transistor) may be used. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and excellent frequency characteristics.

With the use of Si transistors such as LTPS transistors, a circuit required to be driven at a high frequency (e.g., a source driver circuit) can be formed on the same substrate as the display portion. This allows simplification of an external circuit mounted on the display apparatus and a reduction in component cost and mounting cost.

An OS transistor has much higher field-effect mobility than a transistor using amorphous silicon. In addition, the OS transistor has an extremely low leakage current between a source and a drain in an off state (also referred to as off-state current), and electric charge accumulated in a capacitor that is connected in series to the transistor can be retained for a long period. Furthermore, the power consumption of the display apparatus can be reduced with the use of the OS transistor.

The off-state current value per micrometer of channel width of the OS transistor at room temperature can be less than or equal to 1 aA (1×10⁻¹⁸ A), less than or equal to 1 zA (1×10⁻²¹ A), or less than or equal to 1 yA (1×10⁻²⁴ A). Note that the off-state current value per micrometer of channel width of a Si transistor at room temperature is greater than or equal to 1 fA (1×10⁻¹⁵ A) and less than or equal to 1 pA (1×10⁻¹² A). In other words, the off-state current of the OS transistor is lower than that of the Si transistor by approximately ten orders of magnitude.

To increase the emission luminance of the light-emitting device included in a pixel circuit, it is necessary to increase the amount of current flowing through the light-emitting device. For that purpose, the source-drain voltage of the driving transistor included in the pixel circuit needs to be increased. Since an OS transistor has a higher withstand voltage between the source and the drain than a Si transistor, a high voltage can be applied between the source and the drain of the OS transistor. Thus, with use of the OS transistor as the driving transistor included in the pixel circuit, the amount of current flowing through the light-emitting device can be increased, resulting in an increase in emission luminance of the light-emitting device.

When a transistor operates in a saturation region, a change in source-drain current relative to a change in gate-source voltage can be smaller in an OS transistor than in a Si transistor. Accordingly, when the OS transistor is used as the driving transistor included in the pixel circuit, current flowing between the source and the drain can be set minutely by a change in gate-source voltage; hence, the amount of current flowing through the light-emitting device can be controlled. Thus, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made flow through an OS transistor than through a Si transistor. Thus, by using the OS transistor as the driving transistor, a stable current can be fed through the light-emitting device even when the current-voltage characteristics of the EL device vary, for example. In other words, when the OS transistor operates in the saturation region, the source-drain current hardly changes with an increase in the source-drain voltage; hence, the emission luminance of the light-emitting device can be stable.

As described above, by using an OS transistor as the driving transistor included in the pixel circuit, it is possible to achieve “inhibition of black-level degradation”, “increase in emission luminance”, “increase in the number of gray levels”, “inhibition of variation in light-emitting devices”, and the like.

The semiconductor layer preferably contains indium, M(M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO).

In the case where the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

In the In-M-Zn oxide, the atomic proportion of In may be less than the atomic proportion of M. For example, In:M:Zn=1:3:2 or a composition in the neighborhood thereof or In:M:Zn=1:3:4 or a composition in the neighborhood thereof may be employed.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The transistors included in the circuit 164 and the transistors included in the display portion 167 may have the same structure or different structures. One structure or two or more types of structures may be employed for a plurality of transistors included in the circuit 164. Similarly, one structure or two or more types of structures may be employed for a plurality of transistors included in the display portion 167.

All of the transistors included in the display portion 167 may be OS transistors or all of the transistors included in the display portion 167 may be Si transistors; alternatively, some of the transistors included in the display portion 167 may be OS transistors and the others may be Si transistors.

For example, when both an LTPS transistor and an OS transistor are used in the display portion 167, the display apparatus can have low power consumption and high driving capability. A structure where an LTPS transistor and an OS transistor are used in combination is referred to as LTPO in some cases. As a more favorable example, it is preferable that an OS transistor be used as a transistor functioning as a switch for controlling electrical continuity between wirings and an LTPS transistor be used as a transistor for controlling current.

For example, one of the transistors included in the display portion 167 functions as a transistor for controlling current flowing through the light-emitting device and can be referred to as a driving transistor. One of a source and a drain of the driving transistor is electrically connected to the pixel electrode of the light-emitting device. An LTPS transistor is preferably used as the driving transistor. In that case, current flowing through the light-emitting device in the pixel circuit can be increased.

Another transistor included in the display portion 167 functions as a switch for controlling selection and non-selection of a pixel and can be referred to as a selection transistor. A gate of the selection transistor is electrically connected to a gate line, and one of a source and a drain thereof is electrically connected to a source line (signal line). An OS transistor is preferably used as the selection transistor. In that case, the gray level of the pixel can be maintained even with an extremely low frame frequency (e.g., 1 fps or less); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having an MML (metal maskless) structure. With this structure, the leakage current that might flow through the transistor and the leakage current that might flow between adjacent light-emitting devices (also referred to as lateral leakage current, side leakage current, or the like) can be extremely low. With the structure, a viewer can notice any one or more of the image crispness, the image sharpness, a high chroma, and a high contrast ratio in an image displayed on the display apparatus. When the leakage current that might flow through the transistor and the lateral leakage between light-emitting devices are extremely low, display with little light leakage or the like that might occur in black display can be achieved.

FIG. 33D illustrates a structure in which in a peripheral region of the pixel portion, e.g., in the circuit 164, an opening portion is provided in the insulating layer 214, and a sealing portion 186 where the insulating layer 215 and the protective layer 131 are in contact with each other is provided in the opening portion. When an inorganic insulating film is used for each of the insulating layer 215 and the protective layer 131, the pixel portion can be sealed by the inorganic insulating films, enhancing the effect of inhibiting entry of impurities (e.g., moisture and oxygen) into the light-emitting device.

FIG. 33B and FIG. 33C illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, an insulating layer 218 covering the transistor may be provided.

FIG. 33B illustrates an example of the transistor 209 in which the insulating layer 225 covers the top surface and the side surface of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 33C, the insulating layer 225 overlaps with the channel formation region 231i of the semiconductor layer 231 and does not overlap with the low-resistance regions 231n. The structure illustrated in FIG. 33C can be formed by processing the insulating layer 225 using the conductive layer 223 as a mask, for example. In FIG. 33C, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 204 is provided in a region of the substrate 151 where the substrate 152 does not overlap. In the connection portion 204, the wiring 165 is electrically connected to the FPC 172 through a conductive layer 166 and a connection layer 242. An example is described in which the conductive layer 166 has a stacked-layer structure of a conductive film obtained by processing the same conductive film as the conductive layers 112a, 112b, and 112g, a conductive film obtained by processing the same conductive film as the conductive layers 126a, 126b, and 126g, and a conductive film obtained by processing the same conductive film as the conductive layers 129a, 129b, and 129g. The conductive layer 166 is exposed on the top surface of the connection portion 204. Thus, the connection portion 204 and the FPC 172 can be electrically connected to each other through the connection layer 242.

A light-blocking layer 117 is preferably provided on the surface of the substrate 152 that faces the substrate 151. The light-blocking layer 117 can be provided between adjacent light-emitting devices, in the connection portion 140, and in the circuit 164, for example. A variety of optical members can be provided on the outer surface of the substrate 152. FIG. 33 illustrates an example of a structure in which the dummy light-emitting device 58c is covered with the light-blocking layer. Note that in the case where the dummy light-emitting device 58c does not have a function of emitting light, for example, the dummy light-emitting device 58c is not necessarily covered with the light-blocking layer.

The material that can be used for the substrate 120 can be used for each of the substrate 151 and the substrate 152.

The material that can be used for the resin layer 122 can be used for the adhesive layer 142.

As the connection layer 242, an anisotropic conductive film (ACF), an anisotropic conductive paste (ACP), or the like can be used.

This embodiment can be combined with the other embodiments as appropriate.

### Embodiment 4

In this embodiment, a structure example of a transistor that can be used in the display apparatus of one embodiment of the present invention will be described. Specifically, the case of using a transistor containing silicon in a semiconductor where a channel is formed will be described.

One embodiment of the present invention is a display apparatus including a light-emitting device and a pixel circuit. The display apparatus can perform full-color display by including three types of light-emitting devices that emit red (R) light, green (G) light, and blue (B) light, for example.

Transistors containing silicon in their semiconductor layers where channels are formed are preferably used as all transistors included in the pixel circuit for driving the light-emitting device. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) is preferably used. The LTPS transistor has high field-effect mobility and excellent frequency characteristics.

With the use of transistors containing silicon, such as LTPS transistors, a circuit required to be driven at a high frequency (e.g., a source driver circuit) can be formed on the same substrate as the display portion. This allows simplification of an external circuit mounted on the display apparatus and a reduction in component cost and mounting cost.

It is preferable to use transistors containing a metal oxide (hereinafter also referred to as an oxide semiconductor) in their semiconductors where channels are formed (such transistors are hereinafter also referred to as OS transistors) as at least one of the transistors included in the pixel circuit. An OS transistor has much higher field-effect mobility than a transistor using amorphous silicon. In addition, an OS transistor has an extremely low leakage current between a source and a drain in an off state (also referred to as off-state current), and electric charge accumulated in a capacitor that is connected in series to the transistor can be retained for a long period. Furthermore, the power consumption of the display apparatus can be reduced with the use of an OS transistor.

When an LTPS transistor is used as one or more of the transistors included in the pixel circuit and an OS transistor is used as the rest, a display apparatus with low power consumption and high driving capability can be achieved. In a more favorable example, it is preferable that an OS transistor be used as a transistor functioning as a switch for controlling electrical continuity between wirings and an LTPS transistor be used as a transistor for controlling current.

For example, one of the transistors included in the pixel circuit functions as a transistor for controlling current flowing through the light-emitting device and can be referred to as a driving transistor. One of a source and a drain of the driving transistor is electrically connected to the pixel electrode of the light-emitting device. An LTPS transistor is preferably used as the driving transistor. Thus, current flowing through the light-emitting device in the pixel circuit can be increased.

Another transistor included in the pixel circuit functions as a switch for controlling selection and non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

More specific structure examples will be described below with reference to drawings.

### [Structure Example of Display Apparatus]

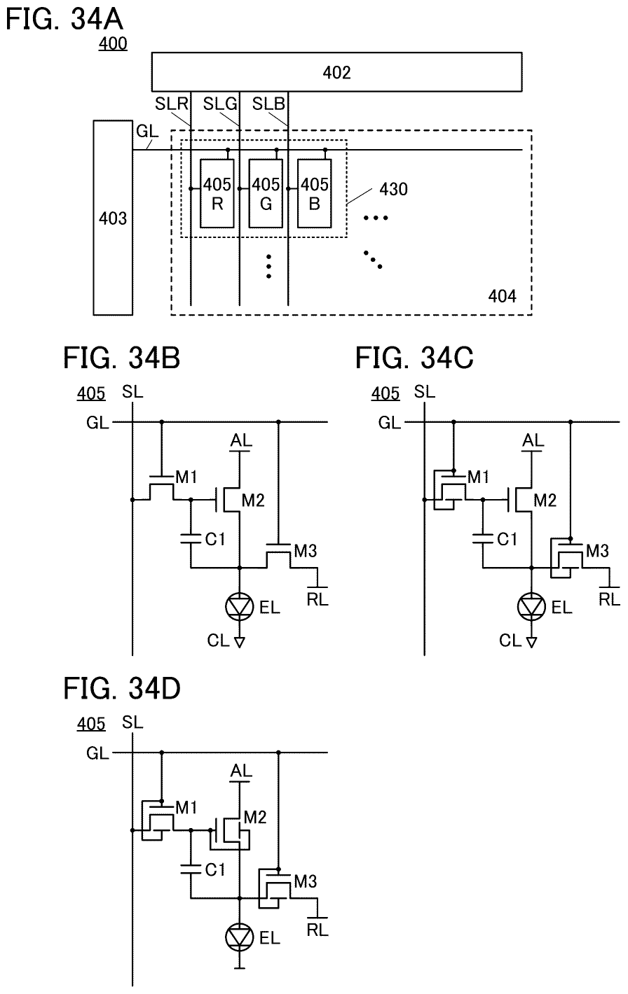

FIG. 34A is a block diagram of a display apparatus 400. The display apparatus 400 includes a display portion 404, a driver circuit portion 402, a driver circuit portion 403, and the like.

The display portion 404 includes a plurality of pixels 430 arranged in a matrix. The pixels 430 each include a subpixel 405R, a subpixel 405G, and a subpixel 405B. The subpixel 405R, the subpixel 405G, and the subpixel 405B each include a light-emitting device functioning as a display device.

The pixel 430 is electrically connected to a wiring GL, a wiring SLR, a wiring SLG, and a wiring SLB. The wiring SLR, the wiring SLG, and the wiring SLB are electrically connected to the driver circuit portion 402. The wiring GL is electrically connected to the driver circuit portion 403. The driver circuit portion 402 functions as a source line driver circuit (also referred to as a source driver), and the driver circuit portion 403 functions as a gate line driver circuit (also referred to as a gate driver). The wiring GL functions as a gate line, and the wiring SLR, the wiring SLG, and the wiring SLB each function as a source line.

The subpixel 405R includes a light-emitting device that emits red light. The subpixel 405G includes a light-emitting device that emits green light. The subpixel 405B includes a light-emitting device that emits blue light. Thus, the display apparatus 400 can perform full-color display. Note that the pixel 430 may include a subpixel that includes a light-emitting device emitting light of another color. For example, the pixel 430 may include, in addition to the three subpixels, a subpixel that includes a light-emitting device emitting white light, a subpixel that includes a light-emitting device emitting yellow light, or the like. Note that the pixel 430 may include a subpixel including a light-emitting device emitting light of another color. For example, the pixel 430 may include, in addition to the three subpixels, a subpixel including a light-emitting device emitting white light, a subpixel including a light-emitting device emitting yellow light, or the like.

The wiring GL is electrically connected to the subpixel 405R, the subpixel 405G, and the subpixel 405B arranged in a row direction (an extending direction of the wiring GL). The wiring SLR, the wiring SLG, and the wiring SLB are electrically connected to the subpixels 405R, the subpixels 405G, and the subpixels 405B (not illustrated) arranged in a column direction (an extending direction of the wiring SLR and the like), respectively.

### [Structure Example of Pixel Circuit]

FIG. 34B illustrates an example of a circuit diagram of a pixel 405 that can be used as the subpixel 405R, the subpixel 405G, and the subpixel 405B. The pixel 405 includes a transistor M1, a transistor M2, a transistor M3, a capacitor C1, and a light-emitting device EL. The wiring GL and a wiring SL are electrically connected to the pixel 405. The wiring SL corresponds to any of the wiring SLR, the wiring SLG, and the wiring SLB illustrated in FIG. 34A.

A gate of the transistor M1 is electrically connected to the wiring GL, one of a source and a drain of the transistor M1 is electrically connected to the wiring SL, and the other thereof is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting device EL, the other electrode of the capacitor C1, and one of a source and a drain of the transistor M3. A gate of the transistor M3 is electrically connected to the wiring GL, and the other of the source and the drain of the transistor M3 is electrically connected to a wiring RL. The other electrode of the light-emitting device EL is electrically connected to a wiring CL.

A data potential D is supplied to the wiring SL. A selection signal is supplied to the wiring GL. The selection signal includes a potential for bringing a transistor into a conducting state and a potential for bringing a transistor into a non-conducting state.

A reset potential is supplied to the wiring RL. An anode potential is supplied to the wiring AL. A cathode potential is supplied to the wiring CL. In the pixel 405, the anode potential is a potential higher than the cathode potential. The reset potential supplied to the wiring RL can be set such that the potential difference between the reset potential and the cathode potential is lower than the threshold voltage of the light-emitting device EL. The reset potential can be a potential higher than the cathode potential, a potential equal to the cathode potential, or a potential lower than the cathode potential.

The transistor M1 and the transistor M3 each function as a switch. The transistor M2 functions as a transistor for controlling current flowing through the light-emitting device EL. For example, it can be said that the transistor M1 functions as a selection transistor and the transistor M2 functions as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, OS transistors may be used as all of the transistor M1 to the transistor M3. In this case, an LTPS transistor can be used as at least one of a plurality of transistors included in the driver circuit portion 402 and a plurality of transistors included in the driver circuit portion 403, and OS transistors can be used as the other transistors. For example, OS transistors can be used as the transistors provided in the display portion 404, and LTPS transistors can be used as the transistors provided in the driver circuit portion 402 and the driver circuit portion 403.

As the OS transistor, a transistor that includes an oxide semiconductor in its semiconductor layer where a channel is formed can be used. The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin. It is particularly preferable to use an oxide containing indium, gallium, and zinc (also referred to as IGZO) for the semiconductor layer of the OS transistor. Alternatively, it is preferable to use an oxide containing indium, tin, and zinc. Further alternatively, it is preferable to use an oxide containing indium, gallium, tin, and zinc.

A transistor that includes an oxide semiconductor having a wider band gap and lower carrier density than silicon can achieve an extremely low off-state current. Thus, such a low off-state current enables long-term retention of electric charge accumulated in a capacitor that is connected to the transistor in series. Therefore, it is particularly preferable to use a transistor containing an oxide semiconductor as the transistor M1 and the transistor M3 each of which is connected to the capacitor C1 in series. The use of the transistor containing an oxide semiconductor as each of the transistor M1 and the transistor M3 can prevent leakage of electric charge retained in the capacitor C1 through the transistor M1 or the transistor M3. Furthermore, since electric charge retained in the capacitor C1 can be retained for a long time, a still image can be displayed for a long time without rewriting data in the pixel 405.

Note that although the transistor is illustrated as an n-channel transistor in FIG. 34B, a p-channel transistor can also be used.

The transistors included in the pixel 405 are preferably formed to be arranged over the same substrate.

Transistors each including a pair of gates overlapping with each other with a semiconductor layer therebetween can be used as the transistors included in the pixel 405.

In the transistor that includes a pair of gates, the same potential is supplied to the pair of gates electrically connected to each other, which brings advantage that the transistor can have a higher on-state current and improved saturation characteristics. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel 405 illustrated in FIG. 34C is an example where a transistor including a pair of gates is used as each of the transistor M1 and the transistor M3. In each of the transistor M1 and the transistor M3, the pair of gates are electrically connected to each other. Such a structure can shorten the period in which data is written to the pixel 405.

The pixel 405 illustrated in FIG. 34D is an example where a transistor including a pair of gates is used as the transistor M2 in addition to the transistor M1 and the transistor M3. A pair of gates of the transistor M2 are electrically connected to each other. When such a transistor is used as the transistor M2, the saturation characteristics are improved, whereby emission luminance of the light-emitting device EL can be controlled easily and the display quality can be increased.

### [Structure Example of Transistor]

Cross-sectional structure examples of a transistor that can be used in the above display apparatus will be described below.

### [Structure Example 1]

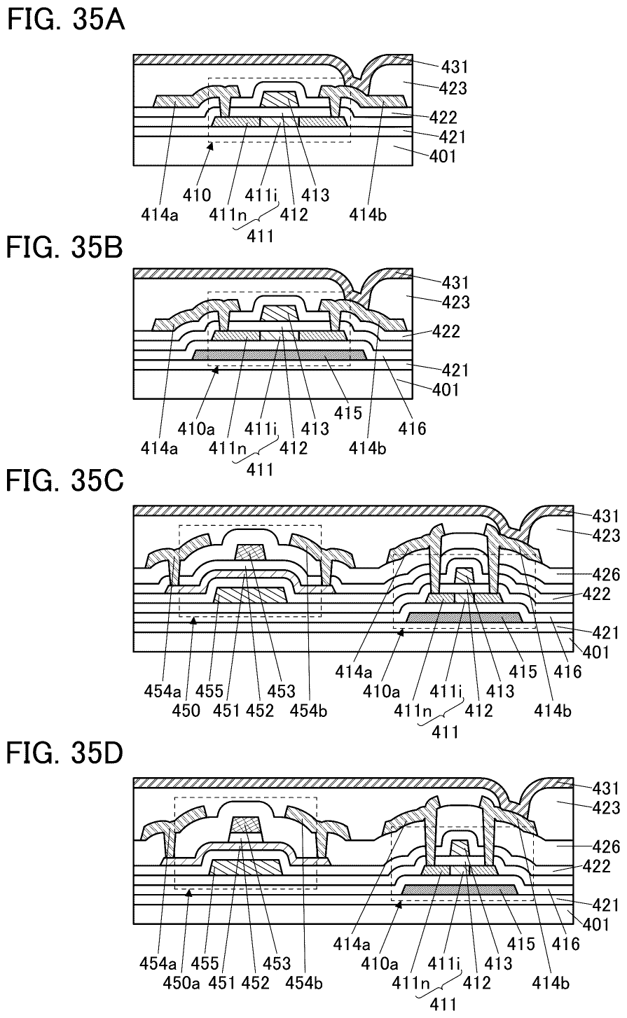

FIG. 35A is a cross-sectional view including a transistor 410.

The transistor 410 is provided over a substrate 401 and contains polycrystalline silicon in its semiconductor layer. For example, the transistor 410 corresponds to the transistor M2 in the pixel 405. In other words, FIG. 35A illustrates an example in which one of a source and a drain of the transistor 410 is electrically connected to a conductive layer 431 of the light-emitting device.

The transistor 410 includes a semiconductor layer 411, an insulating layer 412, a conductive layer 413, and the like. The semiconductor layer 411 includes a channel formation region 411i and low-resistance regions 411n. The semiconductor layer 411 contains silicon. The semiconductor layer 411 preferably contains polycrystalline silicon. Part of the insulating layer 412 functions as a gate insulating layer. Part of the conductive layer 413 functions as a gate electrode.

Note that the semiconductor layer 411 can contain a metal oxide exhibiting semiconductor characteristics (also referred to as an oxide semiconductor). In this case, the transistor 410 can be referred to as an OS transistor.

The low-resistance region 411n is a region containing an impurity element. For example, in the case where the transistor 410 is an n-channel transistor, phosphorus, arsenic, or the like is added to the low-resistance region 411n. Meanwhile, in the case where the transistor 410 is a p-channel transistor, boron, aluminum, or the like is added to the low-resistance region 411n. In addition, in order to control the threshold voltage of the transistor 410, the above-described impurity may be added to the channel formation region 411i.

An insulating layer 421 is provided over the substrate 401. The semiconductor layer 411 is provided over the insulating layer 421. The insulating layer 412 is provided to cover the semiconductor layer 411 and the insulating layer 421. The conductive layer 413 is provided at a position that is over the insulating layer 412 and overlaps with the semiconductor layer 411.

An insulating layer 422 is provided to cover the conductive layer 413 and the insulating layer 412. A conductive layer 414a and a conductive layer 414b are provided over the insulating layer 422. The conductive layer 414a and the conductive layer 414b are electrically connected to the low-resistance regions 411n in opening portions provided in the insulating layer 422 and the insulating layer 412. Part of the conductive layer 414a functions as one of a source electrode and a drain electrode, and part of the conductive layer 414b functions as the other of the source electrode and the drain electrode. An insulating layer 423 is provided to cover the conductive layer 414a, the conductive layer 414b, and the insulating layer 422.

The conductive layer 431 functioning as a pixel electrode is provided over the insulating layer 423. The conductive layer 431 is provided over the insulating layer 423 and is electrically connected to the conductive layer 414b through an opening provided in the insulating layer 423. Although not illustrated here, an EL layer and a common electrode can be stacked over the conductive layer 431.

### [Structure Example 2]

FIG. 35B illustrates a transistor 410a including a pair of gate electrodes. The transistor 410a illustrated in FIG. 35B is different from that in FIG. 35A mainly in including a conductive layer 415 and an insulating layer 416.

The conductive layer 415 is provided over the insulating layer 421. The insulating layer 416 is provided to cover the conductive layer 415 and the insulating layer 421. The semiconductor layer 411 is provided such that at least the channel formation region 411i overlaps with the conductive layer 415 with the insulating layer 416 therebetween.

In the transistor 410a illustrated in FIG. 35B, part of the conductive layer 413 functions as a first gate electrode, and part of the conductive layer 415 functions as a second gate electrode. At this time, part of the insulating layer 412 functions as a first gate insulating layer, and part of the insulating layer 416 functions as a second gate insulating layer.

Here, to electrically connect the first gate electrode to the second gate electrode, the conductive layer 413 is electrically connected to the conductive layer 415 through an opening portion provided in the insulating layer 412 and the insulating layer 416 in a region not illustrated. To electrically connect the second gate electrode to a source or a drain, the conductive layer 415 is electrically connected to the conductive layer 414a or the conductive layer 414b through an opening portion provided in the insulating layer 422, the insulating layer 412, and the insulating layer 416 in a region not illustrated.

In the case where LTPS transistors are used as all of the transistors included in the pixel 405, the transistor 410 exemplified in FIG. 35A or the transistor 410a exemplified in FIG. 35B can be used. In this case, the transistors 410a may be used as all of the transistors included in the pixels 405, the transistors 410 may be used as all of the transistors, or the transistors 410a and the transistors 410 may be used in combination.

### [Structure Example 3]

Described below is an example of a structure that includes both a transistor containing silicon in its semiconductor layer and a transistor containing a metal oxide in its semiconductor layer.

FIG. 35C is a schematic cross-sectional view including the transistor 410a and a transistor 450.

Structure example 1 described above can be referred to for the transistor 410a. Although an example using the transistor 410a is illustrated here, a structure including the transistor 410 and the transistor 450 or a structure including all the transistor 410, the transistor 410a, and the transistor 450 may alternatively be employed.

The transistor 450 is a transistor containing a metal oxide in its semiconductor layer. The structure in FIG. 35C illustrates an example in which the transistor 450 corresponds to the transistor M1 and the transistor 410a corresponds to the transistor M2 in the pixel 405. That is, FIG. 35C illustrates an example in which one of a source and a drain of the transistor 410a is electrically connected to the conductive layer 431.

Moreover, FIG. 35C illustrates an example in which the transistor 450 includes a pair of gates.

The transistor 450 includes a conductive layer 455, the insulating layer 422, a semiconductor layer 451, an insulating layer 452, a conductive layer 453, and the like. Part of the conductive layer 453 functions as a first gate of the transistor 450, and part of the conductive layer 455 functions as a second gate of the transistor 450. In this case, part of the insulating layer 452 functions as a first gate insulating layer of the transistor 450, and part of the insulating layer 422 functions as a second gate insulating layer of the transistor 450.

The conductive layer 455 is provided over the insulating layer 412. The insulating layer 422 is provided to cover the conductive layer 455. The semiconductor layer 451 is provided over the insulating layer 422. The insulating layer 452 is provided to cover the semiconductor layer 451 and the insulating layer 422. The conductive layer 453 is provided over the insulating layer 452 and includes a region overlapping with the semiconductor layer 451 and the conductive layer 455.

An insulating layer 426 is provided to cover the insulating layer 452 and the conductive layer 453. A conductive layer 454a and a conductive layer 454b are provided over the insulating layer 426. The conductive layer 454a and the conductive layer 454b are electrically connected to the semiconductor layer 451 in openings provided in the insulating layer 426 and the insulating layer 452. Part of the conductive layer 454a functions as one of a source electrode and a drain electrode, and part of the conductive layer 454b functions as the other of the source electrode and the drain electrode. The insulating layer 423 is provided to cover the conductive layer 454a, the conductive layer 454b, and the insulating layer 426.

Here, the conductive layer 414a and the conductive layer 414b electrically connected to the transistor 410a are preferably formed by processing the same conductive film as the conductive layer 454a and the conductive layer 454b. In FIG. 35C, the conductive layer 414a, the conductive layer 414b, the conductive layer 454a, and the conductive layer 454b are formed on the same plane (i.e., in contact with the top surface of the insulating layer 426) and contain the same metal element. In this case, the conductive layer 414a and the conductive layer 414b are electrically connected to the low-resistance regions 411n through openings provided in the insulating layer 426, the insulating layer 452, the insulating layer 422, and the insulating layer 412. This can simplify the fabricating process and is thus preferable.

Moreover, the conductive layer 413 functioning as the first gate electrode of the transistor 410a and the conductive layer 455 functioning as the second gate electrode of the transistor 450 are preferably formed by processing the same conductive film. FIG. 35C illustrates a structure where the conductive layer 413 and the conductive layer 455 are formed on the same plane (i.e., in contact with the top surface of the insulating layer 412) and contain the same metal element. This can simplify the fabricating process and is thus preferable.

In the structure in FIG. 35C, the insulating layer 452 functioning as the first gate insulating layer of the transistor 450 covers an end portion of the semiconductor layer 451; however, the insulating layer 452 may be processed to have the same or substantially the same top surface shape as the conductive layer 453 as in the transistor 450a illustrated in FIG. 35D.

Note that in this specification and the like, the expression “top surface shapes are substantially the same” means that at least outlines of stacked layers partly overlap with each other. For example, the case of processing an upper layer and a lower layer with the use of the same mask pattern or mask patterns that are partly the same is included. However, in some cases, the outlines do not completely overlap with each other and the upper layer is located inward from the lower layer or the upper layer is located outward from the lower layer; such cases are also represented by the expression “top surface shapes are substantially the same”.

Although the example in which the transistor 410a corresponds to the transistor M2 and is electrically connected to the pixel electrode is shown here, one embodiment of the present invention is not limited thereto. For example, a structure in which the transistor 450 or the transistor 450a corresponds to the transistor M2 may be employed. In that case, the transistor 410a corresponds to the transistor M1, the transistor M3, or another transistor.

This embodiment can be combined with the other embodiments as appropriate.

### Embodiment 5

In this embodiment, light-emitting devices that can be used for the display apparatus of one embodiment of the present invention will be described.

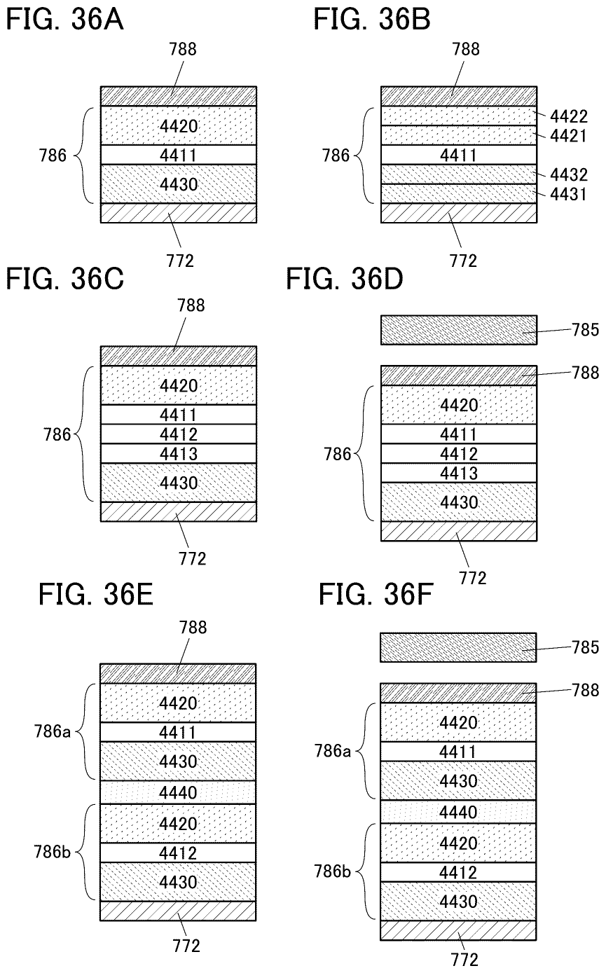

As illustrated in FIG. 36A, the light-emitting device includes an EL layer 786 between a pair of electrodes (a lower electrode 772 and an upper electrode 788). The EL layer 786 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430 provided between a pair of electrodes can function as a single light-emitting unit, and the structure in FIG. 36A is referred to as a single structure in this specification.

FIG. 36B shows a variation example of the EL layer 786 included in the light-emitting device illustrated in FIG. 36A. Specifically, the light-emitting device illustrated in FIG. 36B includes a layer 4431 over the lower electrode 772, a layer 4432 over the layer 4431, the light-emitting layer 4411 over the layer 4432, a layer 4421 over the light-emitting layer 4411, a layer 4422 over the layer 4421, and the upper electrode 788 over the layer 4422. In the case where the lower electrode 772 is an anode and the upper electrode 788 is a cathode, for example, the layer 4431 functions as a hole-injection layer, the layer 4432 functions as a hole-transport layer, the layer 4421 functions as an electron-transport layer, and the layer 4422 functions as an electron-injection layer. Alternatively, in the case where the lower electrode 772 is a cathode and the upper electrode 788 is an anode, the layer 4431 functions as an electron-injection layer, the layer 4432 functions as an electron-transport layer, the layer 4421 functions as a hole-transport layer, and the layer 4422 functions as a hole-injection layer. With such a layered structure, carriers can be efficiently injected to the light-emitting layer 4411, and the efficiency of the recombination of carriers in the light-emitting layer 4411 can be enhanced.

Note that a structure where a plurality of light-emitting layers (light-emitting layers 4411, 4412, and 4413) are provided between the layer 4420 and the layer 4430 as illustrated in FIG. 36C and FIG. 36D is also a variation of the single structure.

A structure where a plurality of light-emitting units (an EL layer 786a and an EL layer 786b) are connected in series with a charge-generation layer 4440 therebetween as illustrated in FIG. 36E and FIG. 36F is referred to as a tandem structure in this specification. Note that the tandem structure may be referred to as a stack structure. Note that the tandem structure enables a light-emitting device capable of emitting light with high luminance.

In FIG. 36C and FIG. 36D, light-emitting materials that emit light of the same color, or moreover, the same light-emitting material may be used for the light-emitting layer 4411, the light-emitting layer 4412, and the light-emitting layer 4413. For example, a light-emitting material that emits blue light may be used for the light-emitting layer 4411, the light-emitting layer 4412, and the light-emitting layer 4413. A color conversion layer may be provided as a layer 785 illustrated in FIG. 36D.

Alternatively, light-emitting materials that emit light of different colors may be used for the light-emitting layer 4411, the light-emitting layer 4412, and the light-emitting layer 4413. White light emission can be obtained when the light-emitting layer 4411, the light-emitting layer 4412, and the light-emitting layer 4413 emit light of complementary colors. A color filter (also referred to as a coloring layer) may be provided as the layer 785 illustrated in FIG. 36D. When white light passes through a color filter, light of a desired color can be obtained.

In FIG. 36E and FIG. 36F, light-emitting materials that emit light of the same color, or moreover, the same light-emitting material may be used for the light-emitting layer 4411 and the light-emitting layer 4412. Alternatively, light-emitting materials that emit light of different colors may be used for the light-emitting layer 4411 and the light-emitting layer 4412. White light emission can be obtained when the light-emitting layer 4411 and the light-emitting layer 4412 emit light of complementary colors. FIG. 36F illustrates an example where the layer 785 is further provided. One or both of a color conversion layer and a color filter (coloring layer) can be used as the layer 785.

In FIG. 36C, FIG. 36D, FIG. 36E, and FIG. 36F, the layer 4420 and the layer 4430 may each have a stacked-layer structure of two or more layers as in FIG. 36B.

A structure where light-emitting devices of different emission colors (e.g., blue (B), green (G), and red (R)) are separately formed is referred to as an SBS (Side By Side) structure in some cases.

The emission color of the light-emitting device can be red, green, blue, cyan, magenta, yellow, white, or the like depending on the material included in the EL layer 786. Furthermore, the color purity can be further increased when the light-emitting device has a microcavity structure.

The light-emitting device that emits white light preferably contains two or more kinds of light-emitting substances in the light-emitting layer. To obtain white light emission, two or more kinds of light-emitting substances are selected such that they emit light of complementary colors. For example, when an emission color of a first light-emitting layer and an emission color of a second light-emitting layer are complementary colors, the light-emitting device can be configured to emit white light as a whole. The same applies to a light-emitting device including three or more light-emitting layers.

The light-emitting layer preferably contains two or more light-emitting substances that emit light of R (red), G (green), B (blue), Y (yellow), O (orange), or the like. Alternatively, the light-emitting layer preferably contains two or more light-emitting substances that emit light containing two or more of spectral components of R, G, and B.

This embodiment can be combined with the other embodiments as appropriate.

### Embodiment 6

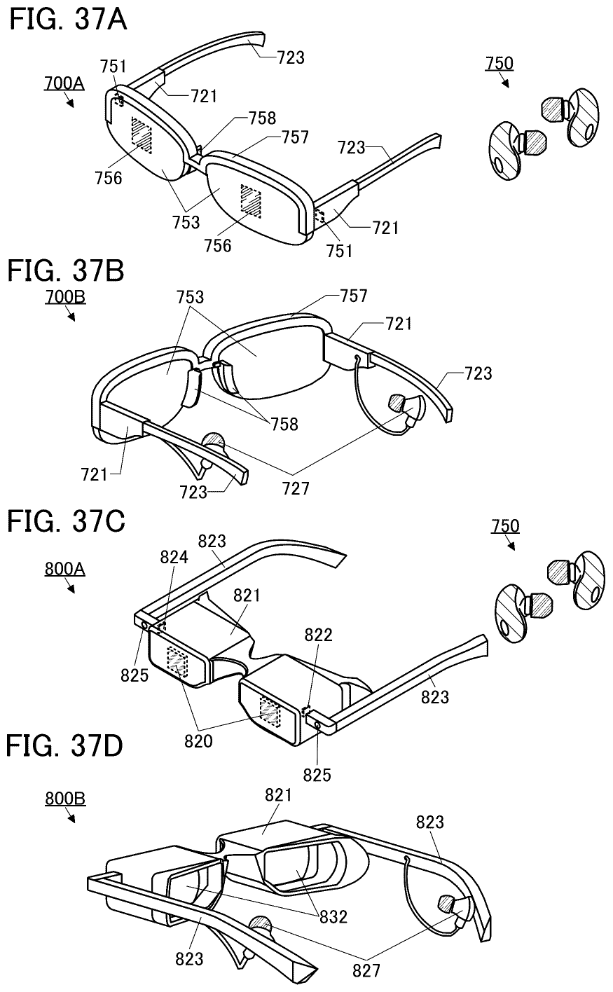

In this embodiment, electronic devices of embodiments of the present invention will be described with reference to FIG. 37 to FIG. 39.

Electronic devices of this embodiment each include the display apparatus of one embodiment of the present invention in a display portion. The display apparatus of one embodiment of the present invention can be easily increased in resolution and definition and can achieve high display quality. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display apparatus of one embodiment of the present invention can have high resolution, and thus can be suitably used for an electronic device having a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4 K (number of pixels: 3840×2160), or 8 k (number of pixels: 7680×4320). In particular, a definition of 4 K, 8 K, or higher is preferable. The pixel density (resolution) of the display apparatus of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With the use of such a display apparatus having one or both of high definition and high resolution, the electronic device can provide higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, or the like, a function of executing a variety of software (programs), a wireless communication function, or a function of reading out a program or data stored in a recording medium.

Examples of a wearable device capable of being worn on a head are described with reference to FIG. 37A to FIG. 37D. These wearable devices have one or both of a function of displaying AR contents and a function of displaying VR contents. Note that the wearable devices may have a function of displaying SR or MR contents, in addition to AR and VR contents. The electronic device having a function of displaying contents of at least one of AR, VR, SR, MR, and the like enables the user to reach a higher level of immersion.

An electronic device 700A illustrated in FIG. 37A and an electronic device 700B illustrated in FIG. 37B each include a pair of display apparatuses 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display apparatuses 751. Thus, the electronic device can perform display with extremely high resolution.

The electronic device 700A and the electronic device 700B can each project images displayed on the display apparatuses 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. When the touch sensor module is provided in each of the two housings 721, the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 37C and an electronic device 800B illustrated in FIG. 37D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used for the display portions 820. Thus, the electronic device can perform display with extremely high resolution. This enables a user to feel high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be mounted on the user's head with the wearing portions 823. FIG. 37C and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter also referred to as a sensing portion) that is capable of measuring a distance from an object may be provided. In other words, the image capturing portion 825 is one embodiment of the sensing portion. As the sensing portion, an image sensor or a distance image sensor such as LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 37A has a function of transmitting information to the earphones 750 with the wireless communication function. As another example, the electronic device 800A illustrated in FIG. 37C has a function of transmitting information to the earphones 750 with the wireless communication function.

The electronic device may include an earphone portion. The electronic device 700B illustrated in FIG. 37B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 37D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

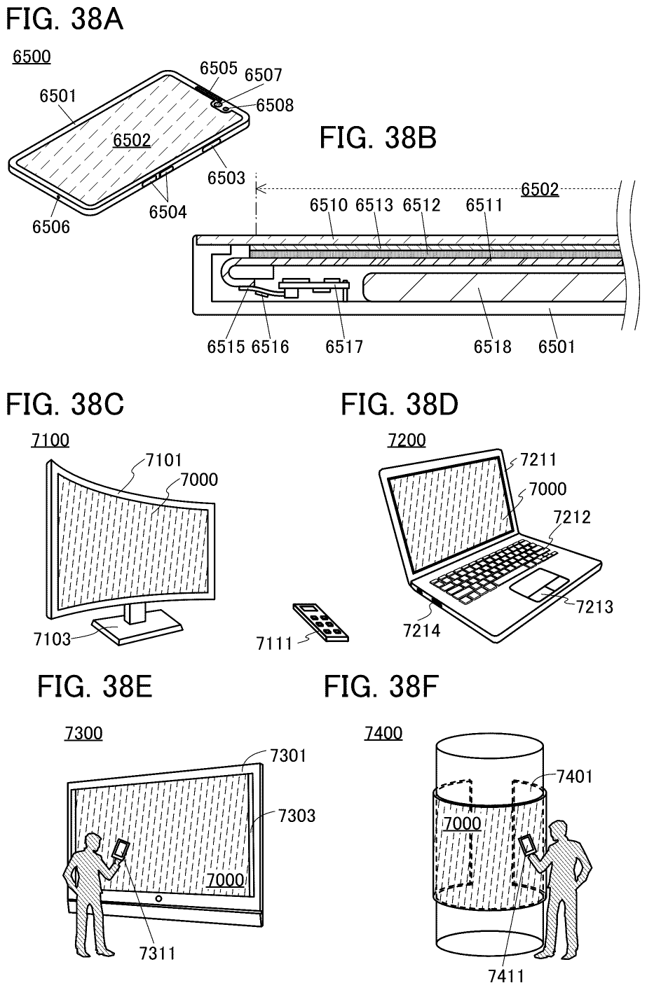

An electronic device 6500 illustrated in FIG. 38A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 38B is a schematic cross-sectional view including an end portion of the housing 6501 on the microphone 6506 side.

A protection member 6510 having a light-transmitting property is provided on a display surface side of the housing 6501, and a display apparatus 6511, an optical member 6512, a touch sensor panel 6513, a printed circuit board 6517, a battery 6518, and the like are provided in a space surrounded by the housing 6501 and the protection member 6510.

The display apparatus 6511, the optical member 6512, and the touch sensor panel 6513 are fixed to the protection member 6510 with an adhesive layer (not illustrated).

Part of the display apparatus 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display apparatus 6511. Thus, an extremely lightweight electronic device can be obtained. Since the display apparatus 6511 is extremely thin, the battery 6518 with high capacity can be mounted without an increase in the thickness of the electronic device. Moreover, part of the display apparatus 6511 is folded back so that a connection portion with the FPC 6515 is provided on the back side of a pixel portion, whereby an electronic device with a narrow bezel can be achieved.

FIG. 38C illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operation of the television device 7100 illustrated in FIG. 38C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure where a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 38D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 38E and FIG. 38F illustrate examples of digital signage.

Digital signage 7300 illustrated in FIG. 38E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 38F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in each of FIG. 38E and FIG. 38F.

A larger area of the display portion 7000 can increase the amount of information that can be provided at a time. The larger display portion 7000 attracts more attentions, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 38E and FIG. 38F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

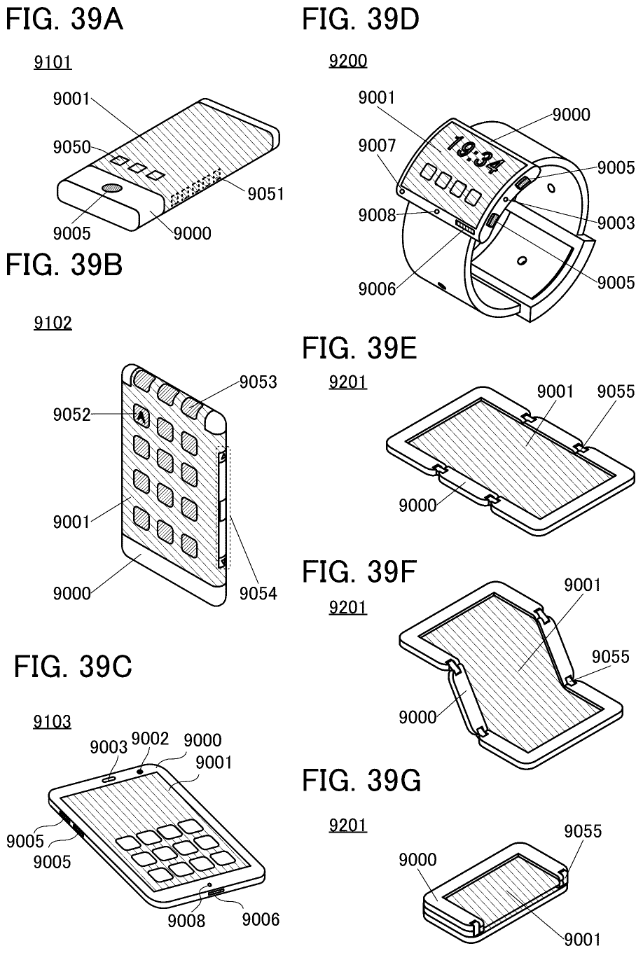

Electronic devices illustrated in FIG. 39A to FIG. 39G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 39A to FIG. 39G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a storage medium (an external storage medium or a storage medium incorporated in the camera), a function of displaying the taken image on the display portion, or the like.

The electronic devices illustrated in FIG. 39A to FIG. 39G are described in detail below.

FIG. 39A is a perspective view illustrating a portable information terminal 9101. The portable information terminal 9101 can be used as a smartphone, for example. Note that the portable information terminal 9101 may include the speaker 9003, the connection terminal 9006, the sensor 9007, or the like. The portable information terminal 9101 can display characters and image information on its plurality of surfaces. FIG. 39A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 39B is a perspective view illustrating a portable information terminal 9102. The portable information terminal 9102 has a function of displaying information on three or more surfaces of the display portion 9001. Shown here is an example where information 9052, information 9053, and information 9054 are displayed on different surfaces. For example, a user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 39C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 39D is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 39E to FIG. 39G are perspective views illustrating a foldable portable information terminal 9201. FIG. 39E is a perspective view of an opened state of the portable information terminal 9201, FIG. 39G is a perspective view of a folded state thereof, and FIG. 39F is a perspective view of a state in the middle of change from one of FIG. 39E and FIG. 39G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### REFERENCE NUMERALS

100A: display apparatus, 100B: display apparatus, 100C: display apparatus, 100D: display apparatus, 100E: display apparatus, 100F: display apparatus, 100G: display apparatus, 100: display apparatus, 101: layer, 105: insulating layer, 110a: subpixel, 110b: subpixel, 110c: subpixel, 110d: subpixel, 110: pixel, 111a: pixel electrode, 111af: conductive film, 111b: pixel electrode, 111c: pixel electrode, 111d: pixel electrode, 111e: pixel electrode, 111f: pixel electrode, 111g: pixel electrode, 111h: pixel electrode, 111: pixel electrode, 112a: conductive layer, 112b: conductive layer, 112g: conductive layer, 113a: layer, 113af: film, 113b: layer, 113bf: film, 113c: layer, 113cf: film, 113d: layer, 113e: layer, 113f: layer, 113g: layer, 113h: layer, 113: layer, 114: common layer, 115: common electrode, 117: light-blocking layer, 118a: insulating layer, 118af: insulating film, 118b: insulating layer, 118bf: insulating film, 118c: insulating layer, 118cf: insulating film, 118e: insulating layer, 118f: insulating layer, 118g: insulating layer, 118h: insulating layer, 118j: insulating layer, 118: insulating layer, 120: substrate, 121: opening portion, 122: resin layer, 123: conductive layer, 124a: pixel, 124b: pixel, 125: insulating layer, 126a: conductive layer, 126b: conductive layer, 126g: conductive layer, 126: resin layer, 127: insulating layer, 128: layer, 129a: conductive layer, 129b: conductive layer, 129g: conductive layer, 130a: light-emitting device, 130b: light-emitting device, 130c: light-emitting device, 130: light-emitting device, 131: protective layer, 139: plug, 140: connection portion, 142: adhesive layer, 150: light-receiving device, 151: substrate, 152: substrate, 162: insulating layer, 163: insulating layer, 164: circuit, 165B: coloring layer, 165G: coloring layer, 165R: coloring layer, 165: wiring, 166: conductive layer, 167: display portion, 172: FPC, 173: IC, 175_1: groove, 175_2: groove, 175_3: groove, 175_4: groove, 175_5: groove, 175_6: groove, 175_7: groove, 175: groove, 181: region, 186: sealing portion, 190a: resist mask, 190b: resist mask, 190c: resist mask, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 256b: plug, 256c: plug, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 294: dummy pixel portion, 295: dummy pixel portion, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 351: substrate, 352: finger, 353: layer, 355: functional layer, 357: layer, 359: substrate, 400: display apparatus, 401: substrate, 402: driver circuit portion, 403: driver circuit portion, 404: display portion, 405B: subpixel, 405G: subpixel, 405R: subpixel, 405: pixel, 410a: transistor, 410: transistor, 411i: channel formation region, 411n: low-resistance region, 411: semiconductor layer, 412: insulating layer, 413: conductive layer, 414a: conductive layer, 414b: conductive layer, 415: conductive layer, 416: insulating layer, 421: insulating layer, 422: insulating layer, 423: insulating layer, 426: insulating layer, 430: pixel, 431: conductive layer, 450a: transistor, 450: transistor, 451: semiconductor layer, 452: insulating layer, 453: conductive layer, 454a: conductive layer, 454b: conductive layer, 455: conductive layer, 700A: electronic device, 700B: electronic device, 721: housing, 723: wearing portion, 727: earphone portion, 750: earphone, 751: display apparatus, 753: optical member, 756: display region, 757: frame, 758: nose pad, 772: lower electrode, 785: layer, 786a: EL layer, 786b: EL layer, 786: EL layer, 788: upper electrode, 800A: electronic device, 800B: electronic device, 820: display portion, 821: housing, 822: communication portion, 823: wearing portion, 824: control portion, 825: image capturing portion, 827: earphone portion, 832: lens, 4411: light-emitting layer, 4412: light-emitting layer, 4413: light-emitting layer, 4420: layer, 4421: layer, 4422: layer, 4430: layer, 4431: layer, 4432: layer, 4440: charge-generation layer, 6500: electronic device, 6501: housing, 6502: display portion, 6503: power button, 6504: button, 6505: speaker, 6506: microphone, 6507: camera, 6508: light source, 6510: protection member, 6511: display apparatus, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: information terminal, 9102: information terminal, 9103: tablet terminal, 9200: information terminal, 9201: information terminal

1. A display apparatus comprising:
a pixel portion; and
a dummy pixel portion,
wherein the dummy pixel portion is a region that does not contribute to display,
wherein the dummy pixel portion is adjacent to an outside of the pixel portion in a plan view,
wherein the pixel portion comprises a first insulating layer, a first pixel electrode and a second pixel electrode over the first insulating layer, a first layer over the first pixel electrode, a second layer over the second pixel electrode, and a common electrode over the first layer and the second layer,
wherein the dummy pixel portion comprises the first insulating layer, a first conductive layer and a second conductive layer over the first insulating layer, a third layer over the first conductive layer, a fourth layer over the second conductive layer, and the common electrode over the third layer and the fourth layer,
wherein the first conductive layer and the second conductive layer each comprise the same material as a material of the first pixel electrode,
wherein the first layer comprises a first compound, the first compound being a light-emitting organic compound,
wherein the third layer comprises the first compound,
wherein the first insulating layer comprises a first groove and a second groove,
wherein the first groove comprises a first region overlapping with the first pixel electrode and a second region overlapping with the second pixel electrode, and
wherein the second groove comprises a third region overlapping with the first conductive layer and a fourth region overlapping with the second conductive layer.

2. The display apparatus according to claim 1, further comprising a resin layer,
wherein the resin layer is in the first region, in the second region, and in a fifth region between the first region and the second region inside the first groove, and
wherein the resin is in the third region, in the fourth region, and in a sixth region between the third region and the fourth region inside the second groove.

3. The display apparatus according to claim 2,
wherein the resin layer overlaps with part of the first pixel electrode and part of the second pixel electrode,
wherein the resin comprises a first opening portion overlapping with the first pixel electrode and a second opening portion overlapping with the second pixel electrode,
wherein in the first opening portion, the first layer and the common electrode are in contact with each other, and
wherein in the second opening portion, the second layer and the common electrode are in contact with each other.

4. The display apparatus according to claim 2,
wherein the resin layer comprises a seventh region that overlaps with 50% or more of an area of the first conductive layer in the plan view and is located between the third layer and the common electrode, and an eighth region that overlaps with 50% or more of an area of the second conductive layer in the plan view and is located between the fourth layer and the common electrode.

5. The display apparatus according to claim 1,
wherein the second layer comprises a second compound, the second compound being a light-emitting organic compound,
wherein the fourth layer comprises at least one of the first compound and the second compound,
wherein the first compound is the light-emitting organic compound that emits light with intensity in a red wavelength range, a green wavelength range, or a blue wavelength range, and
wherein the second compound is the light-emitting organic compound that emits light with intensity in a wavelength range of a color different from a color for the first compound among the red wavelength range, the green wavelength range, and the blue wavelength range.

6. The display apparatus according to claim 1,
wherein the second layer and the fourth layer each comprise the first compound.

7. The display apparatus according to claim 2, further comprising a second insulating layer between the first layer and the resin layer,
wherein the second insulating layer comprises a region in contact with a top surface of the first layer in an end portion of the first layer, and a region in contact with the first insulating layer in the first region.
